(19) United States
(12) Patent Application Publication
(10) Pub. No.: US 2025/0072260 A1
(43) Pub. Date: Feb. 27, 2025

(54) Display Apparatus

(71) Applicant: Semiconductor Energy Laboratory Co., Ltd., Kanagawa-ken (JP)

(72) Inventors: Shunpei YAMAZAKI, Tokyo (JP); Naoaki HASHIMOTO, Sagamihara (JP); Daiki NAKAMURA, Atsugi (JP)

(73) Assignee: Semiconductor Energy Laboratory Co., Ltd., Kanagawa-ken (JP)

(21) Appl. No.: 18/810,137

(22) Filed: Aug. 20, 2024

(30) Foreign Application Priority Data
Aug. 25, 2023 (JP) 2023-136988
Nov. 16, 2023 (JP) 2023-195006

(51) Int. Cl. H10K 59/80; H10K 102/00

(52) U.S. Cl. CPC H10K 59/80516; H10K 2102/351

(57) ABSTRACT

To provide a display apparatus with high display quality. To provide a display apparatus which includes first and second light-emitting devices and in which the first and second light-emitting devices include a common electrode with a light-transmitting property, the first light-emitting device includes a first electrode, a first EL layer, and a first auxiliary electrode with a light-transmitting property, the second light-emitting device includes a second electrode, a second EL layer, and a second auxiliary electrode with a light-transmitting property, the first EL layer is between the first electrode and the common electrode, the second EL layer is between the second electrode and the common electrode, the first auxiliary electrode is between the first EL layer and the common electrode, the second auxiliary electrode is between the second EL layer and the common electrode, and the first auxiliary electrode has a larger thickness than the second auxiliary electrode.

### BACKGROUND OF THE INVENTION

### 1. Field of the Invention

One embodiment of the present invention relates to a display apparatus. Note that one embodiment of the present invention is not limited to the above technical field. Examples of the technical field of one embodiment of the present invention disclosed in this specification and the like include a semiconductor apparatus, a display apparatus, a light-emitting apparatus, a power storage device, a memory device, an electronic device, a lighting device, an input device, an input/output device, a driving method thereof, and a manufacturing method thereof. A semiconductor apparatus generally means an apparatus that can function by utilizing semiconductor characteristics.

### 2. Description of the Related Art

In recent years, higher resolution has been required for display panels. Examples of devices that require high-resolution display panels include a smartphone, a tablet terminal, and a notebook computer. Furthermore, higher resolution has been required for a stationary display apparatus such as a television device or a monitor device along with an increase in definition. An example of a device absolutely required to have the highest resolution display panel is a device for virtual reality (VR) or augmented reality (AR).

Examples of the display apparatus that can be used for a display panel include, typically, a liquid crystal display apparatus, a light-emitting apparatus including a light-emitting device such as an organic electroluminescence (EL) element or a light-emitting diode (LED), and electronic paper performing display by an electrophoretic method or the like.

An organic EL element generally has a structure in which, for example, a layer including a light-emitting organic compound is provided between a pair of electrodes. By voltage application to this element, the light-emitting organic compound can emit light. A display apparatus including such an organic EL element needs no backlight, which is necessary for a liquid crystal display apparatus and the like, and thus can have advantages such as thinness, lightness in weight, high contrast, and low power consumption.

A variety of methods for manufacturing an organic EL element are known; in one disclosed manufacturing method, an organic compound layer is formed by an inkjet method (Patent Document 1). An organic EL element formed by the manufacturing method described in Patent Document 1 includes an optical adjustment layer, with which optical adjustment is performed.

### REFERENCE

### Patent Document

[Patent Document 1] Japanese Published Patent Application No. 2022-080879

### SUMMARY OF THE INVENTION

In the manufacturing method disclosed in Patent Document 1, organic compound layers are formed by an inkjet method, and then, an optical adjustment layer is provided so as to be shared by the organic EL elements. Accordingly, the manufacturing method has difficulty in optimizing optical design for each organic EL element.

An object of one embodiment of the present invention is to provide a display apparatus having high display quality. An object of one embodiment of the present invention is to provide a display apparatus having low power consumption. An object of one embodiment of the present invention is to provide a display apparatus that can easily achieve higher resolution. An object of one embodiment of the present invention is to provide a display apparatus having both high display quality and high resolution. An object of one embodiment of the present invention is to provide a high-contrast display apparatus.

An object of one embodiment of the present invention is to provide a display apparatus having a novel structure or a method for manufacturing the display apparatus. An object of one embodiment of the present invention is to provide a method for manufacturing the above display apparatus with high yield. An object of one embodiment of the present invention is to at least alleviate at least one of problems in the conventional art.

Note that the description of these objects does not preclude the existence of other objects. In one embodiment of the present invention, there is no need to achieve all of these objects. Objects other than these can be derived from the description of the specification, the drawings, the claims, and the like.

One embodiment of the present invention is a display apparatus which includes a first light-emitting device and a second light-emitting device and in which the first light-emitting device and the second light-emitting device include a common electrode with a light-transmitting property, the first light-emitting device includes a first electrode, a first EL layer, and a first auxiliary electrode with a light-transmitting property, the second light-emitting device includes a second electrode, a second EL layer, and a second auxiliary electrode with a light-transmitting property, the first EL layer is between the first electrode and the common electrode, the second EL layer is between the second electrode and the common electrode, the first auxiliary electrode is between the first EL layer and the common electrode, the second auxiliary electrode is between the second EL layer and the common electrode, and a thickness of the first auxiliary electrode is larger than a thickness of the second auxiliary electrode.

Another embodiment of the present invention is a display apparatus which includes a first light-emitting device and a second light-emitting device and in which the first light-emitting device and the second light-emitting device include a common electrode with a light-transmitting property, the first light-emitting device includes a first electrode, a first EL layer, and a first auxiliary electrode with a light-transmitting property, the second light-emitting device includes a second electrode and a second EL layer, the first EL layer is between the first electrode and the common electrode, the second EL layer is between the second electrode and the common electrode and is in contact with the common electrode, and the first auxiliary electrode is between the first EL layer and the common electrode.

Another embodiment of the present invention is a display apparatus which includes a first light-emitting device and a second light-emitting device and in which the first light-emitting device and the second light-emitting device include a common electrode with a light-transmitting property and a common layer, the common electrode is over the common layer, the first light-emitting device includes a first electrode, a first EL layer, and a first auxiliary electrode with a light-transmitting property, the second light-emitting device includes a second electrode and a second EL layer, the first EL layer is between the first electrode and the common layer, the second EL layer is between the second electrode and the common layer and is in contact with the common layer, and the first auxiliary electrode is between the first EL layer and the common layer.

In the display apparatus having the above structure, it is preferable that the common layer include an alkali metal or an alkaline earth metal.

Another embodiment of the present invention is a display apparatus having any of the above structures in which a color of light emitted from the first light-emitting device is different from a color of light emitted from the second light-emitting device.

Another embodiment of the present invention is a display apparatus having any of the above structures in which a wavelength of light emitted from the first light-emitting device is longer than a wavelength of light emitted from the second light-emitting device.

Another embodiment of the present invention is a display apparatus having any of the above structures in which the first auxiliary electrode includes silver and magnesium.

In the display apparatus having the above structure, it is preferable that the thickness of the first auxiliary electrode be greater than or equal to 1 nm and less than or equal to 50 nm.

It is preferable that the display apparatus having any of the above structures further include an insulating layer, and the insulating layer be between the first EL layer and the second EL layer.

According to one embodiment of the present invention, a display apparatus having high display quality can be provided. A display apparatus having low power consumption can be provided. A display apparatus that can easily achieve higher resolution can be provided. A display apparatus having both high display quality and high resolution can be provided. Moreover, a high-contrast display apparatus can be provided.

According to one embodiment of the present invention, a display apparatus having a novel structure or a method for manufacturing the display apparatus can be provided. Moreover, a method for manufacturing the above display apparatus with high yield can be provided. According to one embodiment of the present invention, at least one of problems in the conventional art can be at least alleviated.

Note that the description of these effects does not preclude the existence of other effects. One embodiment of the present invention does not necessarily have all of these effects. Effects other than these can be derived from the description of the specification, the drawings, the claims, and the like.

### BRIEF DESCRIPTION OF THE DRAWINGS

In the accompanying drawings:

FIGS. 1A and 1B show a structure example of a display apparatus;

FIG. 2A shows absorptance of Ag:Mg films, and FIG. 2B shows simulation results of current efficiency of light-emitting devices;

FIGS. 3A and 3B show structure examples of a display apparatus;

FIGS. 4A and 4B show structure examples of a display apparatus;

FIGS. 5A to 5E show an example method for manufacturing a display apparatus;

FIGS. 6A to 6D show an example method for manufacturing a display apparatus;

FIGS. 7A to 7D show an example method for manufacturing a display apparatus;

FIGS. 8A to 8C show an example method for manufacturing a display apparatus;

FIGS. 9A to 9C show an example method for manufacturing a display apparatus;

FIGS. 10A to 10C show an example method for manufacturing a display apparatus;

FIGS. 11A to 11C show structure examples of a light-emitting device;

FIG. 12 shows a structure example of a light-emitting device;

FIGS. 13A and 13B are perspective views showing an example of a display apparatus;

FIGS. 14A and 14B are cross-sectional views showing examples of a display apparatus;

FIG. 15 is a perspective view showing an example of a display apparatus;

FIG. 16 is a cross-sectional view showing an example of a display apparatus;

FIG. 17 is a cross-sectional view showing an example of a display apparatus;

FIGS. 18A to 18D show examples of electronic devices;

FIGS. 19A to 19F show examples of electronic devices;

FIGS. 20A to 20G show examples of electronic devices;

FIG. 21 shows current efficiency-luminance characteristics of Light-emitting Device 1A and Light-emitting Device 1B;

FIG. 22 shows blue index-luminance characteristics of Light-emitting Device 2A and Light-emitting Device 2B;

FIG. 23 shows current density-voltage characteristics of Light-emitting Devices 3R;

FIG. 24 shows current efficiency-current density characteristics of Light-emitting Devices 3R;

FIG. 25 shows external quantum efficiency-current density characteristics of Light-emitting Devices 3R;

FIG. 26 shows electroluminescence spectra of Light-emitting Devices 3R;

FIG. 27 shows current density-voltage characteristics of Light-emitting Devices 3G;

FIG. 28 shows current efficiency-current density characteristics of Light-emitting Devices 3G;

FIG. 29 shows external quantum efficiency-current density characteristics of Light-emitting Devices 3G;

FIG. 30 shows electroluminescence spectra of Light-emitting Devices 3G;

FIG. 31 shows current density-voltage characteristics of Light-emitting Devices 3B;

FIG. 32 shows blue index-current density characteristics of Light-emitting Devices 3B;

FIG. 33 shows external quantum efficiency-current density characteristics of Light-emitting Devices 3B;

FIG. 34 shows electroluminescence spectra of Light-emitting Devices 3B;

FIG. 35 shows current efficiency-luminance characteristics of Light-emitting Device 4A and Light-emitting Device 4B;

FIG. 36 shows current efficiency-luminance characteristics of Light-emitting Device 5A and Light-emitting Device 5B;

FIG. 37 shows blue index-luminance characteristics of Light-emitting Device 6A and Light-emitting Device 6B;

FIG. 38 shows current density-voltage characteristics of Light-emitting Device 7R;

FIG. 39 shows external quantum efficiency-current density characteristics of Light-emitting Device 7R;

FIG. 40 shows current density-voltage characteristics of Light-emitting Device 7G;

FIG. 41 shows external quantum efficiency-current density characteristics of Light-emitting Device 7G;

FIG. 42 shows current density-voltage characteristics of Light-emitting Device 7B;

FIG. 43 shows external quantum efficiency-current density characteristics of Light-emitting Device 7B;

FIG. 44 shows a driving time-dependent change in luminance of Light-emitting Device 7R;

FIG. 45 shows a driving time-dependent change in luminance of Light-emitting Device 7G; and

FIG. 46 shows a driving time-dependent change in luminance of Light-emitting Device 7B.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

In this specification and the like, the terms “film” and “layer” can be interchanged with each other. For example, in some cases, the terms “conductive layer” and “insulating layer” can be changed into “conductive film” and “insulating film”, respectively.

Note that in this specification, an EL layer is provided between a pair of electrodes of a light-emitting device, and means a layer including at least a light-emitting substance (also referred to as a light-emitting layer) or a stacked body including a light-emitting layer. In this specification and the like, an EL layer is referred to as an organic compound layer in some cases.

In this specification and the like, a display panel that is one embodiment of a display apparatus has a function of displaying (outputting) an image or the like on (to) a display surface. Thus, the display panel is one embodiment of an output device.

In this specification and the like, a structure in which a connector such as a flexible printed circuit (FPC) or a tape carrier package (TCP) is attached to a substrate of a display panel, or a structure in which an IC is mounted on the substrate by a chip on glass (COG) method or the like is referred to as a display panel module or a display module, or simply referred to as a display panel or the like in some cases.

A light-emitting device of one embodiment of the present invention may include layers including a substance with a high hole-injection property, a substance with a high hole-transport property, a substance with a high electron-transport property, a substance with a high electron-injection property, a substance with a bipolar property, and the like.

### Embodiment 1

In this embodiment, examples of the structure and manufacturing method of a display apparatus of one embodiment of the present invention will be described.

One embodiment of the present invention is a display apparatus including a light-emitting device (also referred to as a light-emitting element). The display apparatus includes at least two light-emitting devices emitting light of different colors. The light-emitting device includes a pair of electrodes and an EL layer therebetween. As the light-emitting device, an electroluminescence device such as an organic EL element or an inorganic EL element can be used. Besides, a light-emitting diode (LED) can be used. The light-emitting device of one embodiment of the present invention is preferably an organic EL element (organic electroluminescence device). The EL layers of the two or more light-emitting devices emitting light of different colors include different materials. For example, when three kinds of light-emitting devices emitting red (R), green (G), and blue (B) light are provided, a full-color display apparatus can be obtained.

As a way of forming EL layers separately between light-emitting devices of different colors, an evaporation method using a shadow mask such as a metal mask is known. However, this method causes a deviation from the designed shape and position of an island-shaped organic film due to various influences such as the low accuracy of the metal mask position, the positional deviation between the metal mask and a substrate, a warp of the metal mask, and the vapor-scattering-induced expansion of outline of the formed film; accordingly, it is difficult to achieve high resolution and a high aperture ratio. In addition, dust derived from a material attached to the metal mask in evaporation is generated in some cases. Such dust might cause defective patterning of the light-emitting device. In addition, a short circuit due to the dust may occur. A cleaning step for removing the material attached to the metal mask is necessary. Thus, a measure has been taken for pseudo improvement in resolution (also referred to pixel density). As a specific measure, a unique pixel arrangement such as a PenTile pattern has been employed.

In one embodiment of the present invention, fine patterning of an EL layer is performed by a photolithography method without a shadow mask such as a metal mask. With the patterning, a high-resolution display apparatus with a high aperture ratio, which has been difficult to achieve, can be manufactured. Moreover, EL layers can be formed separately, enabling the display apparatus to perform extremely clear display with high contrast and high display quality.

Here, description is made on a case where EL layers in light-emitting devices of two colors are formed separately, for simplicity. First, a stack of a first EL film and a first sacrificial film is formed to cover a pixel electrode (Step A). Next, a resist mask is formed over the first sacrificial film. Then, part of the first sacrificial film and part of the first EL film are etched using the resist mask, so that a first EL layer and a first sacrificial layer over the first EL layer are formed.

Next, a stack of a second EL film and a second sacrificial film is formed. Then, part of the second sacrificial film and part of the second EL film are etched using a resist mask, so that a second EL layer and a second sacrificial layer over the second EL layer are formed. In this manner, the first EL layer and the second EL layer can be formed separately. Finally, the first sacrificial layer and the second sacrificial layer are removed, and a common electrode is formed, whereby the light-emitting devices of two colors can be formed separately.

Furthermore, by repeating the above-described steps, EL layers in light-emitting devices of three or more colors can be formed separately. Accordingly, a display apparatus including light-emitting devices of three or more colors can be achieved.

The display apparatus of one embodiment of the present invention includes an auxiliary electrode located between an EL layer of at least one light-emitting device and the common electrode. The auxiliary electrode has a light-transmitting property and also functions as an optical adjustment layer of the light-emitting device. Since the auxiliary electrode and the EL layer of the light-emitting device are formed by processing at the same time by a photolithography method, an end portion (contour) of the auxiliary electrode and an end portion of the EL layer are substantially aligned with each other in the direction perpendicular to the substrate.

In the case where the auxiliary electrode is provided in each of the light-emitting devices of two colors, a stack of the first EL film, a first conductive film to be a first auxiliary electrode, and the first sacrificial film is formed to cover pixel electrodes. Next, a resist mask is formed over the first sacrificial film. Then, part of the first sacrificial film, part of the first conductive film, and part of the first EL film are etched using the resist mask, so that the first EL layer, the first auxiliary electrode over the first EL layer, and the first sacrificial layer over the first auxiliary electrode are formed (Step A).

After Step A, a stack of the second EL film, a second conductive film to be a second auxiliary electrode, and the second sacrificial film is formed. Then, part of the second sacrificial film, part of the second conductive film, and part of the second EL film are etched using a resist mask, so that the second EL layer, the second auxiliary electrode over the second EL layer, and the second sacrificial layer over the second auxiliary electrode are formed. In this manner, the first auxiliary electrode and the second auxiliary electrode can be formed separately. Finally, the first sacrificial layer and the second sacrificial layer are removed, and the common electrode is formed, whereby the light-emitting devices of two colors that include the respective auxiliary electrodes can be formed separately.

In the case of providing an auxiliary electrode in one of the light-emitting devices of two colors and providing no auxiliary electrode in the other light-emitting device, a stack of the second EL film and the second sacrificial film is formed after Step A. Then, part of the second sacrificial film and part of the second EL film are etched using the resist mask, so that the second EL layer and the second sacrificial layer over the second EL layer are formed. In this manner, the first EL layer and the second EL layer can be formed separately. Finally, the first sacrificial layer and the second sacrificial layer are removed, and the common electrode is formed, whereby the light-emitting device including the auxiliary electrode and the light-emitting device including no auxiliary electrode can be formed separately.

When the auxiliary electrodes are formed separately for the light-emitting devices, the structure (thickness, material, or the like) of the auxiliary electrode can be different between the light-emitting devices. Thus, optical adjustment for each light-emitting device can be easily optimized. Since optical adjustment of the light-emitting device can be performed by the control of the auxiliary electrode in one embodiment of the present invention, the auxiliary electrode can also be referred to as an optical adjustment layer.

In the case where EL layers for different colors are adjacent to each other, it is difficult to set the distance between the EL layers adjacent to each other to less than 10 μm with a formation method using a metal mask, for example. When processing is performed using a photolithography method, however, the distance can be reduced to less than or equal to 3 μm, less than or equal to 2 μm, or less than or equal to 1 μm. Using a light exposure apparatus for LSI can further shorten the distance to less than or equal to 500 nm, less than or equal to 200 nm, less than or equal to 100 nm, or even less than or equal to 50 nm, for example. Accordingly, the area of a non-light-emitting region that may be present between two light-emitting devices can be significantly reduced, and the aperture ratio can be close to 100%. For example, the aperture ratio may be higher than or equal to 50%, higher than or equal to 60%, higher than or equal to 70%, higher than or equal to 80%, or higher than or equal to 90%; that is, the aperture ratio lower than 100% can be achieved.

In the case where adjacent light-emitting devices each include an auxiliary electrode, the distance between the auxiliary electrodes can also be shortened to less than or equal to 3 μm, less than or equal to 2 μm, or less than or equal to 1 μm by performing processing using a photolithography method. Using a light exposure apparatus for LSI can further shorten the distance to less than or equal to 500 nm, less than or equal to 200 nm, less than or equal to 100 nm, or even less than or equal to 50 nm, for example.

Furthermore, a pattern of the EL layer itself can be made extremely smaller than that in the case of using a metal mask. For example, in the case of using a metal mask for forming EL layers separately, a variation in the thickness of the pattern occurs between the center and the edge of the pattern. This causes a reduction in an effective area that can be used as a light-emitting region with respect to the whole pattern area. In contrast, when processing by a photolithography method is employed, the processing can be performed on a film that is formed to have a uniform thickness, which enables a uniform thickness in the pattern. Thus, even with a fine pattern, almost the entire area can be used as a light-emitting region. Therefore, the above manufacturing method achieves both high resolution and a high aperture ratio.

As described above, the above manufacturing method enables a display apparatus in which minute light-emitting devices are integrated; accordingly, it is possible to achieve a display apparatus employing what is called a stripe arrangement having resolution higher than or equal to 500 ppi, higher than or equal to 1000 ppi, higher than or equal to 2000 ppi, higher than or equal to 3000 ppi, or higher than or equal to 5000 ppi.

Specific examples of the structure and manufacturing method of the display apparatus of one embodiment of the present invention will be described below with reference to drawings.

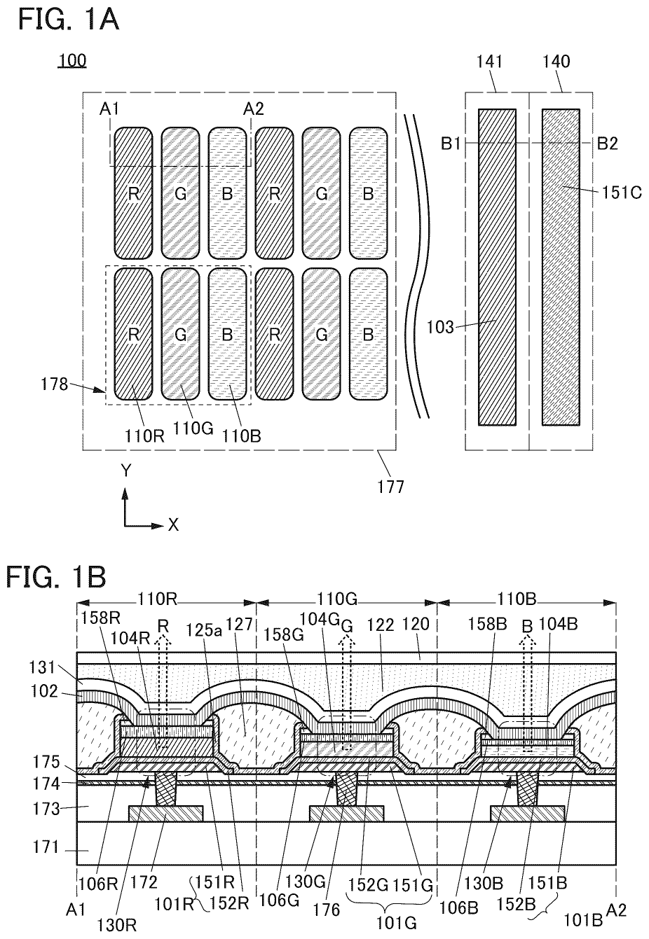

As illustrated in FIGS. 1A and 1B, a plurality of light-emitting devices 130 are formed over an insulating layer 175 to constitute part of a display apparatus 100.

The display apparatus 100 includes a pixel portion 177 in which a plurality of pixels 178 are arranged in matrix. The pixel 178 includes a subpixel 110R, a subpixel 110G, and a subpixel 110B.

Hereinafter, description common to the subpixels 110R, 110G, and 110B is sometimes made using a simple term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light. The pixel 178 may be further provided with a sensor, which is preferably an organic photodiode sensor including an organic compound. Part of a carrier-transport layer in the organic photodiode sensor including the organic compound can be formed using the same material as the light-emitting device.

In this specification and the like, the row direction and the column direction are sometimes referred to as the X direction and the Y direction, respectively. The X direction and the Y direction intersect with each other and are perpendicular to each other, for example.

FIG. 1A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. An EL layer 103 is provided in the region 141. A conductive layer 151C is provided in the connection portion 140.

Although FIG. 1A illustrates an example where the region 141 and the connection portion 140 are located on the right side of the pixel portion 177, there is no particular limitation on the positions of the region 141 and the connection portion 140. The number of regions 141 and the number of connection portions 140 may each be one or more.

FIG. 1B is an example of a cross-sectional view along the dashed-dotted line A1-A2 in FIG. 1A. As illustrated in FIG. 1B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, a light-emitting device 130R, a light-emitting device 130G, and a light-emitting device 130B are provided over the insulating layer 175 and the plug 176. Hereinafter, description common to the light-emitting devices 130R, 130G, and 130B is sometimes made using a simple term “light-emitting device 130”. A protective layer 131 is provided over a second electrode 102 included in the light-emitting device 130 so as to cover the light-emitting device 130. The protective layer 131 can be formed by a vacuum evaporation method, a sputtering method, a chemical vapor deposition (CVD) method, an atomic layer deposition (ALD) method, or the like. As the protective layer 131, a film having a high barrier property can be formed at low temperatures in the case where the protective layer 131 is an inorganic insulating film formed by a plasma-enhanced atomic layer deposition (PEALD) method. In that case, damage to the EL layers of the light-emitting devices can be reduced, so that the display apparatus can easily achieve high display quality. It is also possible to favorably inhibit entry of substances that promote deterioration of the EL layers and the second electrode 102, such as water, oxygen, and a minor component of the air, so that the display apparatus can achieve high display quality. Since an inorganic insulating film formed by a PEALD method has a high barrier property, the protective layer 131 can be formed to be thin, so that the display apparatus can achieve high display quality. Note that the protective layer 131 may have a stacked-layer structure of two or more layers.

A substrate 120 is attached to the protective layer 131 with a resin layer 122. A second insulating layer 125a and a first insulating layer 127 over the second insulating layer 125a are preferably provided between the light-emitting devices 130 that are adjacent to each other.

The second insulating layer 125a is provided in contact with the side surfaces of the EL layers included in the light-emitting devices 130. The second insulating layer 125a is preferably provided in contact with the side surfaces of pixel electrodes (a first electrode 101R, a first electrode 101G, and a first electrode 101B) of the light-emitting devices 130. The second insulating layer 125a is preferably provided in contact with the side surface and the bottom surface of the first insulating layer 127.

In the above structure, the first insulating layer 127 can be separated from the EL layer of the light-emitting device 130 by the second insulating layer 125a.

The second insulating layer 125a functions as a protective insulating layer for the EL layer of the light-emitting device 130. The second insulating layer 125a preferably has a barrier property against at least one of oxygen and moisture. Since the first insulating layer 127 and the EL layer are separated from each other by the second insulating layer 125a, oxygen, moisture, or constituent elements thereof can be inhibited from entering the inside of the EL layer through the side surface thereof, enabling the display apparatus to be highly reliable.

In a region where the second insulating layer 125a is in contact with the side surface of the EL layer of the light-emitting device 130, the thickness of the second insulating layer 125a is preferably greater than or equal to 5 nm and less than or equal to 50 nm, further preferably greater than or equal to 5 nm and less than or equal to 30 nm, still further preferably greater than or equal to 5 nm and less than or equal to 20 nm, yet still further preferably greater than or equal to 5 nm and less than or equal to 10 nm. When the thickness of the second insulating layer 125a is within the above range, the display apparatus can have high reliability and a high aperture ratio.

The second insulating layer 125a can be formed using an inorganic material. For the second insulating layer 125a, a single layer or stacked layers of silicon oxide, silicon oxynitride, silicon nitride, silicon nitride oxide, aluminum oxide, magnesium oxide, hafnium oxide, gallium oxide, or the like can be used. It is particularly preferable to use a silicon-based insulating film such as a silicon oxide film, a silicon oxynitride film, a silicon nitride film, or a silicon nitride oxide film.

Note that in this specification, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The first insulating layer 127 provided over the second insulating layer 125a fills a gap formed between the light-emitting devices that are adjacent to each other, thereby reducing a step on the formation surface of the second electrode 102 and enabling favorable coverage; thus, defects such as disconnection can be inhibited. As the first insulating layer 127, an insulating layer including an organic material can be favorably used. For example, an acrylic resin, a polyimide resin, an epoxy resin, a polyamide resin, a polyimide-amide resin, a siloxane resin, a benzocyclobutene-based resin, a phenol resin, or a precursor of any of these resins can be used for the first insulating layer 127. Moreover, the first insulating layer 127 can be formed using a photosensitive resin. As the photosensitive resin, a positive photosensitive material or a negative photosensitive material can be used.

In FIG. 1B, the light-emitting devices 130R, 130G, and 130B are each illustrated as the light-emitting device 130. The light-emitting devices 130R, 130G, and 130B emit light of different colors. Light emitted from the light-emitting device 130R has a longer wavelength than light emitted from the light-emitting device 130G. Light emitted from the light-emitting device 130G has a longer wavelength than light emitted from the light-emitting device 130B. For example, the light-emitting device 130R can emit red (R) light, the light-emitting device 130G can emit green (G) light, and the light-emitting device 130B can emit blue (B) light. Alternatively, the light-emitting device 130R, 130G, or 130B may emit visible light of another color or infrared light.

In this specification and the like, the color of light emitted from a light-emitting device can be determined by the peak wavelength of an electroluminescence spectrum of the light-emitting device. For example, when the difference between the maximum peak wavelength in the visible light range of an electroluminescence spectrum of a first light-emitting device and the maximum peak wavelength in the visible light range of an electroluminescence spectrum of a second light-emitting device is greater than or equal to 50 nm, the color of light emitted from the first light-emitting device and the color of light emitted from the second light-emitting device are regarded as being different.

In this specification and the like, the blue wavelength range ranges from 400 nm to less than 490 nm, and blue light emission has at least one emission spectrum peak in this range. The green wavelength range ranges from 490 nm to less than 580 nm, and green light emission has at least one emission spectrum peak in this range. The red wavelength range ranges from 580 nm to 780 nm, and red light emission has at least one emission spectrum peak in this range.

The display apparatus of one embodiment of the present invention can be a top-emission display apparatus where light is emitted in the direction opposite to a substrate over which light-emitting devices are formed. Note that one embodiment of the present invention is not limited to this structure, and a dual-emission structure may be employed in which light emitted from the light-emitting devices is extracted to above and below the substrate over which the light-emitting devices are formed.

The light-emitting device 130R includes the first electrode 101R (pixel electrode) including a conductive layer 151R and a conductive layer 152R, an EL layer 104R over the first electrode 101R, an auxiliary electrode 106R over the EL layer 104R, and the second electrode 102 (common electrode) over the auxiliary electrode 106R. In other words, the EL layer 104R is located between the first electrode 101R and the second electrode 102, and the auxiliary electrode 106R is located between the EL layer 104R and the second electrode 102, in the light-emitting device 130R. The light-emitting device 130R includes a protective layer 158R in a region which is over the auxiliary electrode 106R and in which the auxiliary electrode 106R and the second electrode 102 are not connected to each other.

The light-emitting device 130G includes the first electrode 101G (pixel electrode) including a conductive layer 151G and a conductive layer 152G, an EL layer 104G over the first electrode 101G, an auxiliary electrode 106G over the EL layer 104G, and the second electrode 102 (common electrode) over the auxiliary electrode 106G. In other words, the EL layer 104G is located between the first electrode 101G and the second electrode 102, and the auxiliary electrode 106G is located between the EL layer 104G and the second electrode 102, in the light-emitting device 130G. The light-emitting device 130G includes a protective layer 158G in a region which is over the auxiliary electrode 106G and in which the auxiliary electrode 106G and the second electrode 102 are not connected to each other.

The light-emitting device 130B includes the first electrode 101B (pixel electrode) including a conductive layer 151B and a conductive layer 152B, an EL layer 104B over the first electrode 101B, an auxiliary electrode 106B over the EL layer 104B, and the second electrode 102 (common electrode) over the auxiliary electrode 106B. In other words, the EL layer 104B is located between the first electrode 101B and the second electrode 102, and the auxiliary electrode 106B is located between the EL layer 104B and the second electrode 102, in the light-emitting device 130B. The light-emitting device 130B includes a protective layer 158B in a region which is over the auxiliary electrode 106B and in which the auxiliary electrode 106B and the second electrode 102 are not connected to each other.

Each of the EL layers 104R, 104G, and 104B is formed by forming an EL film and processing the EL film by a photolithography method. Thus, the EL layers 104R, 104G, and 104B are island-shaped layers that are independent of each other; alternatively, an island-shaped EL layer of the light-emitting devices of one emission color is independent of an island-shaped EL layer of the light-emitting devices of another emission color. It is preferable that the EL layers 104R, 104G, and 104B not overlap with one another. Providing the island-shaped EL layer in each of the light-emitting devices 130 can inhibit a leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained. Hereinafter, description common to the EL layers 104R, 104G, and 104B is sometimes made using a simple term “EL layer 104”.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified. The auxiliary electrode of the light-emitting device is located between the EL layer and the common electrode; when the common electrode functions as the cathode, the auxiliary electrode also functions as the cathode, and when the common electrode functions as the anode, the auxiliary electrode also functions as the anode.

Each of the auxiliary electrodes 106R, 106G, and 106B is formed by forming a conductive film and processing the conductive film by a photolithography method, in a manner similar to that of each of the EL layers 104R, 104G, and 104B. Thus, the auxiliary electrodes 106R, 106G, and 106B are island-shaped electrodes that are independent of each other; alternatively, an island-shaped auxiliary electrode of the light-emitting devices of one emission color is independent of an island-shaped auxiliary electrode of the light-emitting devices of another emission color. When the island-shaped auxiliary electrodes are formed separately for the light-emitting devices 130, the structure (thickness, material, or the like) of the auxiliary electrode can be different between the light-emitting devices 130; thus, optical adjustment can be performed for each of the light-emitting devices 130. In other words, the auxiliary electrodes 106R, 106G, and 106B function as optical adjustment layers. Hereinafter, description common to the auxiliary electrodes 106R, 106G, and 106B is sometimes made using a simple term “auxiliary electrode 106”.

Conductive films having a light-transmitting property (e.g., transparent conductive films or semi-transmissive and semi-reflective conductive films) are preferably used for the second electrode 102 (common electrode) and the auxiliary electrodes 106R, 106G, and 106B. In this specification and the like, visible light refers to light with a wavelength longer than or equal to 400 nm and shorter than 780 nm. In this specification and the like, the expression “having a light-transmitting property” refers to a state where the transmittance for light with at least some wavelengths in the visible light range is higher than or equal to 5%. In this specification and the like, a conductive film refers to a film having a resistivity lower than or equal to 10×10⁸ Ωcm. Note that the resistivity is a value obtained by dividing the resistance value of a sample by the length of the sample and then multiplying the result by the cross-sectional area of the sample. The resistivity is different from the sheet resistance obtained by dividing the resistance value of a sample by the length of the sample and then multiplying the result by the width of the sample.

A transparent conductive film is defined as a conductive film whose transmittance for light with at least some wavelengths in the visible light range is higher than or equal to 40%. The transmittance is preferably higher than or equal to 50%, further preferably higher than or equal to 60%, still further preferably higher than or equal to 70%, yet still further preferably higher than or equal to 80%, yet still further preferably higher than or equal to 90%. Specific examples of the transparent conductive film include a film of indium oxide containing tungsten oxide, a film of indium zinc oxide containing tungsten oxide, a film of indium oxide containing titanium oxide, a film of indium tin oxide containing titanium oxide, a film of indium tin oxide (hereinafter referred to as ITO), a film of indium zinc oxide, and a film of indium tin oxide to which silicon oxide is added. Alternatively, a film of an organic substance with high conductivity or a mixed film of an organic substance and an inorganic substance may be used as the transparent conductive film. Specific examples of the organic substance with high conductivity include an electron-transport material and a hole-transport material. Specific examples of the mixed film of an organic substance and an inorganic substance include a mixed film of an electron-transport material and Li and a mixed film of a hole-transport material and MoO₃.

A semi-transmissive and semi-reflective conductive film is defined as a conductive film whose reflectance for light with at least some wavelengths in the visible light range is higher than or equal to 10% and lower than or equal to 95%. The lower limit of the reflectance is preferably greater than or equal to 20%, further preferably greater than or equal to 30%, still further preferably greater than or equal to 40%. The upper limit of the reflectance is preferably less than or equal to 90%, further preferably less than or equal to 80%, still further preferably less than or equal to 70%. Furthermore, the transmittance of the semi-transmissive and semi-reflective conductive film for light with at least some wavelengths in the visible light range is preferably higher than or equal to 10%, further preferably higher than or equal to 20%, still further preferably higher than or equal to 30%. Specific examples of the semi-transmissive and semi-reflective conductive film include a film formed by co-evaporation such as an Ag:Mg (an alloy of silver and magnesium) film or an Mg:In (an alloy of magnesium and indium) film, and a film formed by co-evaporation of aluminum and an element belonging to Group 1 or 2 of the periodic table.

In order that the auxiliary electrode 106 can be formed stably and function sufficiently as the optical adjustment layer, the lower limit of the thickness of the auxiliary electrode 106 is preferably greater than or equal to 1 nm, further preferably greater than or equal to 5 nm, still further preferably greater than or equal to 10 nm. In the case where each light-emitting device has a micro optical resonator (microcavity) structure, a large thickness of the auxiliary electrode leads to a narrowed electroluminescence spectrum and improved color purity.

On the other hand, the auxiliary electrode 106 having an excessively large thickness might have an increased visible light absorptance, in which case the light extraction efficiency of the light-emitting device decreases. Thus, in order to prevent a decrease in light extraction efficiency, the upper limit of the thickness of the transparent conductive film that would be used for the auxiliary electrode 106 is preferably less than or equal to 200 nm, further preferably less than or equal to 100 nm, still further preferably less than or equal to 50 nm, yet still further preferably less than or equal to 30 nm. The thickness of the semi-transmissive and semi-reflective conductive film that would be used for the auxiliary electrode 106 is preferably less than or equal to 50 nm, further preferably less than or equal to 40 nm, still further preferably less than or equal to 30 nm, yet still further preferably less than or equal to 20 nm. In the case where a semi-transmissive and semi-reflective conductive film is used for each of the second electrode 102 and the auxiliary electrode 106, the thickness of a stack of the second electrode 102 and the auxiliary electrode 106 is preferably less than or equal to 50 nm, further preferably less than or equal to 40 nm, still further preferably less than or equal to 30 nm, yet still further preferably less than or equal to 20 nm. With such a thickness, the auxiliary electrode 106 can be inhibited from having an increased visible light absorptance while ensuring the function of the optical adjustment layer, increasing the light extraction efficiency of the light-emitting device.

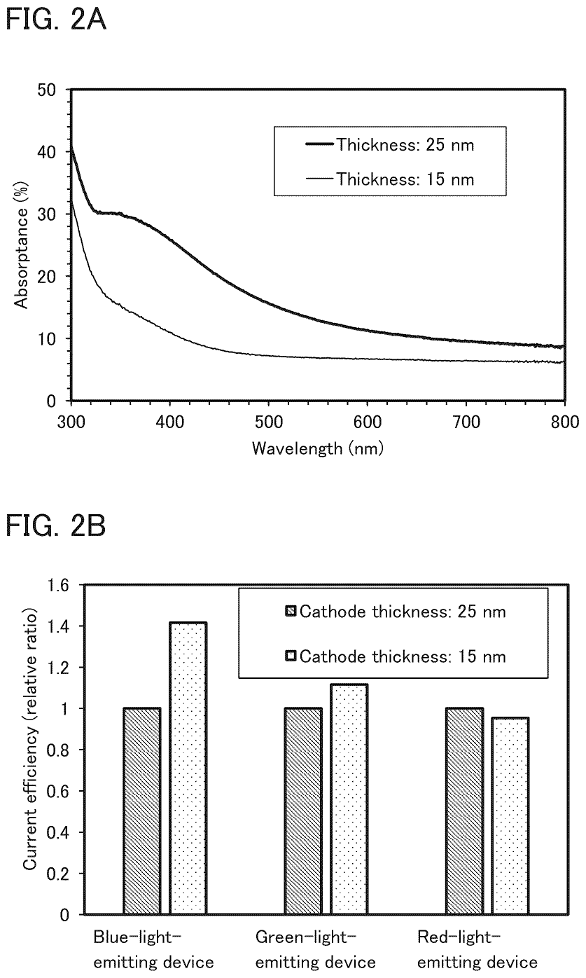

Note that the visible light absorptance of the conductive film having a light-transmitting property may depend on the wavelength of the light. FIG. 2A shows the light absorptance of Ag:Mg films (thickness: 15 nm and 25 nm) each formed by co-evaporation of Ag and Mg over a quartz substrate at a volume ratio of 1:0.1. The measurement was performed with an ultraviolet-visible spectrophotometer (U-4100 from Hitachi, Ltd.). Note that the absorptance in FIG. 2A represents the percentage of a value obtained by subtracting the intensity of transmitted light and the intensity of reflected light from the intensity of irradiated light, to the intensity of the irradiated light. As shown in FIG. 2A, the 25-nm-thick Ag:Mg film was found to have a higher absorptance than the 15-nm-thick Ag:Mg film. It was also found from FIG. 2A that the Ag—Mg films have a higher absorptance for light with a shorter wavelength. In the case where a material whose absorptance depends on the wavelength of light is used for the auxiliary electrodes 106R, 106G, and 106B, the thicknesses of the auxiliary electrodes 106R, 106G, and 106B are preferably different from each other to be optimal for the respective light-emitting devices.

In the case where the auxiliary electrodes 106R, 106G, and 106B are formed using a material that has a higher absorptance for light with a shorter wavelength, such as an Ag:Mg film, and the light-emitting devices 130R, 130G, and 130B emit red light, green light, and blue light, respectively, it is preferable that the thickness of the auxiliary electrode 106R be larger than the thickness of the auxiliary electrode 106G and the thickness of the auxiliary electrode 106G be larger than the thickness of the auxiliary electrode 106B as illustrated in FIG. 1B. In that case, the light-emitting devices can have increased light extraction efficiency.

As shown in FIG. 2A, the absorptances of the 15-nm-thick Ag:Mg film and the 25-nm-thick Ag:Mg film for red light (wavelength: 700 nm) are 6.49% and 9.56%, respectively; the absorptances of the 15-nm-thick Ag:Mg film and the 25-nm-thick Ag:Mg film for green light (wavelength: 546 nm) are 6.97% and 13.14%, respectively; and the absorptances of the 15-nm-thick Ag:Mg film and the 25-nm-thick Ag:Mg film for blue light (wavelength: 436 nm) are 8.70% and 21.47%, respectively. This shows that as the wavelength becomes shorter, the difference in absorptance between the 15-nm-thick Ag:Mg film and the 25-nm-thick Ag:Mg film becomes larger. It is thus found that the effect obtained by making the auxiliary electrode 106 thin is more significant when the wavelength is shorter.

In the case where the auxiliary electrode 106 is formed using a material that has a higher absorptance for light with a shorter wavelength, such as an Ag:Mg film, the thickness of each auxiliary electrode is preferably controlled such that the absorptance of the auxiliary electrode 106 for light of the emission color of the light-emitting device 130 is lower than or equal to 30%, further preferably lower than or equal to 10%, still further preferably lower than or equal to 5%.

In the case where the second electrode 102 and the auxiliary electrode 106 are each formed using a material that has a higher absorptance for light with a shorter wavelength, such as an Ag:Mg film, the thickness of each auxiliary electrode is preferably controlled such that the absorptance of the stack of the second electrode 102 and the auxiliary electrode 106 for light of the emission color of the light-emitting device is lower than or equal to 30%, further preferably lower than or equal to 10%, still further preferably lower than or equal to 5%.

Thus, in the case where the auxiliary electrode 106 is formed using an Ag:Mg film or the second electrode 102 and the auxiliary electrode 106 are each formed using an Ag:Mg film, it is further preferable that the thickness of the Ag:Mg film in the red-light-emitting device be less than or equal to 50 nm, less than or equal to 35 nm, or less than or equal to 20 nm, the thickness of the Ag:Mg film in the green-light-emitting device be less than or equal to 45 nm, less than or equal to 30 nm, or less than or equal to 15 nm, and the thickness of the Ag:Mg film in the blue-light-emitting device be less than or equal to 35 nm, less than or equal to 25 nm, or less than or equal to 15 nm. Note that in the case where the second electrode 102 and the auxiliary electrode 106 are each formed using an Ag:Mg film, the thickness of the Ag:Mg film refers to the thickness of the stack of the second electrode 102 and the auxiliary electrode 106. With such a structure, the light-emitting devices can have increased light extraction efficiency.

For specific description, FIG. 2B shows, as the results of simulating a change in current efficiency of the red-, green-, and blue-light-emitting devices due to a change in cathode thickness (which corresponds to the sum of the thickness of the second electrode 102 and the thickness of the auxiliary electrode 106 in this embodiment), the relative ratio of the current efficiency of each light-emitting device to the current efficiency of each light-emitting device including a 25-nm-thick cathode, which is set to 1. The simulation was performed with an organic EL and solar cell simulator (setfos from FLUXiM AG), assuming using Ag:Mg for the cathode. Note that the following discussion is on the efficiency of light emission in the direction perpendicular to the light-emitting surface.

As shown in FIG. 2B, the red-light-emitting device in which the cathode thickness is 25 nm has higher current efficiency than the red-light-emitting device in which the cathode thickness is 15 nm; the green-light-emitting device in which the cathode thickness is 15 nm has higher current efficiency than the green-light-emitting device in which the cathode thickness is 25 nm; and the blue-light-emitting device in which the cathode thickness is 15 nm has much higher current efficiency than the blue-light-emitting device in which the cathode thickness is 25 nm. It can be said that since the absorptance of an Ag:Mg film for red light is low, the red-light-emitting device with the larger cathode thickness achieves improved directivity of light in the direction perpendicular to the light-emitting surface owing to a microcavity structure and accordingly has the higher current efficiency. Meanwhile, since the absorptance of an Ag:Mg film for blue light is high, the blue-light-emitting device with the smaller cathode thickness suffers from less light absorption by the cathode and accordingly has the higher current efficiency.

When having the respective cathode thicknesses (or the respective auxiliary electrode thicknesses) as described above, the light-emitting devices of different colors can each have increased efficiency. Thus, in the display apparatus of one embodiment of the present invention, the efficiency of the light-emitting devices can be increased by separately forming the auxiliary electrodes in the light-emitting devices. The display apparatus can accordingly have low power consumption.

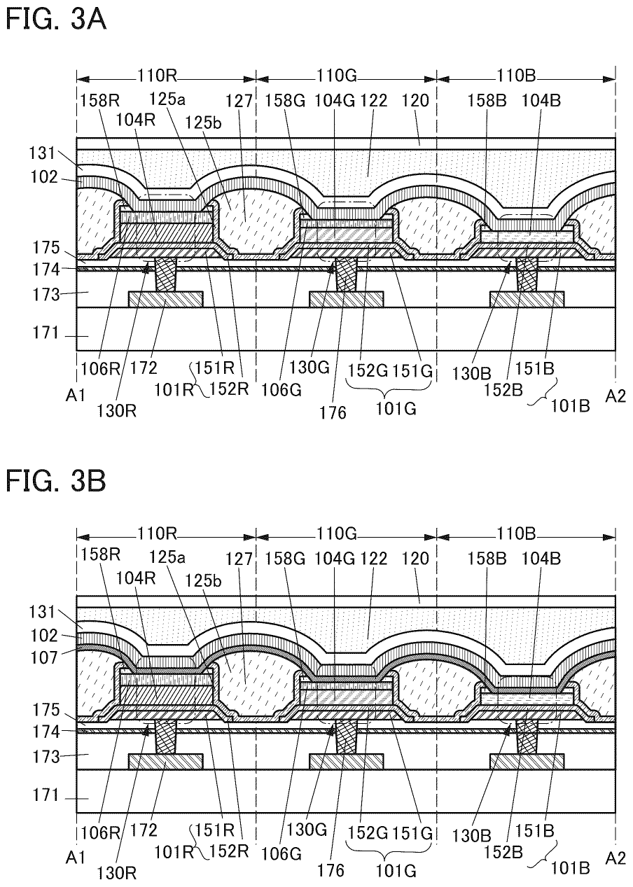

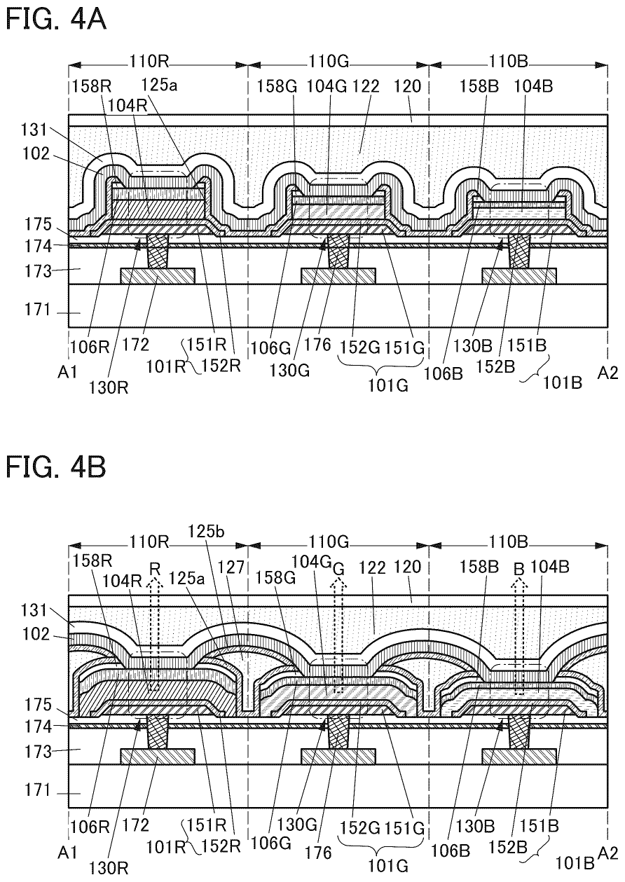

FIGS. 3A and 3B and FIGS. 4A and 4B illustrate variation examples of the cross-sectional view of the display apparatus in FIG. 1B.

The display apparatus of one embodiment of the present invention illustrated in FIG. 3A is different from the display apparatus illustrated in FIG. 1B in that the light-emitting device 130B does not include the auxiliary electrode 106B. In the case where the auxiliary electrode 106B is not provided, the second electrode 102 (common electrode) is located over the EL layer 104B in the light-emitting device 130B. In other words, the EL layer 104B of the light-emitting device 130B without the auxiliary electrode 106B is located between the first electrode 101B and the second electrode 102 and is in contact with the second electrode 102. The light extraction efficiency of each of the light-emitting devices can be increased also by employing the structure in which the auxiliary electrode 106 is provided in some of the light-emitting devices (here, the light-emitting devices 130R and 130G) and the auxiliary electrode 106 is not provided in the other light-emitting device (here, the light-emitting device 130B), as described above. Such a structure without the auxiliary electrode 106B can simplify the manufacturing process of the display apparatus and reduce the manufacturing cost.

In the case where an Ag:Mg film is used as each of the second electrode 102 (common electrode), the auxiliary electrode 106R, and the auxiliary electrode 106G, the upper limit of the thickness of the second electrode 102 (common electrode) is preferably less than or equal to 35 nm, less than or equal to 25 nm, or less than or equal to 15 nm; the upper limit of the thickness of the auxiliary electrode 106R in the red-light-emitting device 130R is preferably less than or equal to 15 nm, less than or equal to 10 nm, or less than or equal to 5 nm; and the upper limit of the thickness of the auxiliary electrode 106G in the green-light-emitting device 130G is preferably less than or equal to 10 nm, less than or equal to 5 nm, or less than or equal to 1 nm.

In each of the light-emitting devices 130 illustrated in FIG. 1B and FIG. 3A, when the uppermost layer of the EL layer 104 is an electron-injection layer or a charge-generation layer, electrons can be easily injected from the second electrode 102 (common electrode) into the EL layer 104, so that the driving voltage of the light-emitting devices 130 can be reduced. Typical examples of a material used for the electron-injection layer or the charge-generation layer include an alkali metal having a low work function such as lithium (Li), a compound of the alkali metal, an alkaline earth metal, and a compound of the alkaline earth metal. Note that using an alkali metal or a compound of the alkali metal for the uppermost layer of the EL layer 104B in the light-emitting device 130B without the auxiliary electrode 106B may cause a decrease in film quality of the EL layer 104B due to the influence of oxygen or water in the air, a chemical solution, or the like at the time of forming the EL layer 104B by a photolithography method or separating a sacrificial layer, in which case the light-emitting device 130B may have an increased driving voltage or reduced current efficiency.

Thus, in the display apparatus illustrated in FIG. 3A, an electron-injection layer that does not include an alkali metal or a compound of the alkali metal is preferably used as the uppermost layer of the EL layer 104B. The structure of the electron-injection layer that does not include an alkali metal or a compound of the alkali metal will be described in a later embodiment.

Although the light-emitting device 130B is not provided with an auxiliary electrode in the structure illustrated in FIG. 3A, one embodiment of the present invention is not limited thereto, and a structure in which the light-emitting device 130G is not provided with an auxiliary electrode may be employed.

FIG. 3B illustrates a variation example of the cross-sectional view of the display apparatus in FIG. 3A. The display apparatus of one embodiment of the present invention illustrated in FIG. 3B is different from the display apparatus illustrated in FIG. 3A in including a common layer 107.

In FIG. 3B, the light-emitting device 130R includes the first electrode 101R (pixel electrode) including the conductive layer 151R and the conductive layer 152R, the EL layer 104R over the first electrode 101R, the auxiliary electrode 106R over the EL layer 104R, the common layer 107 over the auxiliary electrode 106R, and the second electrode 102 (common electrode) over the common layer 107. In other words, the second electrode 102 is located over the common layer 107, the EL layer 104R is located between the first electrode 101R and the common layer 107, and the auxiliary electrode 106R is located between the EL layer 104R and the common layer 107, in the light-emitting device 130R.

In FIG. 3B, the light-emitting device 130G includes the first electrode 101G (pixel electrode) including the conductive layer 151G and the conductive layer 152G, the EL layer 104G over the first electrode 101G, the auxiliary electrode 106G over the EL layer 104G, the common layer 107 over the auxiliary electrode 106G, and the second electrode 102 (common electrode) over the common layer 107. In other words, the second electrode 102 is located over the common layer 107, the EL layer 104G is located between the first electrode 101G and the common layer 107, and the auxiliary electrode 106G is located between the EL layer 104G and the common layer 107, in the light-emitting device 130G.

In FIG. 3B, the light-emitting device 130B includes the first electrode 101B (pixel electrode) including the conductive layer 151B and the conductive layer 152B, the EL layer 104B over the first electrode 101B, the common layer 107 over the EL layer 104B, and the second electrode 102 (common electrode) over the common layer 107. In other words, the second electrode 102 is located over the common layer 107, the EL layer 104B is located between the first electrode 101B and the common layer 107, and the EL layer 104B is in contact with the common layer 107, in the light-emitting device 130B.

Hereinafter, description common to the conductive layers 151R, 151G, and 151B is sometimes made using a simple term “conductive layer 151”. Hereinafter, description common to the conductive layers 152R, 152G, and 152B is sometimes made using a simple term “conductive layer 152”.

In FIG. 3B, the common layer 107 is preferably an electron-injection layer. The common layer 107 is formed after processing for forming each EL layer is performed by a photolithography method and the sacrificial layer is removed, in the manufacturing process. Accordingly, the common layer 107 is not easily affected by oxygen or water in the air, a chemical solution, or the like, and thus, the range of choices for the material of the common layer 107 is wide. Even when the uppermost layer of the EL layer 104B is not an electron-injection layer, electrons can be easily injected from the second electrode 102 into the EL layer 104B through the common layer 107 that is an electron-injection layer, so that the driving voltage of the light-emitting device 130B can be reduced.

The common layer 107 is located between the auxiliary electrode 106R and the second electrode 102 in the light-emitting device 130R and between the auxiliary electrode 106B and the second electrode 102 in the light-emitting device 130B; thus, it is preferable that the common layer 107 not prevent electrical continuity between the auxiliary electrode 106 and the second electrode 102. For example, the thickness of the common layer 107 is preferably less than or equal to 10 nm, further preferably less than or equal to 5 nm, in which case electrical continuity between the auxiliary electrode 106 and the second electrode 102 is not prevented. Alternatively, a material having high conductivity is preferably used for the common layer 107.

The display apparatus of one embodiment of the present invention does not necessarily include the first insulating layer 127. The display apparatus illustrated in FIG. 4A is different from that illustrated in FIG. 1B in not including the first insulating layer 127. Omitting the first insulating layer 127 can reduce the manufacturing cost.

Although FIGS. 1A and 1B, FIGS. 3A and 3B, and FIG. 4A illustrate the structures in which end portions of the EL layer 104 and the auxiliary electrode 106 are located inward from end portions of the conductive layers 151 and 152 as the first electrode, one embodiment of the present invention is not limited thereto, and the end portions of the EL layer 104 and the auxiliary electrode 106 may be located outward from the end portions of the conductive layers 151 and 152. The display apparatus illustrated in FIG. 4B has a structure in which the end portions of the EL layer 104R and the auxiliary electrode 106R are located outward from the end portions of the conductive layers 151R and 152R, the end portions of the EL layer 104G and the auxiliary electrode 106G are located outward from the end portions of the conductive layers 151G and 152G, and the end portions of the EL layer 104B and the auxiliary electrode 106B are located outward from the end portions of the conductive layers 151B and 152B.

In the example illustrated in FIG. 4B, a third insulating layer 125b is provided over the first insulating layer 127. The third insulating layer 125b preferably has a structure similar to that of the second insulating layer 125a. Providing the third insulating layer 125b over the first insulating layer 127 separates the first insulating layer 127 from the second electrode 102 to inhibit at least one of oxygen and moisture from reaching the second electrode 102 and to increase the reliability of the display apparatus.

In the display apparatus of one embodiment of the present invention, the first electrodes (101R, 101G, and 101B) (pixel electrodes) of the light-emitting devices each preferably have a stacked-layer structure. For example, in the example illustrated in FIG. 1B, the first electrode 101R of the light-emitting device 130R is a stack of the conductive layer 151R on the insulating layer 171 side and the conductive layer 152R on the EL layer side. The first electrode 101G of the light-emitting device 130G is a stack of the conductive layer 151G on the insulating layer 171 side and the conductive layer 152G on the EL layer side. The first electrode 101B of the light-emitting device 130B is a stack of the conductive layer 151B on the insulating layer 171 side and the conductive layer 152B on the EL layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers that include different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that the end portion of the conductive layer 151 may have a tapered shape. Specifically, the end portion of the conductive layer 151 preferably has a tapered shape with a taper angle less than 90°. In that case, the conductive layer 152 provided along the side surface of the conductive layer 151 also has a tapered shape. When the side surface of the conductive layer 152 has a tapered shape, coverage with the EL layer 104 provided along the side surface of the conductive layer 152 can be improved. Note that the end portion of the conductive layer 151 does not necessarily have a tapered shape and may be substantially perpendicular to the substrate surface. In that case, the distance between adjacent EL layers can be short, and thus, the display apparatus can have a high aperture ratio.

The structure of this embodiment can be used in combination with any of the other structures as appropriate.

### Embodiment 2

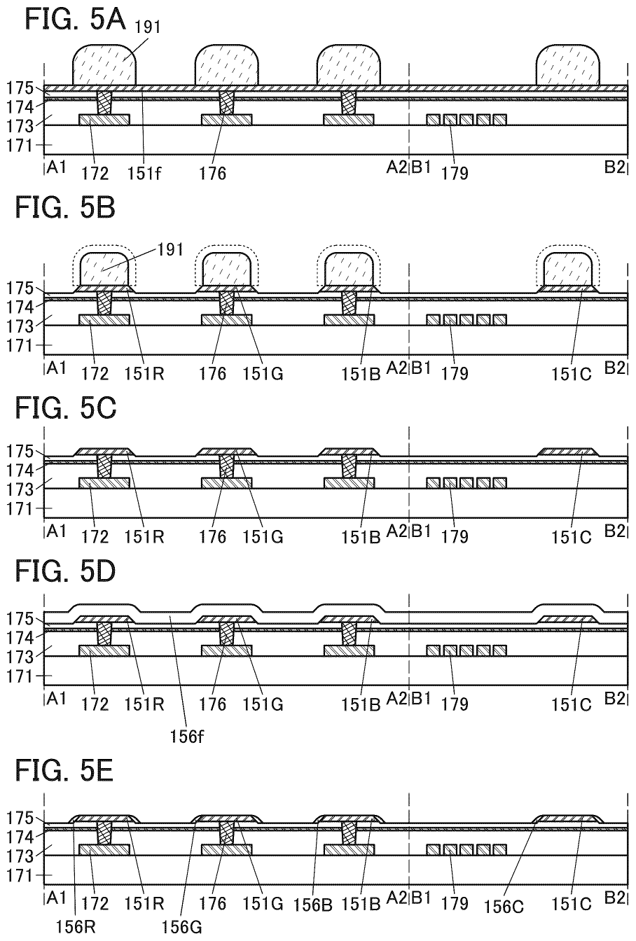

In this embodiment, an example method for manufacturing a display apparatus of one embodiment of the present invention will be described with reference to FIGS. 5A to 5E, FIGS. 6A to 6D, FIGS. 7A to 7D, FIGS. 8A to 8C, FIGS. 9A to 9C, and FIGS. 10A to 10C. Each of FIGS. 5A to 5E, FIGS. 6A to 6D, FIGS. 7A to 7D, FIGS. 8A to 8C, FIGS. 9A to 9C, and FIGS. 10A to 10C shows cross-sectional views taken along the dashed-dotted line A1-A2 and the dashed-dotted line B1-B2 in FIG. 1A for the description of the example manufacturing method.

Thin films included in the display apparatus (e.g., insulating films, semiconductor films, and conductive films) can be formed by a sputtering method, a CVD method, a vacuum evaporation method, a pulsed laser deposition (PLD) method, an ALD method, or the like.

Thin films included in the display apparatus (e.g., insulating films, semiconductor films, and conductive films) can also be formed by a wet film-formation method such as spin coating, dipping, spray coating, inkjetting, dispensing, screen printing, offset printing, doctor blade coating, slit coating, roll coating, curtain coating, or knife coating.

Thin films included in the display apparatus can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblasting method, or the like can be used.

First, as illustrated in FIG. 5A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 5A, openings reaching the conductive layer 172 are formed in the insulating layers 175, 174, and 173. Then, the plugs 176 are formed to fill the openings.

Next, as illustrated in FIG. 5A, a conductive film 151f to be the conductive layers 151R, 151G, 151B, and 151C is formed over the plugs 176 and the insulating layer 175. A metal material can be used for the conductive film 151f, for example.

Subsequently, a resist mask 191 is formed over the conductive film 151f as illustrated in FIG. 5A. The resist mask 191 can be formed by application of a photosensitive material (photoresist), light exposure, and development.

Subsequently, as illustrated in FIG. 5B, the conductive film 151f in a region not overlapping with the resist mask 191 is removed, for example. In this manner, the conductive layer 151 is formed.

Next, the resist mask 191 is removed as illustrated in FIG. 5C. The resist mask 191 can be removed by ashing using oxygen plasma, for example.

Then, as illustrated in FIG. 5D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film can be used; for example, a silicon oxynitride film can be used.

Subsequently, as illustrated in FIG. 5E, the insulating film 156f is processed to form the insulating layers 156R, 156G, 156B, and 156C.

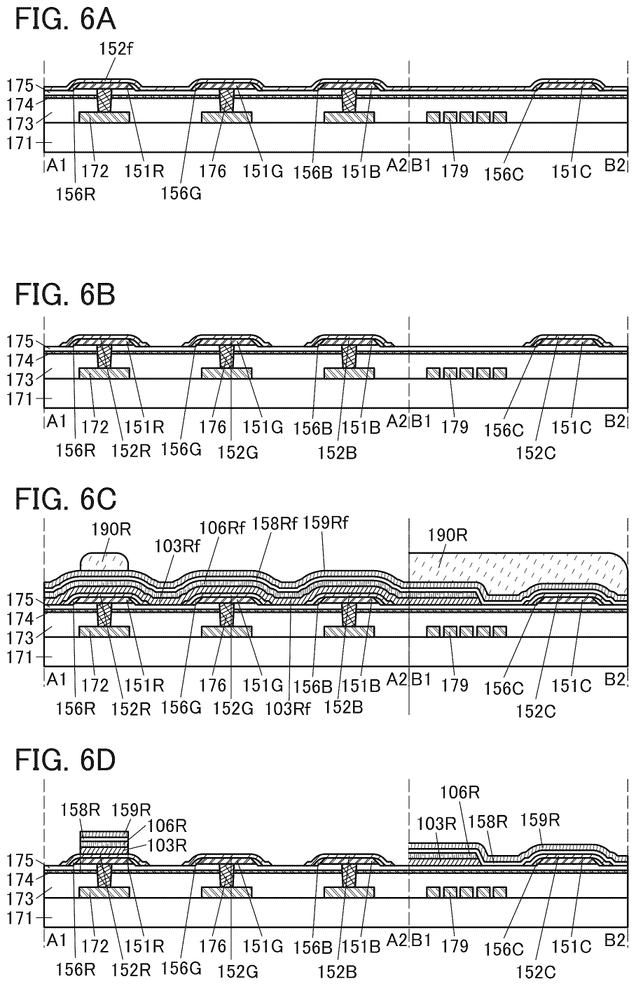

Then, as illustrated in FIG. 6A, a conductive film 152f is formed over the conductive layers 151R, 151G, 151B, and 151C and the insulating layers 156R, 156G, 156B, 156C, and 175.

A conductive oxide can be used for the conductive film 152f, for example. The conductive film 152f may have a stacked-layer structure.

Then, as illustrated in FIG. 6B, the conductive film 152f is processed to form the conductive layers 152R, 152G, and 152B and a conductive layer 152C.

Next, an organic compound film 103Rf is formed over the conductive layers 152R, 152G, and 152B and the insulating layer 175. As illustrated in FIG. 6C, the organic compound film 103Rf is not formed over the conductive layer 152C.

Next, as illustrated in FIG. 6C, a conductive film 106Rf, a protective film 158Rf, and a sacrificial film 159Rf are formed over the organic compound film 103Rf.

Providing the protective film 158Rf over the conductive film 106Rf can reduce damage to the organic compound film 103Rf and the conductive film 106Rf during the manufacturing process of the display apparatus, resulting in an increase in reliability of the light-emitting device.

As the protective film 158Rf, a film that is highly resistant to the process conditions for the organic compound film 103Rf and the conductive film 106Rf, specifically, a film having high etching selectivity with respect to the organic compound film 103Rf and the conductive film 106Rf is used. As the sacrificial film 159Rf, a film having high etching selectivity with respect to the protective film 158Rf and the conductive film 106Rf is used.

The protective film 158Rf and the sacrificial film 159Rf are formed at a temperature lower than the upper temperature limit of the organic compound film 103Rf. The typical substrate temperatures in formation of the protective film 158Rf and the sacrificial film 159Rf are each higher than or equal to 100° C. and lower than or equal to 200° C., preferably higher than or equal to 100° C. and lower than or equal to 150° C., further preferably higher than or equal to 100° C. and lower than or equal to 120° C.

The protective film 158Rf and the sacrificial film 159Rf are preferably films that can be removed by a wet etching method or a dry etching method.

Note that the protective film 158Rf, which is formed closer to the organic compound film 103Rf, is preferably formed by a formation method that is less likely to damage the organic compound film 103Rf than a formation method of the sacrificial film 159Rf. For example, the protective film 158Rf is preferably formed by an ALD method or a vacuum evaporation method rather than a sputtering method.

As each of the protective film 158Rf and the sacrificial film 159Rf, one or more of a metal film, an alloy film, a metal oxide film, a semiconductor film, an organic insulating film, and an inorganic insulating film, for example, can be used.

For each of the protective film 158Rf and the sacrificial film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the protective film 158Rf and the sacrificial film 159Rf, in which case the organic compound film 103Rf can be inhibited from being irradiated with ultraviolet rays in patterning light exposure, and deterioration of the organic compound film 103Rf can be inhibited.

The protective film 158Rf and the sacrificial film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The protective film 158Rf and the sacrificial film 159Rf are preferably formed using a semiconductor material such as silicon or germanium, for example, for excellent compatibility with a semiconductor manufacturing process. Alternatively, a compound containing the above semiconductor material can be used.

As each of the protective film 158Rf and the sacrificial film 159Rf, any of a variety of inorganic insulating films can be used. In particular, an oxide insulating film is preferable because its adhesion to the organic compound film 103Rf is higher than that of a nitride insulating film. A nitride insulating film, which is dense and has a high barrier property, is preferable. As the nitride insulating film, it is particularly preferable to use a silicon nitride film.

Next, a resist mask 190R is formed as illustrated in FIG. 6C. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display apparatus.

Next, part of the sacrificial film 159Rf is removed using the resist mask 190R, so that a sacrificial layer 159R is formed. The sacrificial layer 159R remains over the conductive layers 152R and 152C. After that, the resist mask 190R is removed. Then, part of the protective film 158Rf is removed using the sacrificial layer 159R as a mask (also referred to as a hard mask), so that the protective layer 158R is formed.

Using a wet etching method can reduce damage to the organic compound film 103Rf in processing of the protective film 158Rf and the sacrificial film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the protective film 158Rf, deterioration of the organic compound film 103Rf can be inhibited by not using a gas containing oxygen as the etching gas.

The resist mask 190R can be removed by a method similar to that for the resist mask 191.

Then, the conductive film 106Rf is processed to form the auxiliary electrode 106R. For example, part of the conductive film 106Rf is removed using the sacrificial layer 159R and the protective layer 158R as a hard mask to form the auxiliary electrode 106R.

Next, the organic compound film 103Rf is processed, so that an EL layer 103R is formed. For example, part of the organic compound film 103Rf is removed using the sacrificial layer 159R and the protective layer 158R as a hard mask to form the EL layer 103R.

Accordingly, as illustrated in FIG. 6D, a stack of the EL layer 103R, the auxiliary electrode 106R, the protective layer 158R, and the sacrificial layer 159R remains over the conductive layer 152R. The conductive layers 152G and 152B are exposed.

The organic compound film 103Rf and the conductive film 106Rf are preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

Next, an organic compound film 103Gf to be an EL layer 103G and a conductive film 106Gf to be the auxiliary electrode 106G are formed.

The organic compound film 103Gf can be formed by a method similar to that for forming the organic compound film 103Rf.

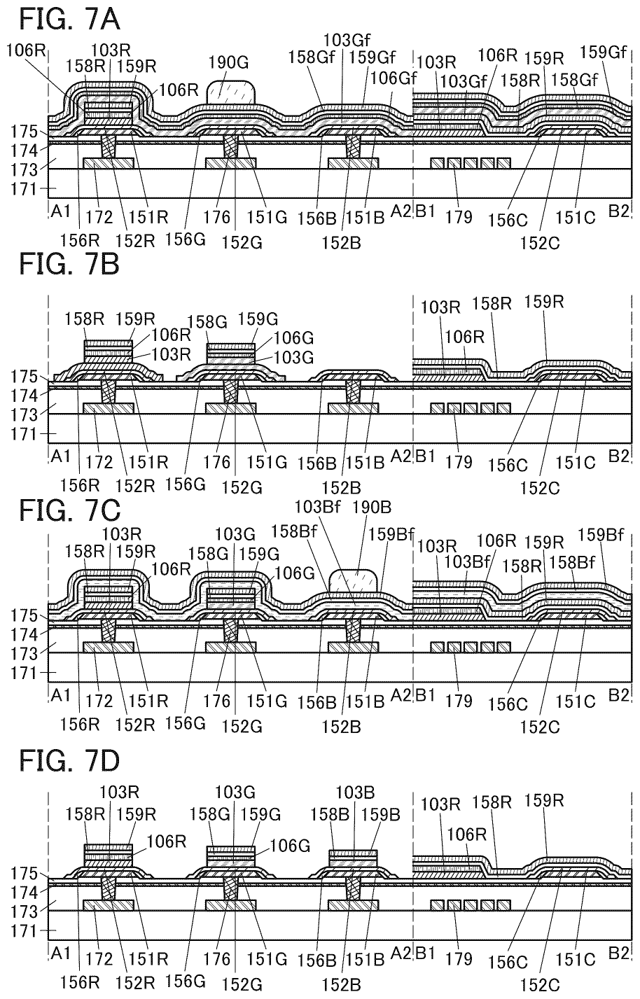

Subsequently, as illustrated in FIG. 7A, a protective film 158Gf and a sacrificial film 159Gf are formed in this order. After that, a resist mask 190G is formed. The materials and the formation methods of the protective film 158Gf and the sacrificial film 159Gf are similar to those of the protective film 158Rf and the sacrificial film 159Rf. The material and the formation method of the resist mask 190G are similar to those of the resist mask 190R.

The resist mask 190G is preferably provided at a position overlapping with the conductive layer 152G.

Subsequently, part of the sacrificial film 159Gf is removed using the resist mask 190G, so that a sacrificial layer 159G is formed. The sacrificial layer 159G remains over the conductive layer 152G. After that, the resist mask 190G is removed. Then, part of the protective film 158Gf is removed using the sacrificial layer 159G as a mask, so that the protective layer 158G is formed. Next, the organic compound film 103Gf is processed, so that the EL layer 103G is formed. Accordingly, as illustrated in FIG. 7B, a stack of the EL layer 103G, the auxiliary electrode 106G, the protective layer 158G, and the sacrificial layer 159G remains over the conductive layer 152G. The sacrificial layer 159R and the conductive layer 152B are exposed.

Then, an organic compound film 103Bf to be an EL layer 103B is formed as illustrated in FIG. 7C.

The organic compound film 103Bf can be formed by a method similar to that for forming the organic compound film 103Rf.

Subsequently, a protective film 158Bf and a sacrificial film 159Bf are formed in this order as illustrated in FIG. 7C. After that, a resist mask 190B is formed. The materials and the formation methods of the protective film 158Bf and the sacrificial film 159Bf are similar to those of the protective film 158Rf and the sacrificial film 159Rf. The material and the formation method of the resist mask 190B are similar to those of the resist mask 190R.

The resist mask 190B is provided at a position overlapping with the conductive layer 152B.

Subsequently, as illustrated in FIG. 7D, part of the sacrificial film 159Bf is removed using the resist mask 190B, so that a sacrificial layer 159B is formed. The sacrificial layer 159B preferably remains over the conductive layer 152B. After that, the resist mask 190B is removed. Then, part of the protective film 158Bf is removed using the sacrificial layer 159B as a mask, so that the protective layer 158B is formed. Next, the organic compound film 103Bf is processed, so that the EL layer 103B is formed. For example, part of the organic compound film 103Bf is removed using the sacrificial layer 159B and the protective layer 158B as a hard mask to form the EL layer 103B.

Accordingly, as illustrated in FIG. 7D, a stack of the EL layer 103B, the protective layer 158B, and the sacrificial layer 159B remains over the conductive layer 152B. The sacrificial layers 159R and 159G are exposed.

Note that the side surfaces of the EL layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the EL layers 103R, 103G, and 103B, which are formed by a photolithography method as described above, can be shortened to less than or equal to 8 μm, less than or equal to 5 μm, less than or equal to 3 μm, less than or equal to 2 μm, or less than or equal to 1 μm. Using a light exposure apparatus for LSI can further shorten the distance to less than or equal to 500 nm, less than or equal to 200 nm, less than or equal to 100 nm, or even less than or equal to 50 nm, for example. Here, the distance can be specified, for example, by the distance between opposite end portions of two adjacent layers among the EL layers 103R, 103G, and 103B. Shortening the distance between the island-shaped EL layers can provide a display apparatus having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, less than or equal to 2 μm, or less than or equal to 1 μm. Using a light exposure apparatus for LSI can further shorten the distance to less than or equal to 500 nm, less than or equal to 200 nm, less than or equal to 100 nm, or even less than or equal to 50 nm, for example.

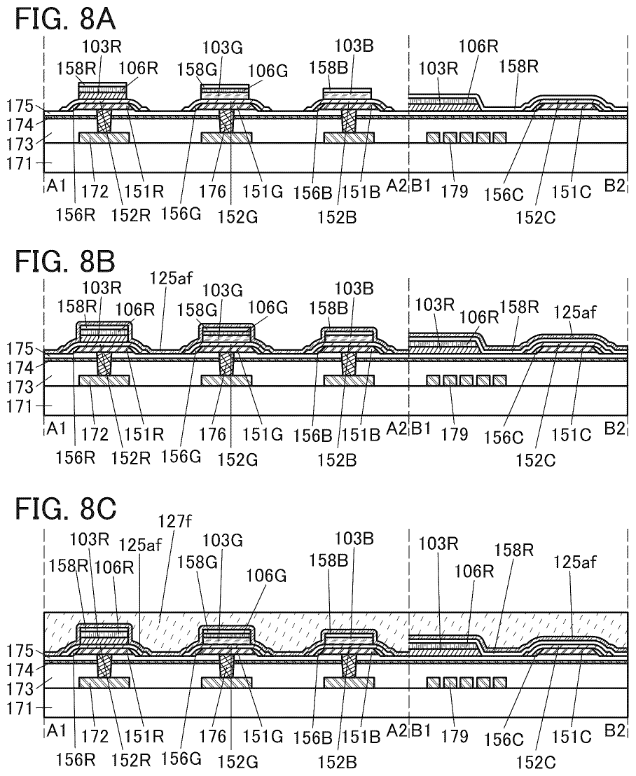

Next, as illustrated in FIG. 8A, the sacrificial layers 159R, 159G, and 159B are preferably removed.

The step of removing the sacrificial layers can be performed by a method similar to that for the step of processing the sacrificial films. Specifically, by using a wet etching method, damage applied to the EL layers 103R, 103G, and 103B at the time of removing the sacrificial layers can be reduced as compared to the case of using a dry etching method.

The sacrificial layers may be removed by being dissolved in a polar solvent such as water or an alcohol. Examples of an alcohol include ethyl alcohol, methyl alcohol, isopropyl alcohol (IPA), and glycerin.

After the sacrificial layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 8B, an insulating film 125af to be the second insulating layer 125a is formed.

Then, as illustrated in FIG. 8C, an insulating film 127f to be the first insulating layer 127 is formed over the insulating film 125af.

The insulating film 125af and the insulating film 127f are preferably formed by a formation method by which the EL layers are less damaged. In particular, the insulating film 125af, which is formed in contact with the side surfaces of the EL layers, is preferably formed by a formation method that causes less damage to the EL layers than the method for forming the insulating film 127f.

Each of the insulating film 125af and the insulating film 127f is formed at a temperature lower than the upper temperature limits of the EL layers. When the insulating film 125af is formed at a high substrate temperature, the formed insulating film 125af, even with a small thickness, can have a low impurity concentration and a high barrier property against at least one of water and oxygen.

The substrate temperature at the time of forming the insulating film 125af and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 125af, an insulating film having a thickness greater than or equal to 5 nm or greater than or equal to 10 nm and less than or equal to 200 nm, less than or equal to 150 nm, less than or equal to 100 nm, less than or equal to 50 nm, less than or equal to 30 nm, or less than or equal to 20 nm is preferably formed in the above-described range of the substrate temperature.

The insulating film 125af is preferably formed by an ALD method, for example. An ALD method is preferably used, in which case damage due to film formation is reduced and a film with good coverage can be formed. As the insulating film 125af, an aluminum oxide film is preferably formed by an ALD method. Alternatively, the insulating film 125af is preferably formed by a PEALD method. A PEALD method, which can form a film with good coverage and a high barrier property, is preferably used. As the insulating film 125af, a silicon nitride film is preferably formed by a PEALD method, for example. Alternatively, the insulating film 125af is preferably formed in the following manner: an aluminum oxide film is formed by an ALD method, and then, a silicon-based insulating film, which is particularly preferably a silicon nitride film, is formed by a PEALD method.

The insulating film 127f is preferably formed by the aforementioned wet film-formation method. The insulating film 127f is preferably formed by spin coating using a photosensitive material, for example, and specifically preferably formed using a photosensitive resin composition containing an acrylic resin.

Then, part of the insulating film 127f is exposed to visible light or ultraviolet rays. The first insulating layer 127 is formed in regions that are sandwiched between any two of the conductive layers 152R, 152G, and 152B and around the conductive layer 152C.

The width of the first insulating layer 127 that is to be formed later can be controlled in accordance with the exposed region of the insulating film 127f. In this embodiment, processing is performed such that the first insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

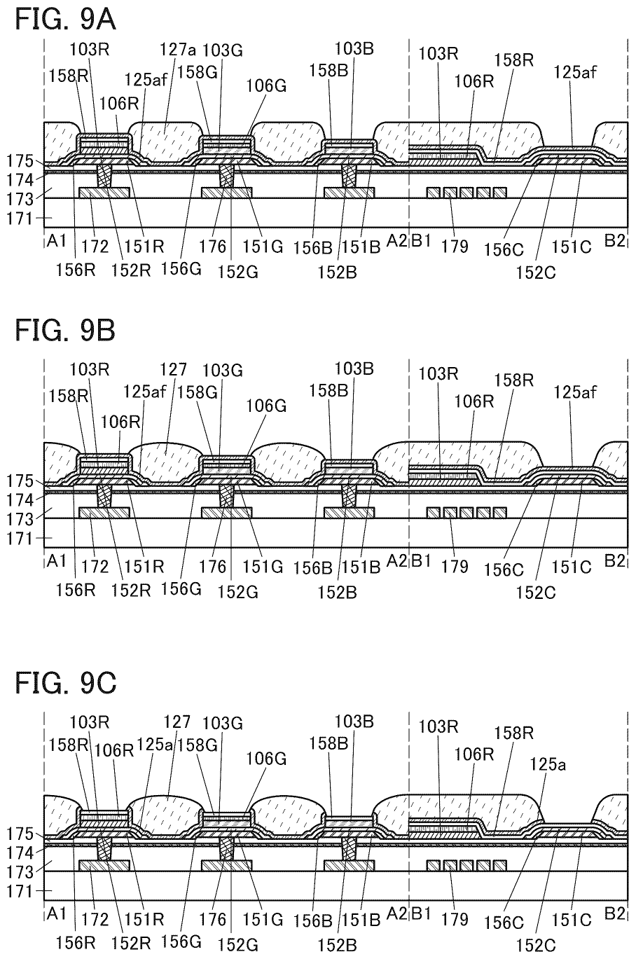

Next, as illustrated in FIG. 9A, development is performed to remove the exposed region of the insulating film 127f, so that a first insulating layer 127a is formed.

Next, the first insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the first insulating layer 127. In addition, it is sometimes possible to lower the substrate temperature required for subsequent heat treatment for changing the shape of the first insulating layer 127a to a tapered shape.

Here, when a barrier insulating layer against oxygen (e.g., an aluminum oxide film or a silicon nitride film) is present as each of the protective layers 158R, 158G, and 158B and the insulating film 125af, diffusion of oxygen into the EL layers 103R, 103G, and 103B can be inhibited.

Then, heat treatment (also referred to as post-baking) is performed. The heat treatment can change the first insulating layer 127a into the first insulating layer 127 having a tapered side surface (FIG. 9B). The heat treatment is performed at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. In that case, adhesion between the first insulating layer 127 and the second insulating layer 125a can be improved, and corrosion resistance of the first insulating layer 127 can be increased.

The protective layers 158R, 158G, and 158B and the insulating film 125af provided over the EL layers 103R, 103G, and 103B can prevent the EL layers 103R, 103G, and 103B from being damaged and deteriorating during the heat treatment. This increases the reliability of the light-emitting devices.

Next, a photomask is formed over the first insulating layer 127 and etching treatment is performed to remove part of the insulating film 125af. Thus, the second insulating layer 125a is formed under the first insulating layer 127 (FIG. 9C). Note that this etching treatment may be hereinafter referred to as first etching treatment.

The first etching treatment can be performed by dry etching or wet etching.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the EL layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. Alternatively, an acid solution containing a fluoride can also be used. In this case, puddle wet etching can be performed.

For the first etching treatment, an etching method that can secure high etching selectivity of the insulating film 125af over the protective layers 158R, 158G, and 158B is preferably used.

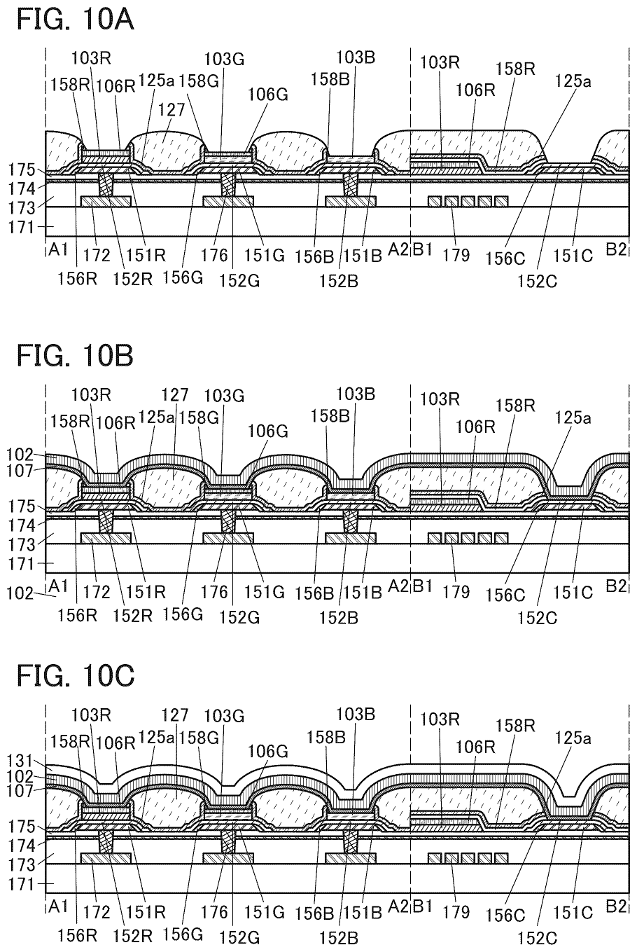

Next, as illustrated in FIG. 10A, etching treatment is performed using the second insulating layer 125a and the first insulating layer 127 as a mask to partly remove the protective layers 158R, 158G, and 158B. Thus, openings are formed in the protective layers 158R, 158G, and 158B, and the top surfaces of the auxiliary electrodes 106R and 106G, the EL layer 103B, and the conductive layer 152C are exposed. Note that this etching treatment may be hereinafter referred to as second etching treatment.

The second etching treatment is performed by wet etching. The use of a wet etching method can reduce damage to the auxiliary electrodes 106R and 106G and the EL layer 103B, as compared to the case of using a dry etching method. The wet etching can be performed using an alkaline solution or an acid solution, for example. An aqueous solution is preferably used in order that the EL layer 103B may not be dissolved.

Next, as illustrated in FIG. 10B, the common layer 107 and the second electrode 102 are formed over the auxiliary electrodes 106R and 106G, the EL layer 103B, the conductive layer 152C, and the first insulating layer 127. The common layer 107 and the second electrode 102 can be formed by a sputtering method, a vacuum evaporation method, or the like.

Next, as illustrated in FIG. 10C, the protective layer 131 is formed over the second electrode 102. The protective layer 131 can be formed by a vacuum evaporation method, a sputtering method, a CVD method, an ALD method, or the like. In particular, using a PEALD method enables formation of a film with a high barrier property at low temperatures.

Then, the substrate 120 is attached to the protective layer 131 using the resin layer 122, so that the display apparatus can be manufactured.

As described above, in the method for manufacturing the display apparatus of one embodiment of the present invention, the island-shaped EL layers 103R, 103G, and 103B are each formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the EL layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be obtained. Moreover, even a display apparatus that includes light-emitting devices formed by a photolithography method can have favorable characteristics.

The structure of this embodiment can be used in combination with any of the other structures as appropriate.

### Embodiment 3

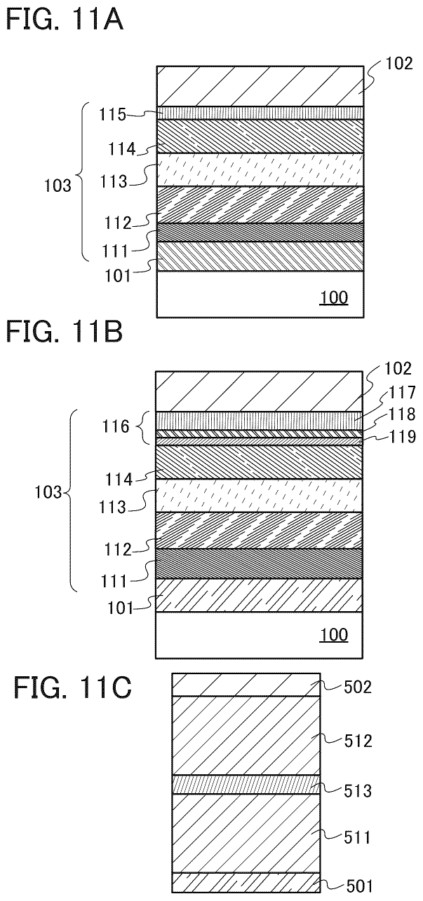

In this embodiment, structures of an organic EL element, which is a light-emitting device including an EL layer, are described with reference to FIGS. 11A to 11C. The organic EL element is a light-emitting device that includes an EL layer including a light-emitting layer between a first electrode 101 and the second electrode 102.

One of the first electrode 101 and the second electrode 102 functions as an anode and the other functions as a cathode. FIGS. 11A to 11C illustrate examples in which the first electrode 101 is an anode.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), a nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables a high resolution of several thousand ppi. Graphene can also be used for the anode. When a composite material that can be included in a hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the EL layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance with an electron-accepting property. Examples of the substance with an electron-accepting property include an organic compound having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylene-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance with an electron-accepting property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials with an electron-accepting property and an organic compound with a hole-transport property.

As the organic compound with a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound with a hole-transport property used in the composite material preferably has a hole mobility higher than or equal to 1×10⁻⁶ cm²/Vs. The organic compound with a hole-transport property used in the composite material preferably has a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound with a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound with a hole-transport property preferably has an N,N-bis(4-biphenyl)amino group to enable fabricating a light-emitting device with a long lifetime.

Specific examples of the organic compound with a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the material with a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances with an electron-accepting property, the organic compound with an electron-accepting property is easy to use because it is easily deposited by evaporation.

A hole-transport layer 112 is formed using an organic compound with a hole-transport property. The organic compound with a hole-transport property preferably has a hole mobility higher than or equal to 1×10⁻⁶ cm²/Vs.

Examples of the material with a hole-transport property include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, or 9-[4-(9-phenyl-9H-carbazol-3-yl)phenyl]phenanthrene (abbreviation: PCPPn); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferably used because the compound is highly reliable and has a high hole-transport property to contribute to a reduction in driving voltage. Note that any of the substances given as examples of the material with a hole-transport property used in the composite material for the hole-injection layer 111 can also be suitably used as the material included in the hole-transport layer 112.

A light-emitting layer 113 is a layer including a light-emitting substance and preferably includes a light-emitting substance and a host material. The light-emitting layer 113 may additionally include other materials. Alternatively, the light-emitting layer 113 may be a stack of two layers with different compositions.

The light-emitting substance may be a fluorescent substance, a phosphorescent substance, a substance exhibiting thermally activated delayed fluorescence (TADF), or any other light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPm, and 1,6BnfAPrn-03 are particularly preferable because of their high hole-trapping properties, high emission efficiency, or high reliability.

A fused heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(diphenyl-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N′-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-k]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-{1-[2,6-bis(1-methylethyl)phenyl]-1H-imidazol-2-yl-κN³}-4-cyanophenyl-κC)iridium(III) (abbreviation: CNImIr); an organometallic complex having a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds emit blue phosphorescent light and have an emission peak in the wavelength range from 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-KC]bis[2-(2-pyridinyl-κN)phenyl-κC]iridium(III) (abbreviation: [Ir(ppy)₂(mbfpypy-d₃)]), tris{2-[5-(methyl-d₃)-4-phenyl-2-pyridinyl-N]phenyl-κC}iridium(III) (abbreviation: [Ir(5m4dppy-d₃)₃]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-KN)benzofuro[2,3-b]pyridine-κC]bis[2-(2-pyridinyl-κN)phenyl-κC]iridium(III) (abbreviation: [Ir(ppy)₂(mbfpypy)]), or [2-(4-methyl-5-phenyl-2-pyridinyl-κN)phenyl-κC]bis[2-(2-pyridinyl-KN)phenyl-κC]iridium(III) (abbreviation: [Ir(ppy)₂(mdppy)]); and a rare earth metal complex such as tris(acetylacetonato)(monophenanthroline)terbium(III) (abbreviation: [Tb(acac)₃(Phen)]). These are mainly compounds that emit green phosphorescent light and have an emission peak in the wavelength range from 500 nm to 600 nm. Note that organometallic iridium complexes including a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), or (3,7-diethyl-4,6-nonanedionato-κO⁴,κO⁶)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

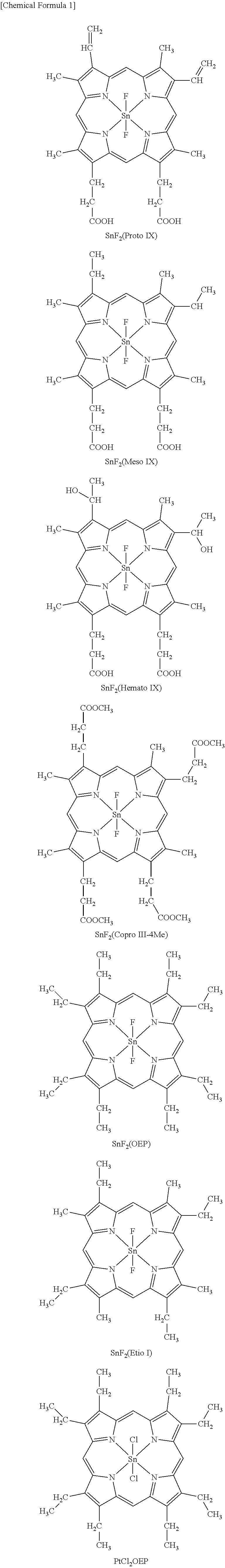

Alternatively, a heterocyclic compound having one or both of a π-electron rich heteroaromatic ring and a π-electron deficient heteroaromatic ring and represented by any of the following structure formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having high electron-transport and hole-transport properties owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting properties and high reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the Ti level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

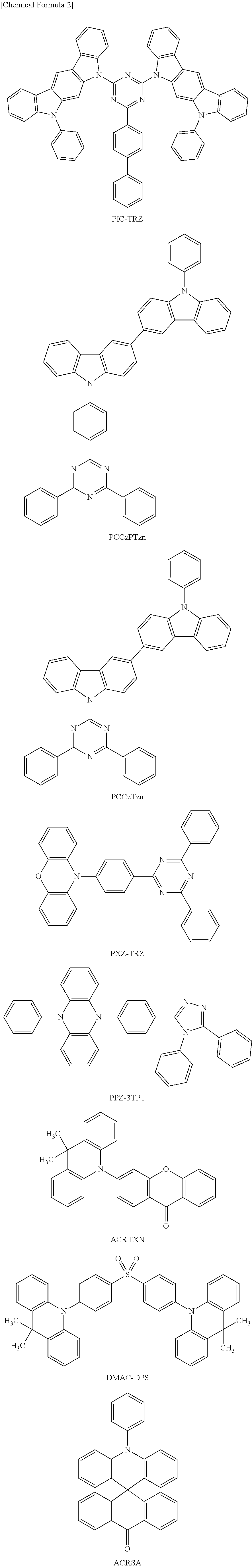

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as materials with an electron-transport property and/or materials with a hole-transport property, and the TADF materials can be used.

The material with a hole-transport property is preferably an organic compound having an amine skeleton or a π-electron rich heteroaromatic ring skeleton, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferably used; specifically, a carbazole ring, a dibenzothiophene ring, or a ring in which an aromatic ring or a heteroaromatic ring is further fused to a carbazole ring or a dibenzothiophene ring is preferably used.

Such an organic compound with a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound with a hole-transport property preferably has an N,N-bis(4-biphenyl)amino group to enable fabricating a light-emitting device with a long lifetime.

Examples of such an organic compound include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9,9′-diphenyl-9H,9′H-3,3′-bicarbazole (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material with a hole-transport property that can be used for the hole-transport layer can also be used.

As the material with an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring skeleton is preferably used. Examples of the organic compound having a π-electron deficient heteroaromatic ring skeleton include an organic compound that includes a heteroaromatic ring having a polyazole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high electron-accepting properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound that includes a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 8-(1,1′: 4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound that includes a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn). The organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on the lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further fused to a carbazole skeleton, because the HOMO level of the host material having a benzocarbazole skeleton is shallower than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is shallower than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material with an electron-transport property and a material with a hole-transport property. By mixing the material with an electron-transport property and the material with a hole-transport property, the transport property of the light-emitting layer 113 can be easily adjusted and a recombination region can be easily controlled. The weight ratio of the content of the material with a hole-transport property to the content of the material with an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on the lowest-energy-side absorption band of the light-emitting substance, in which case energy can be transferred smoothly and light emission can be obtained efficiently. Such a structure is preferably used to reduce the driving voltage.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by, for example, comparing the emission spectra of the material having a hole-transport property, the material having an electron-transport property, and the mixed film of these materials, and observing the phenomenon in which the emission spectrum of the mixed film is shifted to the longer wavelength side than the emission spectrum of each of the materials (or has another peak on the longer wavelength side). Alternatively, the formation of an exciplex can be confirmed by comparing the transient photoluminescence (PL) of the material having a hole-transport property, the transient PL of the material having an electron-transport property, and the transient PL of the mixed film of the materials, and observing a difference in transient response, such as a phenomenon in which the transient PL lifetime of the mixed film has more long lifetime components or has a larger proportion of delayed components than that of each of the materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

An electron-transport layer 114 includes a substance with an electron-transport property. The substance with an electron-transport property preferably has an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property. An organic compound having a π-electron deficient heteroaromatic ring skeleton is preferably used. Examples of the organic compound having a π-electron deficient heteroaromatic ring skeleton include an organic compound that includes a heteroaromatic ring having a polyazole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton. Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of such an organic compound include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound that includes a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 8-(1,1′: 4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound that includes a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn). Among these examples, it is preferable to use an organic compound that does not include a fused aromatic ring consisting only of six-membered rings; or an organic compound that does not have a structure in which two or more adjacent six-membered aromatic hydrocarbon rings are fused, a structure in which two or more adjacent six-membered heteroaromatic rings are fused, or a structure in which one or more six-membered aromatic hydrocarbon rings and one or more six-membered heteroaromatic rings that are adjacent to each other are fused.

Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. The organic compound that includes a heteroaromatic ring having a diazine (pyrimidine or pyrazine) skeleton and the organic compound that includes a heteroaromatic ring having a triazine skeleton are particularly preferable because these organic compounds have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of high stability.

Note that the electron-transport layer 114 may have a stacked-layer structure. A layer that is included in the stacked-layer structure of the electron-transport layer 114 and that is in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than a material included in the light-emitting layer 113 by greater than or equal to 0.5 eV.

As an electron-injection layer 115, a layer that includes a compound or a complex of an alkali metal or an alkaline earth metal such as lithium fluoride, 8-hydroxyquinolinato-lithium (abbreviation: Liq), or a mixed material of lithium fluoride and ytterbium; a mixture of any of these; 1,1′-pyridine-2,6-diyl-bis(1,3,4,6,7,8-hexahydro-2H-pyrimido[1,2-a]pyrimidine) (abbreviation: hpp2Py); or the like may be provided. The electron-injection layer 115 may be a layer that is formed using a substance with an electron-transport property and includes any of the above substances.

Instead of the electron-injection layer 115, a charge-generation layer 116 may be provided (FIG. 11B). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film including the above-described acceptor material as a material included in the composite material and a film including a hole-transport material. When a potential is applied to the p-type layer 117, electrons are injected into the electron-transport layer 114 and holes are injected into the cathode; thus, the organic EL element operates.

Note that the charge-generation layer 116 preferably includes one or both of an electron-relay layer 118 and an electron-injection buffer layer 119 in addition to the p-type layer 117.

The electron-relay layer 118 includes at least a substance with an electron-transport property and has a function of preventing an interaction between the electron-injection buffer layer 119 and the p-type layer 117 and smoothly transferring electrons. The LUMO level of the substance with an electron-transport property included in the electron-relay layer 118 is preferably between the LUMO level of the acceptor substance in the p-type layer 117 and the LUMO level of a substance in a layer that is included in the electron-transport layer 114 and that is in contact with the charge-generation layer 116. As a specific value of the energy level, the LUMO level of the substance with an electron-transport property in the electron-relay layer 118 is preferably higher than or equal to −5.0 eV, further preferably higher than or equal to −5.0 eV and lower than or equal to −3.0 eV. Note that as the substance with an electron-transport property in the electron-relay layer 118, a phthalocyanine-based material such as phthalocyanine (abbreviation: H₂Pc), copper phthalocyanine (abbreviation: CuPc), or zinc phthalocyanine (abbreviation: ZnPc) or a metal complex having a metal-oxygen bond and an aromatic ligand is preferably used.

The electron-injection buffer layer 119 can be formed using a substance with a high electron-injection property, e.g., an alkali metal, an alkaline earth metal, a rare earth metal, or a compound thereof (an alkali metal compound (including an oxide such as lithium oxide, a halide such as lithium fluoride, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 includes a substance with an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide such as lithium fluoride, and a carbonate such as lithium carbonate or cesium carbonate), an alkaline earth metal compound (including an oxide, a halide, and a carbonate), or a rare earth metal compound (including an oxide, a halide, and a carbonate)). As the substance with an electron-transport property, a material similar to the above-described material included in the electron-transport layer 114 can be used.

Note that an auxiliary electrode is preferably provided between the electron-injection layer 115 and the second electrode 102 or between the charge-generation layer 116 and the second electrode 102 as described in Embodiment 1, in which case optical adjustment can be performed.

The second electrode 102 is an electrode including a cathode. The second electrode 102 may have a stacked-layer structure, in which case a layer in contact with the EL layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Group 1 or 2 of the periodic table, such as alkali metals (e.g., lithium (Li) or cesium (Cs)), magnesium (Mg), calcium (Ca), and strontium (Sr), alloys containing these elements (e.g., Mg:Ag and Al:Li), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, any of a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an inkjet method, a spin coating method, or the like. Alternatively, a wet process using a sol-gel method or a wet process using a paste of a metal material may be employed.

The EL layer 103 can be formed by any of a variety of methods, including a dry process and a wet process. For example, a vacuum evaporation method, a gravure printing method, an offset printing method, a screen printing method, an inkjet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem-type element) is described with reference to FIG. 11C. This organic EL element includes a plurality of light-emitting units between an anode and a cathode. One light-emitting unit has substantially the same structure as the EL layer 103 illustrated in FIG. 11A. In other words, the organic EL element illustrated in FIG. 11C includes a plurality of light-emitting units, and the organic EL element illustrated in FIG. 11A or 11B includes one light-emitting unit.

In FIG. 11C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 11A, and can be formed using the materials given in the description for FIG. 11A. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 11C, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 11B. A composite material of an organic compound and a metal oxide enables low-voltage driving and low-current driving because of having an excellent carrier-injection property and an excellent carrier-transport property. In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as the electron-injection layer in the light-emitting unit on the anode side; thus, an electron-injection layer is not necessarily formed in the light-emitting unit on the anode side.

The organic EL element having two light-emitting units has been described with reference to FIG. 11C; however, one embodiment of the present invention can also be applied to an organic EL element in which three or more light-emitting units are stacked. When a plurality of light-emitting units partitioned by the charge-generation layer 513 are provided between a pair of electrodes as in the organic EL element of this embodiment, it is possible to provide a long-life element that can emit light with high luminance at a low current density. A display apparatus that can be driven at a low voltage and has low power consumption can also be provided.

When the emission colors of the light-emitting units are different, light emission of a desired color can be obtained from the organic EL element as a whole. For example, in an organic EL element having two light-emitting units, the emission colors of the first light-emitting unit may be red and green and the emission color of the second light-emitting unit may be blue, so that the organic EL element can emit white light as a whole.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an inkjet method), a coating method, or a gravure printing method. A low molecular material, a middle molecular material (including an oligomer and a dendrimer), or a high molecular material may be included in the above components.

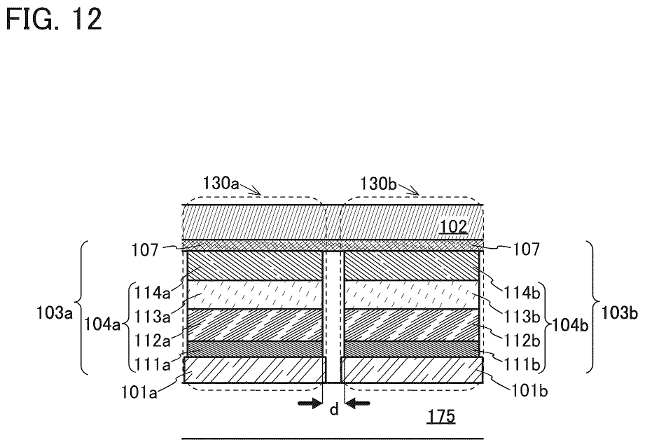

FIG. 12 illustrates two adjacent light-emitting devices (a light-emitting device 130a and a light-emitting device 130b) among a group of the light-emitting devices 130 included in the display apparatus of one embodiment of the present invention. Note that the display apparatus includes a plurality of first electrodes (101a and 101b) formed over the insulating layer 175, the second electrode 102, a plurality of EL layers (104a and 104b), and the common layer 107; in each of the light-emitting devices, at least the first electrode (101a or 101b), the EL layer (104a or 104b), the common layer 107, and the second electrode 102 overlap with each other.

The light-emitting device 130a includes an EL layer 103a between the first electrode 101a over the insulating layer 175 and the second electrode 102 facing the first electrode 101a. The EL layer 103a includes a hole-injection layer 111a, a hole-transport layer 112a, a light-emitting layer 113a, an electron-transport layer 114a, and the common layer 107, but may have a different stacked-layer structure. The EL layer 103a includes the EL layer 104a that is separate from an EL layer of another light-emitting device, and may further include the common layer 107 shared by a plurality of light-emitting devices. In FIG. 12, the hole-injection layer 111a, the hole-transport layer 112a, the light-emitting layer 113a, and the electron-transport layer 114a correspond to the EL layer 104a. Note that a structure may be employed in which a layer having the same function as the common layer is separately provided in the light-emitting devices and the common layer 107 is not provided.

The light-emitting device 130b includes an EL layer 103b between the first electrode 101b over the insulating layer 175 and the second electrode 102 facing the first electrode 101b. The EL layer 103b includes a hole-injection layer 111b, a hole-transport layer 112b, a light-emitting layer 113b, an electron-transport layer 114b, and the common layer 107, but may have a different stacked-layer structure. In FIG. 12, the hole-injection layer 111b, the hole-transport layer 112b, the light-emitting layer 113b, and the electron-transport layer 114b correspond to the EL layer 104b. Note that a structure may be employed in which a layer having the same function as the common layer is separately provided in the light-emitting devices and the common layer 107 is not provided.

The second electrode 102 is preferably one layer (common layer) shared by the light-emitting device 130a and the light-emitting device 130b. The layers other than the common layer 107 included in the EL layers 103a and 103b, i.e., the EL layers 104a and 104b, are independent layers because these layers are formed by processing using a photolithography method after the electron-transport layer 114a is formed and after the electron-transport layer 114b is formed. End portions (outlines) of the layers other than the common layer 107 included in the EL layer 103a are substantially aligned in the direction perpendicular to the substrate due to the processing by a lithography method. End portions (outlines) of the layers other than the common layer 107 included in the EL layer 103b are substantially aligned in the direction perpendicular to the substrate due to the processing by a lithography method.

Since the EL layers are formed by processing using a photolithography method, a distance d between the first electrodes 101a and 101b can be shorter than that in the case of employing mask vapor deposition; the distance d can be longer than or equal to 50 nm and shorter than or equal to 5 μm.

Note that the structure described in this embodiment can be used in combination with any of the structures described in the other embodiments as appropriate.

### Embodiment 4

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, desktop and notebook personal computers, a monitor of a computer and the like, digital signage, and a large game machine such as a pachinko machine.

### [Display Module]

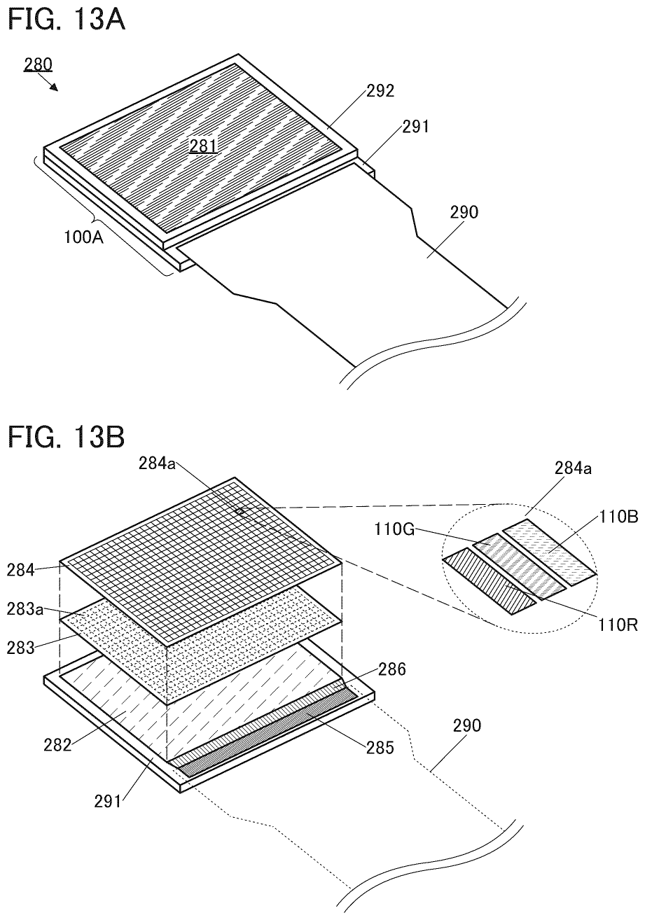

FIG. 13A is a perspective view of a display module 280. The display module 280 includes a display apparatus 100A and an FPC 290. Note that the display apparatus included in the display module 280 is not limited to the display apparatus 100A and may be any of display apparatuses 100B and 100D described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 13B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 13B. The pixels 284a can employ any of the structures described in the above embodiments. FIG. 13B illustrates an example where the pixel 284a has a structure similar to that of the pixel 178 illustrated in FIGS. 1A and 1B.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Apparatus 100A]

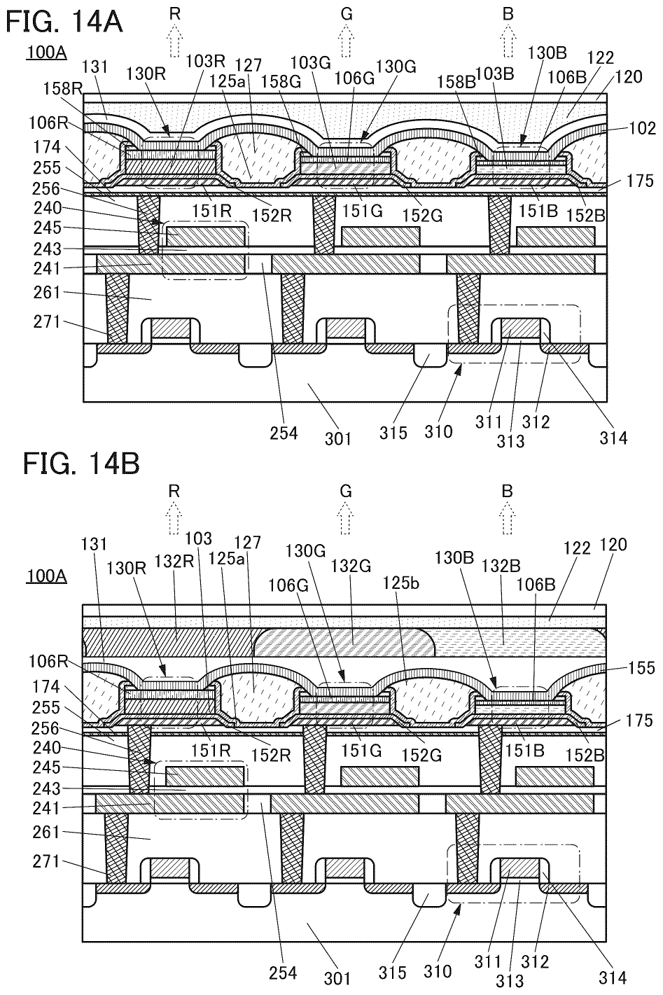

The display apparatus 100A illustrated in FIG. 14A includes a substrate 301, the light-emitting devices 130R, 130G, and 130B, a capacitor 240, and a transistor 310.

The substrate 301 corresponds to the substrate 291 in FIGS. 13A and 13B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided so as to be embedded in the substrate 301 between two of the transistors 310 that are adjacent to each other.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between the adjacent light-emitting devices.

The auxiliary electrode 106R is located over the EL layer 103R. The protective layer 158R is located over the auxiliary electrode 106R. The auxiliary electrode 106G is located over the EL layer 103G. The protective layer 158G is located over the auxiliary electrode 106G. The auxiliary electrode 106B is located over the EL layer 103B. The protective layer 158B is located over the auxiliary electrode 106B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is attached to the protective layer 131 with the resin layer 122. Other embodiments can be referred to for the details of the light-emitting device 130 and the components thereover up to the substrate 120. The substrate 120 corresponds to the substrate 292 in FIG. 13A.

FIG. 14B illustrates a variation example of the display apparatus 100A illustrated in FIG. 14A. The display apparatus illustrated in FIG. 14B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 14B, the light-emitting device 130 can emit white light, for example. The coloring layer 132R, the coloring layer 132G, and the coloring layer 132B can transmit red light, green light, and blue light, respectively, for example.

### [Display Apparatus 100B]

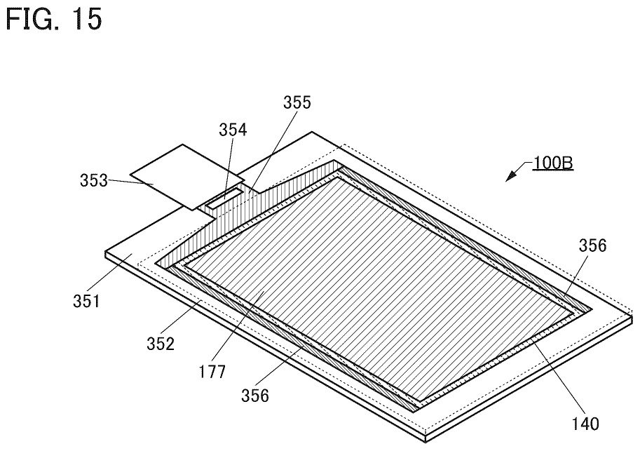

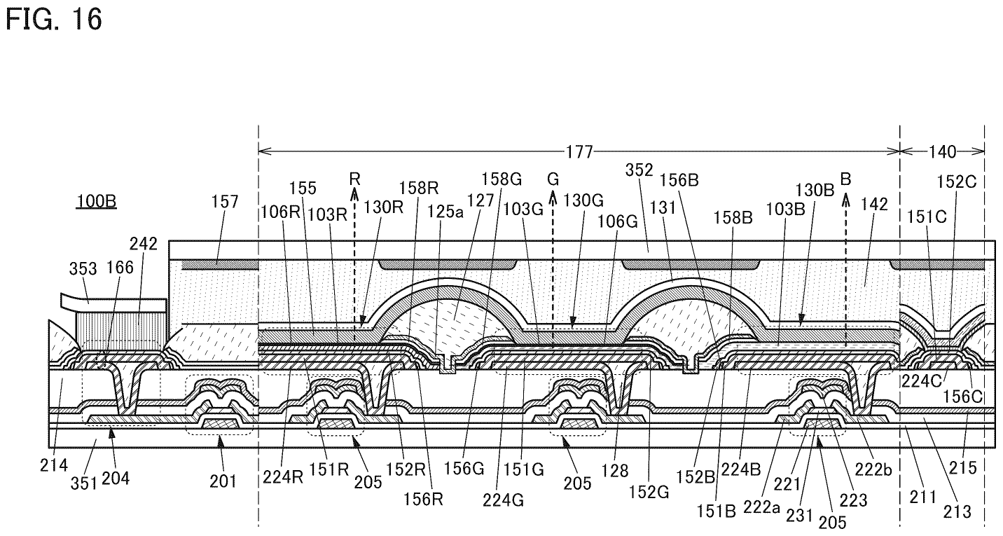

FIG. 15 is a perspective view of the display apparatus 100B, and FIG. 16 is a cross-sectional view of the display apparatus 100B.

In the display apparatus 100B, a substrate 352 and a substrate 351 are bonded to each other. In FIG. 15, the substrate 352 is denoted by a dashed line.

The display apparatus 100B includes the pixel portion 177, the connection portion 140, a circuit 356, a wiring 355, and the like. FIG. 15 illustrates an example in which an IC 354 and an FPC 353 are mounted on the display apparatus 100B. Thus, the structure illustrated in FIG. 15 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 15 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 16 illustrates an example of cross sections of part of a region including the FPC 353, part of the circuit 356, part of the pixel portion 177, part of the connection portion 140, and part of a region including an end portion of the display apparatus 100B.

### [Display Apparatus 100B]

The display apparatus 100B illustrated in FIG. 16 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiments 1 to 3 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is located outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering the opening provided in the insulating layer 214. A layer 128 is embedded in the depression portion.

The layer 128 has a function of filling the depression portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the first insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 16, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided so as not to overlap with the light-emitting device. Alternatively, the space may be filled with a resin other than the frame-like adhesive layer 142.

FIG. 16 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 16, the insulating layer 156C is provided to include a region overlapping with the side surface of the conductive layer 151C.

The display apparatus 100B has a top-emission structure. Light from the light-emitting device is emitted toward the substrate 352. For the substrate 352, a material with a high visible-light-transmitting property is preferably used. In the case where the light-emitting device emits infrared or near-infrared light, a material with a high transmitting property with respect to infrared or near-infrared light is preferably used. The pixel electrode includes a material that reflects visible light, and the counter electrode (common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable for the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 that does not overlap with the substrate 352. In the connection portion 204, the source electrode or the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between the adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

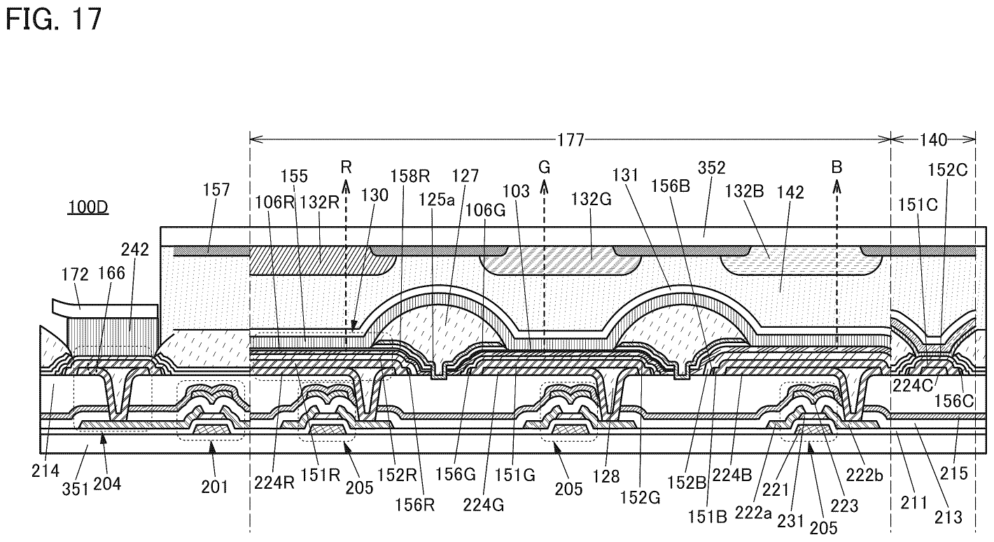

The display apparatus 100D illustrated in FIG. 17 is a variation example of the display apparatus 100B illustrated in FIG. 16 and differs from the display apparatus 100B mainly in including the coloring layers 132R, 132G, and 132B.

In the display apparatus 100D, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display apparatus 100D, the light-emitting device 130 can emit white light, for example. The coloring layer 132R, the coloring layer 132G, and the coloring layer 132B can transmit red light, green light, and blue light, respectively, for example. Note that in the display apparatus 100D, the coloring layers 132R, 132G, and 132B may be provided between the protective layer 131 and the adhesive layer 142.

Although FIG. 16, FIG. 17, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are described in one embodiment, the structure examples can be combined as appropriate.

### Embodiment 5

In this embodiment, electronic devices of embodiments of the present invention will be described.

Electronic devices of this embodiment include the display apparatus of one embodiment of the present invention in their display portions. The display apparatus of one embodiment of the present invention has high display performance and can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display apparatus of one embodiment of the present invention can have high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

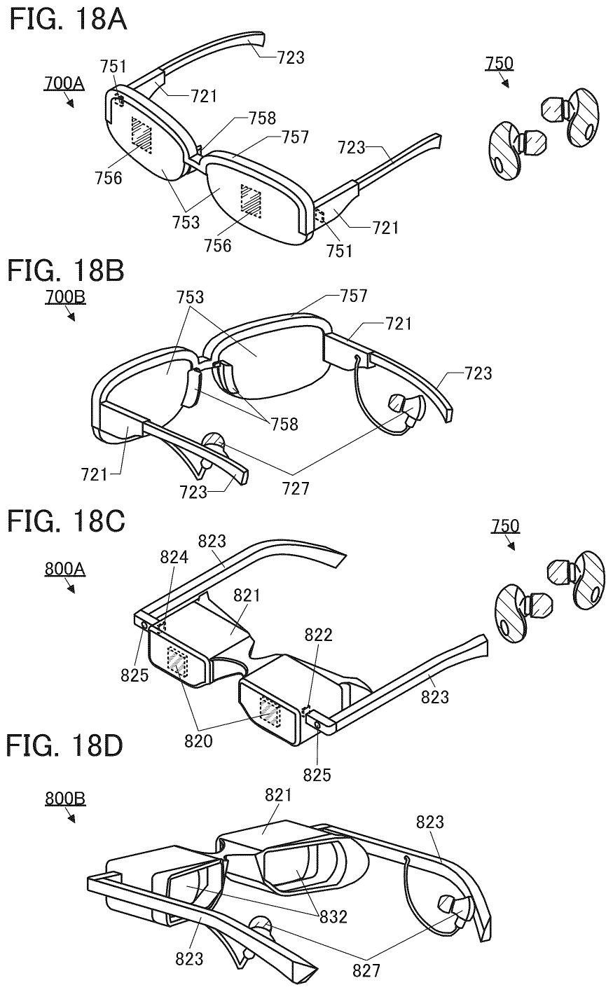

Examples of head-mounted wearable devices are described with reference to FIGS. 18A to 18D.

An electronic device 700A illustrated in FIG. 18A and an electronic device 700B illustrated in FIG. 18B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices can be highly reliable.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 18C and an electronic device 800B illustrated in FIG. 18D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices can be highly reliable.

The display portions 820 are located inside the housing 821 so as to be seen through the lenses 832. When the pair of display portions 820 display different images, three-dimensional display using parallax can be performed.

The electronic devices 800A and 800B preferably include a mechanism for adjusting the lateral positions of the lenses 832 and the display portions 820 so that the lenses 832 and the display portions 820 are located optimally in accordance with the positions of the user's eyes.

The electronic device 800A or the electronic device 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750.

The electronic device may include an earphone portion. The electronic device 700B in FIG. 18B includes earphone portions 727. Part of a wiring that connects the earphone portion 727 and the control portion may be located inside the housing 721 or the wearing portion 723.

Similarly, the electronic device 800B in FIG. 18D includes earphone portions 827. For example, the earphone portion 827 can be connected to the control portion 824 by wire.

As described above, both the glasses-type device (e.g., the electronic devices 700A and 700B) and the goggles-type device (e.g., the electronic devices 800A and 800B) are preferable as the electronic device of one embodiment of the present invention.

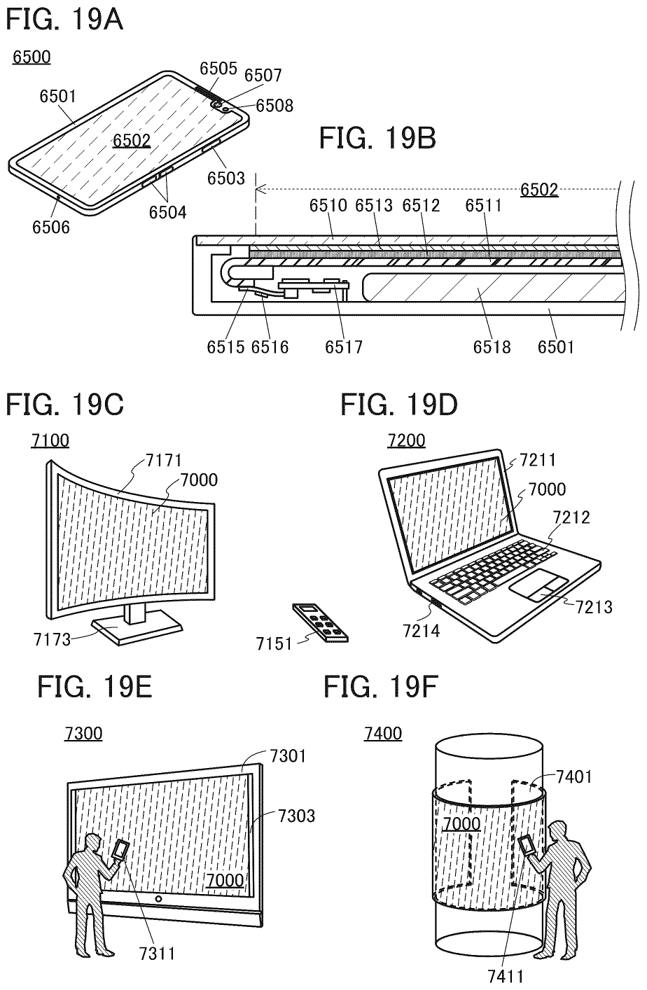

An electronic device 6500 in FIG. 19A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, the electronic devices can be highly reliable.

FIG. 19B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, the electronic device can be extremely lightweight. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby the electronic device can have a narrow bezel.

FIG. 19C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, the electronic devices can be highly reliable.

Operation of the television device 7100 illustrated in FIG. 19C can be performed with an operation switch provided in the housing 7171 and a separate remote control 7151.

FIG. 19D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, the electronic devices can be highly reliable.

FIGS. 19E and 19F illustrate examples of digital signage.

Digital signage 7300 illustrated in FIG. 19E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 19F illustrates digital signage 7400 attached to a cylindrical pillar 7401. The digital signage 7400 includes the display portion 7000 provided along a curved surface of the pillar 7401.

In FIGS. 19E and 19F, the display apparatus of one embodiment of the present invention can be used in the display portion 7000. Thus, the electronic devices can be highly reliable.

A larger area of the display portion 7000 can increase the amount of information that can be provided at a time. The display portion 7000 having a larger area attracts more attention, so that the effectiveness of the advertisement can be increased, for example.

As illustrated in FIGS. 19E and 19F, it is preferable that the digital signage 7300 or the digital signage 7400 can work with an information terminal 7311 or an information terminal 7411, such as a smartphone that a user has, through wireless communication.

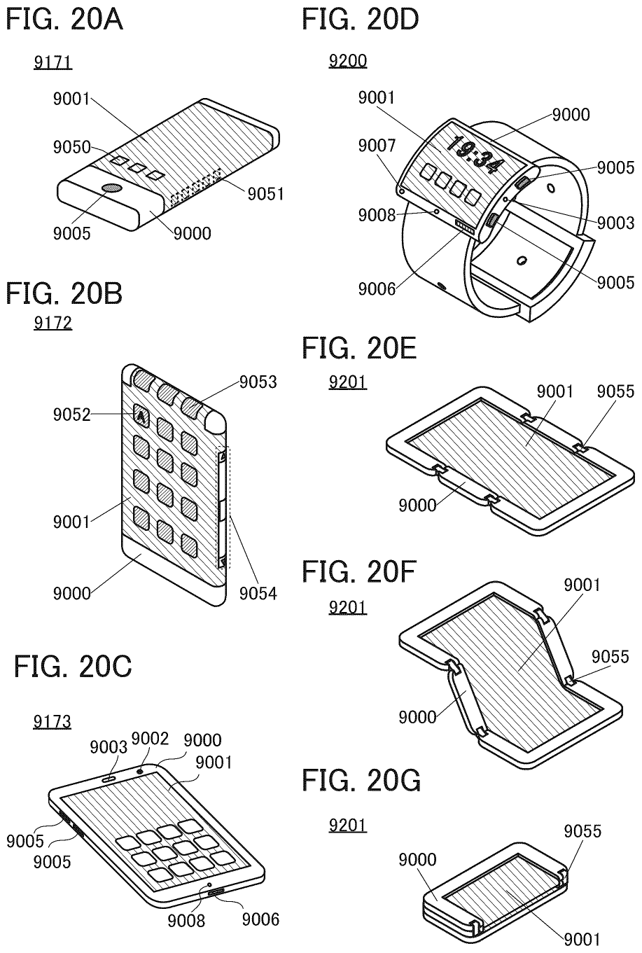

Electronic devices illustrated in FIGS. 20A to 20G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 20A to 20G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic devices in FIGS. 20A to 20G are described in detail below.

FIG. 20A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 20A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 20B is a perspective view of a portable information terminal 9172. The portable information terminal 9172 has a function of displaying information on three or more surfaces of the display portion 9001. Here, information 9052, information 9053, and information 9054 are displayed on the respective surfaces. For example, the user of the portable information terminal 9172 can check the information 9053 displayed such that it can be seen from above the portable information terminal 9172, with the portable information terminal 9172 put in a breast pocket of his/her clothes.

FIG. 20C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 20D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 20E to 20G are perspective views of a foldable portable information terminal 9201. FIG. 20E is a perspective view showing the portable information terminal 9201 that is opened. FIG. 20G is a perspective view showing the portable information terminal 9201 that is folded. FIG. 20F is a perspective view showing the portable information terminal 9201 that is shifted from one of the states in FIGS. 20E and 20G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are described in one embodiment, the structure examples can be combined as appropriate.

At least part of any of the structure examples, the drawings corresponding thereto, and the like described in this embodiment can be combined with any of the other structure examples, the other drawings corresponding thereto, and the like as appropriate.

At least part of this embodiment can be implemented in combination with any of the other embodiments described in this specification, as appropriate.

### Example 1

In this example, to describe a display apparatus of one embodiment of the present invention, Light-emitting Device 1A and Light-emitting Device 1B that are red-light-emitting devices with different cathode thicknesses and Light-emitting Device 2A and Light-emitting Device 2B that are blue-light-emitting devices with different cathode thicknesses were fabricated, and results of comparing their emission efficiency are described. Furthermore, Light-emitting Device 3R (red), Light-emitting Device 3G (green), and Light-emitting Device 3B (blue) were fabricated in each of which an organic compound layer was formed by a photolithography method to enable a resolution of 3207 ppi, and results of evaluating their characteristics are described.

First, methods for fabricating Light-emitting Devices 1A, 1B, 2A, and 2B are described. The structural formulae of organic compounds used in the light-emitting devices are shown below.

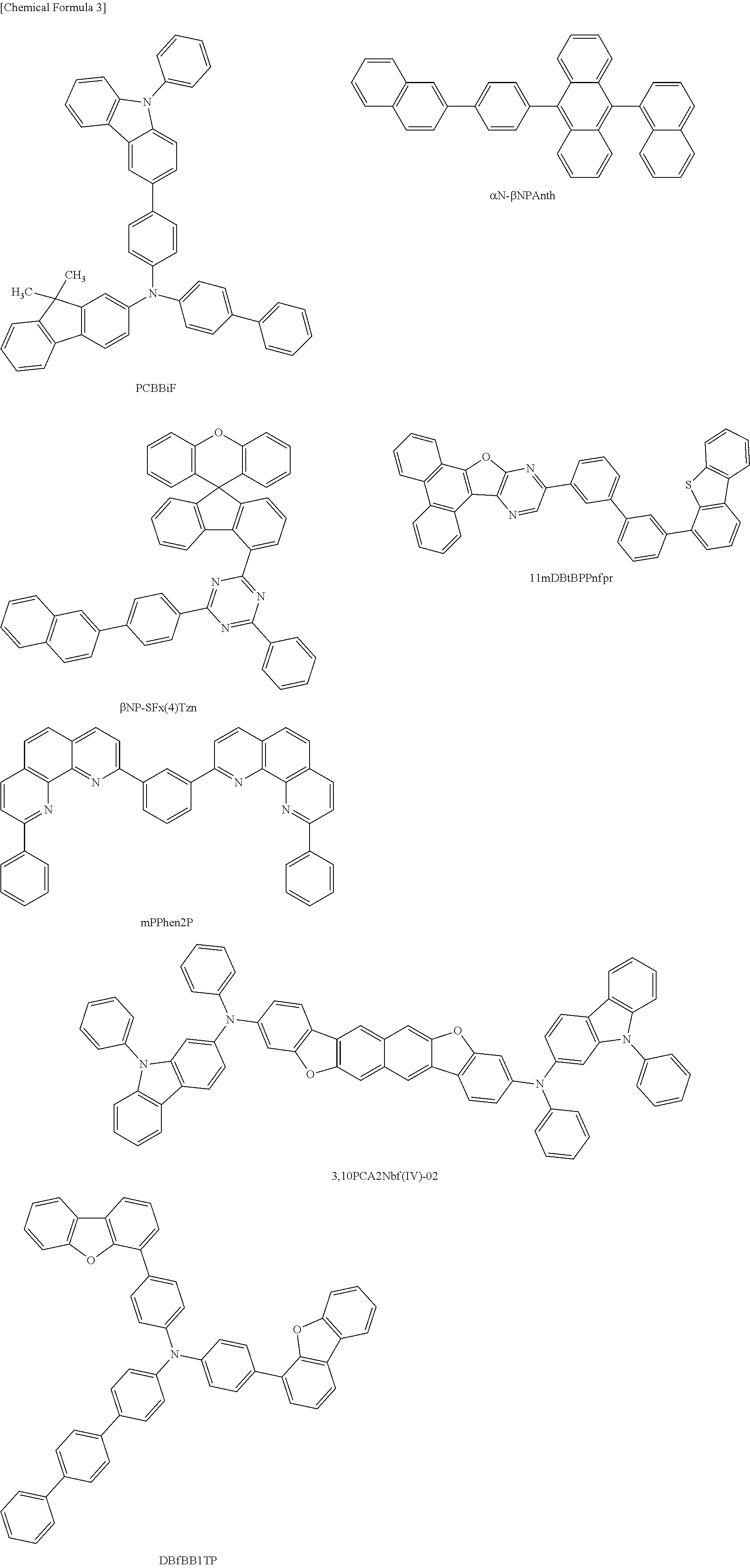

### (Method for Fabricating Light-Emitting Device 1A)

Over a glass substrate, a 50-nm-thick titanium (Ti) layer, a 70-nm-thick aluminum (Al) layer, and a 2-nm-thick Ti layer were stacked in this order from the substrate side and then, baking was performed at 300° C. in the air for 1 hour. Then, as a transparent electrode, a 10-nm-thick layer of indium tin oxide containing silicon oxide (JTSO) was stacked by a sputtering method, so that an anode was formed. The electrode area was set to 4 mm² (2 mm×2 mm).

Next, in pretreatment for forming the light-emitting device over the substrate, the surface of the substrate was washed with water, and baking was performed at 200° C. for 1 hour.

After that, the substrate was transferred into a vacuum evaporation apparatus where the pressure had been reduced to approximately 1×10⁴ Pa, and was subjected to heat treatment at 170° C. for 30 minutes in a heating chamber of the vacuum evaporation apparatus, and then, the substrate was cooled down for approximately 30 minutes.

Then, the substrate was fixed to a substrate holder provided in the vacuum evaporation apparatus such that the surface on which the anode was formed faced downward. Over the anode, N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material with a molecular weight of 672 and four or more fluorine atoms (OCHD-003) were deposited by co-evaporation to a thickness of 10 nm such that the weight ratio of PCBBiF to OCHD-003 was 1:0.03, so that a hole-injection layer was formed.

Over the hole-injection layer, PCBBiF was deposited by evaporation to a thickness of 30 nm, so that a hole-transport layer was formed.

Then, over the hole-transport layer, 11-[3′-(dibenzothiophen-4-yl)biphenyl-3-yl]phenanthro[9′,10′: 4,5]furo[2,3-b]pyrazine (abbreviation: 11mDBtBPPnfpr), PCBBiF, and a red phosphorescent dopant (OCPG-006) were deposited by co-evaporation to a thickness of 40 nm such that the weight ratio of 11mDBtBPPnfpr to PCBBiF to OCPG-006 was 0.7:0.3:0.05, whereby a light-emitting layer was formed.

Next, 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn) was deposited by evaporation to a thickness of 20 nm, and then, 2,2′-(1,3-phenylene)bis(9-phenyl-1,10-phenanthroline) (abbreviation: mPPhen2P) was deposited by evaporation to a thickness of 20 nm, so that an electron-transport layer was formed.

After the formation of the electron-transport layer, lithium fluoride and ytterbium were deposited by co-evaporation to a thickness of 1.5 nm such that the volume ratio of LiF to Yb was 1:0.5, whereby an electron-injection layer was formed.

Over the electron-injection layer, silver (Ag) and magnesium (Mg) were deposited by co-evaporation to a thickness of 15 nm such that the volume ratio of Ag to Mg was 1:0.1 to form a cathode, whereby Light-emitting Device 1A was fabricated.

The cathode is a semi-transmissive and semi-reflective electrode having a function of reflecting light and a function of transmitting light; thus, the light-emitting device of this example is a top-emission single-type device in which light is extracted through the cathode. Over the cathode, PCBBiF was deposited by evaporation to a thickness of 80 nm as a cap layer to improve light extraction efficiency.

### (Method for Fabricating Light-Emitting Device 1B)

Light-emitting Device 1B is a red-light-emitting device whose cathode thickness is different from that of Light-emitting Device 1A. That is, in Light-emitting Device 1B, over the electron-injection layer, silver (Ag) and magnesium (Mg) were deposited by co-evaporation to a thickness of 25 nm such that the volume ratio of Ag to Mg was 1:0.1 to form the cathode. The other components were formed in the same manner as those in Light-emitting Device 1A.

### (Method for Fabricating Light-Emitting Device 2A)

Light-emitting Device 2A is a blue-light-emitting device that differs from Light-emitting Device 1A in the structure of the hole-transport layer, the structure of the light-emitting layer, and the thickness of the electron-transport layer. To form the hole-transport layer, over the hole-injection layer, PCBBiF was deposited by evaporation to a thickness of 105 nm and then, N,N′-bis[4-(dibenzofuran-4-yl)phenyl]-4-amino-p-terphenyl (abbreviation: DBfBB1TP) was deposited by evaporation to a thickness of 10 nm. To form the light-emitting layer, over the hole-transport layer, 9-(1-naphthyl)-10-[4-(2-naphthyl)phenyl]anthracene (abbreviation: αN-βNPAnth) and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) were deposited by co-evaporation to a thickness of 25 nm such that the weight ratio of αN-βNPAnth to 3,10PCA2Nbf(IV)-02 was 1:0.015. To form the electron-transport layer, PNP-SFx(4)Tzn was deposited by evaporation to a thickness of 20 nm, and then, mPPhen2P was deposited by evaporation to a thickness of 15 nm.

### (Method for Fabricating Light-Emitting Device 2B)

Light-emitting Device 2B is a blue-light-emitting device whose cathode thickness is different from that of Light-emitting Device 2A. That is, in Light-emitting Device 2B, over the electron-injection layer, silver (Ag) and magnesium (Mg) were deposited by co-evaporation to a thickness of 25 nm such that the volume ratio of Ag to Mg was 1:0.1 to form the cathode. The other components were formed in the same manner as those in Light-emitting Device 2A.

Table 1 lists the structures of Light-emitting Devices 1A and 1B.

TABLE 1
Light-emitting Device 1B

| | | Light-emitting | Light-emitting |
|---|---|---|---|
| | Thickness | Device 1A | Device 1B |
| Cap layer | 80 nm | PCBBiF | |
| Cathode | — | Ag:Mg (1:0.1) | |
| | | (15 nm) | (25 nm) |

| | | |
|---|---|---|
| Electron-injection layer | 1.5 nm | LIF:Yb (1:0.5) |
| Electron-transport | 20 nm | mPPhen2P |
| layer | 20 nm | βNP-SFx(4)Tzn |
| Light-emitting layer | 40 nm | 11mDBtBPPnfpr:PCBBiF: |
| | | OCPG-006 (0.7:0.3:0.05) |
| Hole-transport layer | 30 nm | PCBBiF |
| Hole-injection layer | 10 nm | PCBBiF:OCHD-003 (1:0.03) |
| Anode | 10 nm | ITSO |
| | 2 nm | Ti |
| | 70 nm | Al |
| | 50 nm | Ti |

Table 2 lists the structures of Light-emitting Devices 2A and 2B.

TABLE 2
Light-emitting Device 2B

| | | Light-emitting | Light-emitting |
|---|---|---|---|
| | Thickness | Device 2A | Device 2B |
| Cap layer | 80 nm | PCBBiF | |
| Cathode | — | Ag:Mg (1:0.1) | |
| | | (15 nm) | (25 nm) |

| | | |
|---|---|---|
| Electron-injection layer | 1.5 nm | LIF:Yb (1:0.5) |
| Electron-transport layer | 15 nm | mPPhen2P |
| | 20 nm | βNP-SFx(4)Tzn |
| Light-emitting layer | 25 nm | αN-βNP Anth:3,10PCA2Nbf(IV)-02 |
| | | (1:0.015) |
| Hole-transport layer | 10 nm | DBfBB1TP |
| | 105 nm | PCBBiF |
| Hole-injection layer | 10 nm | PCBBiF:OCHD-003 (1:0.03) |
| Anode | 10 nm | ITSO |
| | 2 nm | Ti |
| | 70 nm | Al |
| | 50 nm | Ti |

Next, methods for fabricating Light-emitting Devices 3R, 3G, and 3B, in each of which an organic compound layer was formed by a photolithography method to enable a resolution of 3207 ppi, are described. Note that the organic compound layer of Light-emitting Device 3R has the same structure as that of Light-emitting Device 1A except for the thickness of the hole-transport layer, and the cathode thickness of Light-emitting Device 3R is the same as that of Light-emitting Device 1A. The organic compound layer of Light-emitting Device 3B has the same structure as that of Light-emitting Device 2A except for the thickness of the hole-transport layer, and the cathode thickness of Light-emitting Device 3B is the same as that of Light-emitting Device 2A. The structural formulae of organic compounds used in the light-emitting devices are shown below.

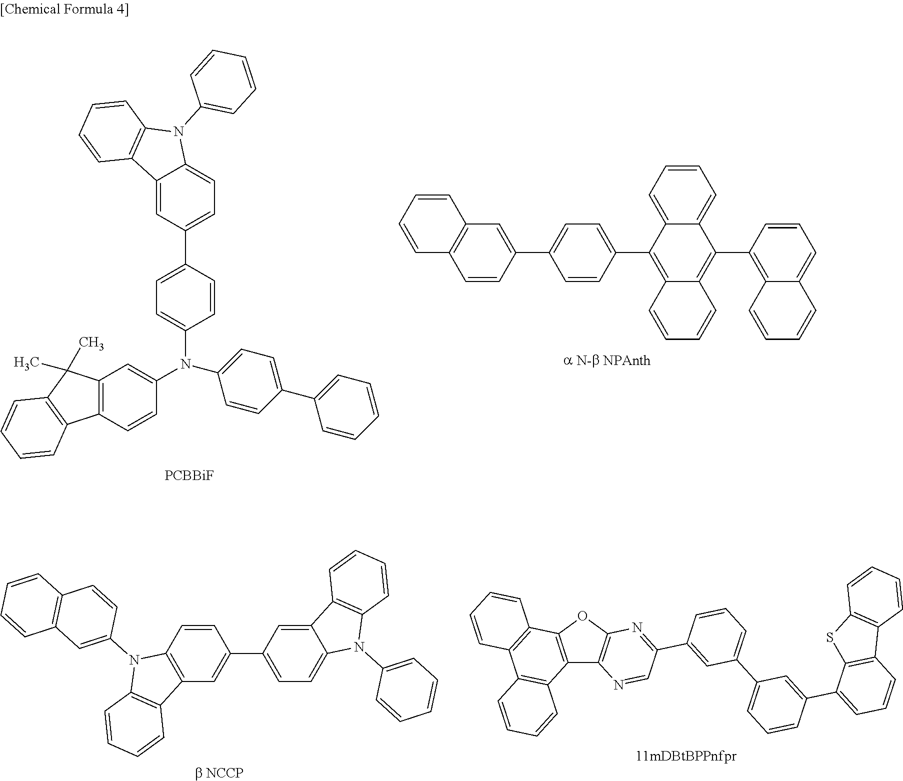

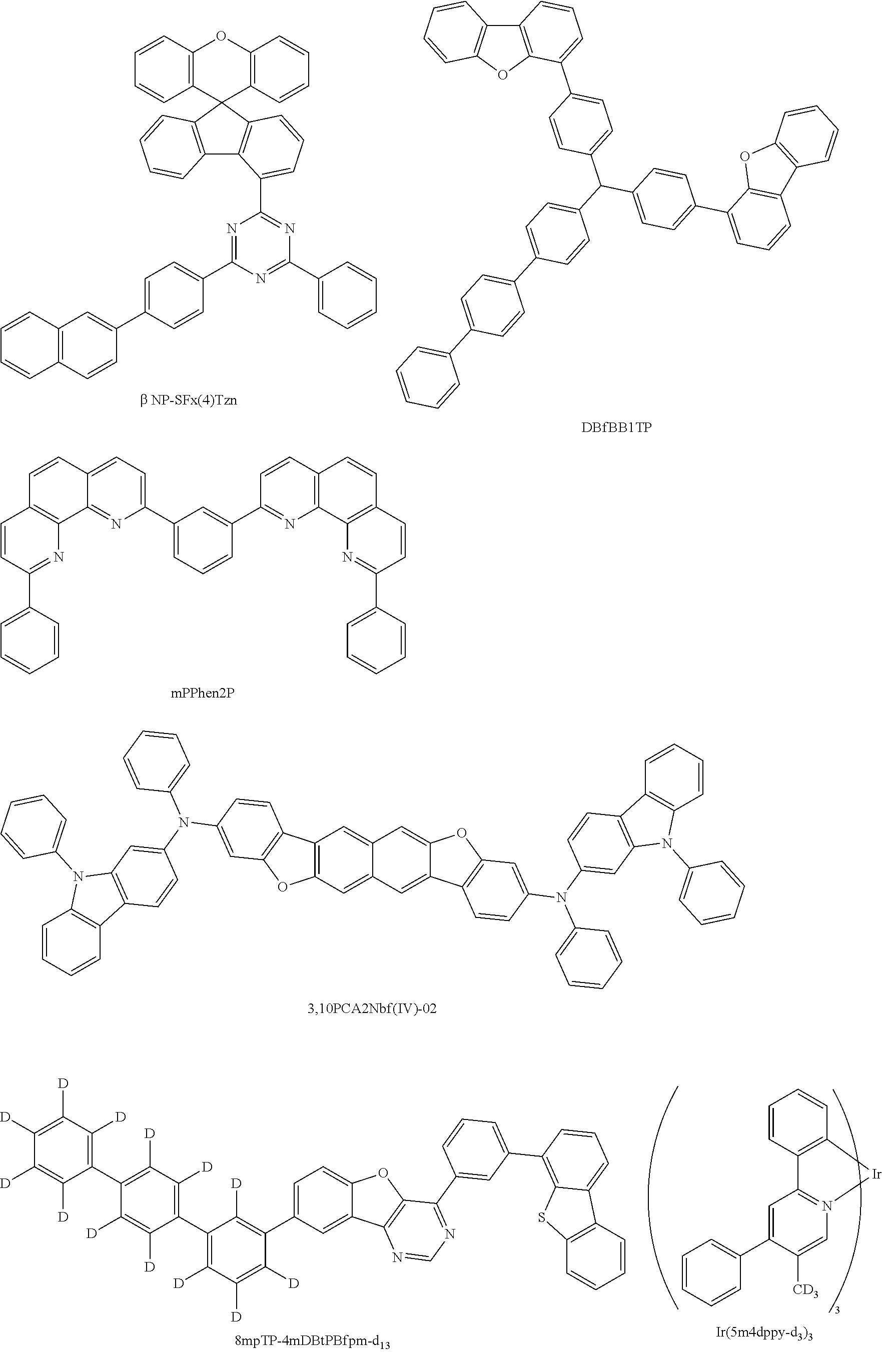

### (Methods for Fabricating Light-Emitting Devices 3R, 3G, and 3B)

First, over a silicon substrate provided with a wiring, a 50-nm-thick titanium (Ti) layer, a 70-nm-thick aluminum (Al) layer, and a 2-nm-thick Ti layer were stacked in this order from the substrate side and then, baking was performed at 300° C. in the air for 1 hour. After that, a 10-nm-thick layer of indium tin oxide containing silicon oxide (JTSO) was stacked by a sputtering method. Then, processing by a photolithography method was performed such that a resolution of 3207 ppi would be achieved, whereby anodes were formed. Then, a film of SiON was formed, and a sidewall was formed using SiON to cover end portions of the anodes. Note that the anodes were formed to achieve matrix arrangement of 251×251=63001 pixels in an area of 2 mm×2 mm. This shape and arrangement correspond to a resolution of 3207 ppi.

Next, in pretreatment for forming the light-emitting devices over the substrate, the substrate was subjected to heat treatment at 120° C. for 120 seconds, 1,1,1,3,3,3-hexamethyldisilazane (abbreviation: HMDS) was then vaporized, and a spray thereof was given to the substrate heated to 60° C., for 120 seconds. This can make it difficult for the stacked-layer film formed over the anodes to be separated from the anodes in the fabrication process.

After that, the substrate was transferred into a vacuum evaporation apparatus where the pressure had been reduced to approximately 1×10⁴ Pa, and was subjected to vacuum baking at 170° C. for 60 minutes in a heating chamber of the vacuum evaporation apparatus, and then, the substrate was cooled down for approximately 60 minutes.

Then, a hole-injection layer was formed as in the method for fabricating Light-emitting Device 1A.

Over the hole-injection layer, PCBBiF was deposited by evaporation to a thickness of 103.5 nm, and then, DBfBB1TP was deposited by evaporation to a thickness of 10 nm, so that a hole-transport layer was formed.

Next, as in the method for fabricating Light-emitting Device 2A, which is a blue-light-emitting device, a light-emitting layer and an electron-transport layer were formed, and then, the organic compound layer was processed by a photolithography method as described below.

### <<Processing by Photolithography Method>>

The substrate over which the electron-transport layer and the components thereunder had been formed was taken out from the vacuum evaporation apparatus and exposed to the air, and then, as a first sacrificial layer, a film of aluminum oxide was formed to have a thickness of 30 nm by an ALD method using trimethylaluminum (abbreviation: TMA) as a precursor and water vapor as an oxidizer.

Next, over the first sacrificial layer, a film of tungsten (W) was formed to have a thickness of 54 nm by a sputtering method as a second sacrificial layer.

A photoresist was applied onto the second sacrificial layer, light exposure and development were performed, and processing was performed such that an end portion of the second sacrificial layer was located inward from an end surface of the anode. This makes it possible that the organic compound layer is formed by processing to have a shape such that an end portion of the organic compound layer is located inward from the end surface of the anode.

The second sacrificial layer was processed using an etching gas containing SF₆ with the use of the photoresist as a mask and then, the first sacrificial layer was processed using an etching gas containing fluoroform (CHF₃), helium (He), and methane (CH₄) at a flow rate ratio of CHF₃:He:CH₄=16.5:118.5:15 with the use of the second sacrificial layer as a hard mask. Then, the organic compound layer was processed using an etching gas containing oxygen (O₂).

The above is the description of the processing by a photolithography method. By performing the processing by a photolithography method, the hole-injection layer, the hole-transport layer, the light-emitting layer, and the electron-transport layer of Light-emitting Device 3B were formed. Moreover, the anodes in the portions where Light-emitting Devices 3R and 3G were to be formed were exposed.

Over the second sacrificial layer and the anodes, PCBBiF and OCHD-003 were deposited by co-evaporation to a thickness of 10 nm such that the weight ratio of PCBBiF to OCHD-003 was 1:0.1, so that a hole-injection layer was formed.

Over the hole-injection layer, PCBBiF was deposited by evaporation to a thickness of 157.5 nm, so that a hole-transport layer was formed.

Then, over the hole-transport layer, 8-(1,1′: 4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), 9-(2-naphthyl)-9′-phenyl-9H,9′H-3,3′-bicarbazole (abbreviation: βNCCP), and tris{2-[5-(methyl-d₃)-4-phenyl-2-pyridinyl-N]phenyl-κC}iridium(III) (abbreviation: Ir(5m4dppy-d₃)₃), which is a green phosphorescent dopant, were deposited by co-evaporation to a thickness of 40 nm such that the weight ratio of 8mpTP-4mDBtPBfpm-d₁₃ to βNCCP to Ir(5m4dppy-d₃)₃ was 0.5:0.5:0.1, whereby a light-emitting layer was formed.

Next, to form an electron-transport layer, PNP-SFx(4)Tzn was deposited by evaporation to a thickness of 10 nm, and then, mPPhen2P was deposited by evaporation to a thickness of 15 nm. After that, processing similar to the above-described processing by a photolithography method was performed, so that the hole-injection layer, the hole-transport layer, the light-emitting layer, and the electron-transport layer of Light-emitting Device 3G were formed. Moreover, the anode in the portion where Light-emitting Device 3R was to be formed was exposed.

Subsequently, over the second sacrificial layers and the anode, PCBBiF and OCHD-003 were deposited by co-evaporation to a thickness of 10 nm such that the weight ratio of PCBBiF to OCHD-003 was 1:0.1, so that a hole-injection layer was formed.

Over the hole-injection layer, PCBBiF was deposited by evaporation to a thickness of 200 nm, so that a hole-transport layer was formed.

Next, as in the method for fabricating Light-emitting Device 1A, which is a red-light-emitting device, a light-emitting layer and an electron-transport layer were formed; then, processing similar to the above-described processing by a photolithography method was performed, so that the hole-injection layer, the hole-transport layer, the light-emitting layer, and the electron-transport layer of Light-emitting Device 3R were formed.

After the formation of the hole-injection layer, the hole-transport layer, the light-emitting layer, and the electron-transport layer of Light-emitting Device 3R, the second sacrificial layers were removed using an etching gas containing SF₆, whereas the first sacrificial layers were left. Then, as a protective film, a film of aluminum oxide was formed to have a thickness of 15 nm by an ALD method.

Next, a layer of a photosensitive high molecular material was formed over the protective film by a photolithography method so as not to overlap with the anodes. After heating was performed at 100° C. in an air atmosphere for 1 hour, unnecessary portions of the first sacrificial layers and the protective film were removed using a mixed acid aqueous solution containing hydrofluoric acid (HF), so that the second electron-transport layers were exposed. At this time, the layer of the photosensitive high molecular material functions as a resist.

The substrate, over which the second electron-transport layers were exposed, was transferred into a vacuum evaporation apparatus where the pressure had been reduced to approximately 1×10⁻⁴ Pa, and was subjected to vacuum baking at 100° C. for 90 minutes in a heating chamber of the vacuum evaporation apparatus.

Subsequently, lithium fluoride and ytterbium were deposited by co-evaporation to a thickness of 1.5 nm such that the volume ratio of LiF to Yb was 1:0.5 to form an electron-injection layer, and then, silver (Ag) and magnesium (Mg) were deposited by co-evaporation to a thickness of 15 nm such that the volume ratio of Ag to Mg was 1:0.1 to form a cathode; thus, Light-emitting Devices 3R, 3G, and 3B were fabricated. As a cap layer, a film of ITO (indium oxide-tin oxide) was formed over the cathode of the light-emitting devices to have a thickness of 70 nm by a sputtering method.

Table 3 lists the structures of Light-emitting Devices 3R, 3G, and 3B.

TABLE 3

| | | Light-emitting | Light-emitting | Light-emitting |
|---|---|---|---|---|
| | Thickness | Device 3R | Device 3G | Device 3B |
| Aperture ratio | — | 11.6% | 19.1% | 25.8% |
| Cap layer | 70 nm | ITO | | |
| Cathode | 15 nm | Ag:Mg (1:0.1) | | |
| Electron-injection layer | 1.5 nm | LiF:Yb (1:0.5) | | |
| Electron-transport layer | — | mPPhen2P (20 nm) | mPPhen2P (15 nm) | mPPhen2P (15 nm) |
| | 20 nm | βNP-SFx(4)Tzn (20 nm) | βNP-SFx(4)Tzn (10 nm) | βNP-SFx(4)Tzn (20 nm) |
| Light-emitting layer | — | 11mDBtBPPnfpr:PCBBiF: | 8mpTP-4mDBtPBfpm-d₁₃: | αN-βNP Anth: |
| | | OCPG-006 | BNCCP:Ir(5m4dppy-d3)₃ | 3,10PCA2Nbf(IV)-02 |
| | | (0.7:0.3:0.05) (40 nm) | (0.5:0.5:0.1) (40 nm) | (1:0.015) (25 nm) |
| Hole-transport layer | — | PCBBiF (200 nm) | PCBBiF (157.5 nm) | DBfBB1TP (10 nm) |
| | | | | PCBBiF (103.5 nm) |
| Hole-injection layer | 10 nm | PCBBiF:OCHD-003 (1:0.1) | | PCBBiF:OCHD-003 |
| | | | | (1:0.03) |

| | | |
|---|---|---|
| Anode | 10 nm | ITSO |
| | 2 nm | Ti |
| | 70 nm | Al |
| | 50 nm | Ti |

The light-emitting devices fabricated were sealed using a glass substrate in a glove box containing a nitrogen atmosphere so as not to be exposed to the air. Specifically, a UV curable sealing material was applied to surround the devices, only the sealing material was irradiated with UV while the light-emitting devices were not irradiated with the UV, and heat treatment was performed at 80° C. under an atmospheric pressure for 1 hour. Then, the initial characteristics of the light-emitting devices were measured.

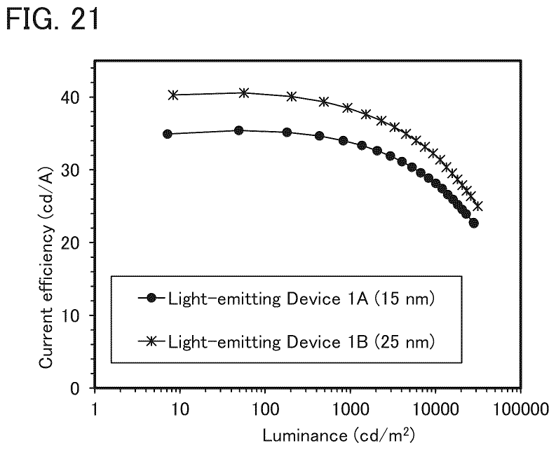

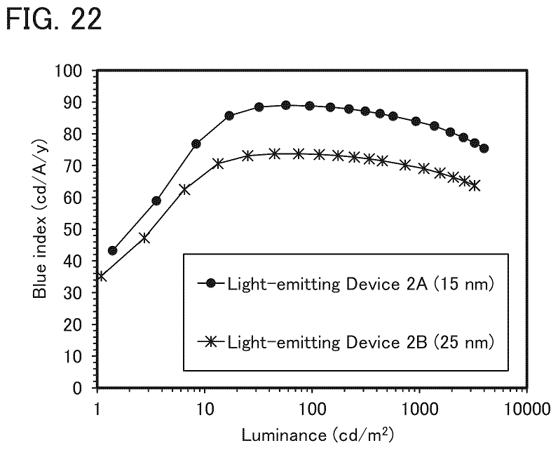

FIG. 21 shows the current efficiency-luminance characteristics of Light-emitting Devices 1A and 1B. FIG. 22 shows the blue index-luminance characteristics of Light-emitting Devices 2A and 2B.

Note that the blue index (BI) is a value obtained by dividing current efficiency (cd/A) by chromaticity y, and is one of the indicators of characteristics of blue light emission. As the chromaticity y of blue light emission becomes smaller, the color purity thereof tends to be higher. With high color purity, a wide range of blue colors can be expressed even with a small number of luminance components; hence, using blue light emission with high color purity reduces the luminance needed for expressing blue, leading to lower power consumption. Thus, a BI, which is based on chromaticity y as one of the indicators of color purity of blue, is suitably used as a means for showing the efficiency of blue light emission. The light-emitting device with a higher BI can be regarded as a blue-light-emitting device having higher efficiency for a display.

Table 4 shows the main characteristics of Light-emitting Devices 1A and 1B at a luminance of approximately 1000 cd/m². Table 5 shows the main characteristics of Light-emitting Devices 2A and 2B at a luminance of approximately 1000 cd/m². The luminance, CIE chromaticity, and electroluminescence spectra were measured at normal temperature with a spectroradiometer (SR-UL1R from TOPCON TECHNOHOUSE CORPORATION).

TABLE 4

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 2.6 | 0.097 | 2.43 | 0.68 | 0.31 | 825 | 34 | 33 |
| Device 1A | | | | | | | | |
| Light-emitting | 2.6 | 0.096 | 2.41 | 0.69 | 0.31 | 927 | 39 | 33 |
| Device 1B | | | | | | | | |

TABLE 5

| | | | | | | | | External | |
|---|---|---|---|---|---|---|---|---|---|
| | | | Current | | | | Current | quantum | |
| | Voltage | Current | density | Chromaticity | Chromaticity | Luminance | efficiency | efficiency | BI value |
| | (V) | (mA) | (mA/cm²) | x | y | (cd/m²) | (cd/A) | (%) | (cd/A/y) |
| Light-emitting | 4.2 | 1.0 | 26.0 | 0.14 | 0.042 | 923 | 3.5 | 7.8 | 84 |
| Device 2A | | | | | | | | | |
| Light-emitting | 4.4 | 1.6 | 39.0 | 0.14 | 0.041 | 1100 | 2.8 | 6.4 | 69 |
| Device 2B | | | | | | | | | |

FIG. 21 and Table 4 show that the current efficiency of Light-emitting Device 1B is higher than that of Light-emitting Device 1A. This indicates that a red-light-emitting device has higher emission efficiency when the thickness of its cathode is 25 nm.

FIG. 22 and Table 5 show that the blue index of Light-emitting Device 2A is higher than that of Light-emitting Device 2B. This indicates that a blue-light-emitting device has higher emission efficiency when the thickness of its cathode is 15 nm.

As described in Embodiment 1 with reference to FIG. 2B, it can be said that since the absorptance of an Ag:Mg film for red light is low, the red-light-emitting device with the larger cathode thickness achieved improved directivity of light in the direction perpendicular to the light-emitting surface owing to a microcavity structure and accordingly had the higher current efficiency. Meanwhile, it can be said that since the absorptance of an Ag:Mg film for blue light is high, the blue-light-emitting device with the smaller cathode thickness suffered from less light absorption by the cathode and accordingly had the higher current efficiency.

The above results show that in a display apparatus of one embodiment of the present invention, when the thickness of the auxiliary electrode 106 differs between the light-emitting devices emitting light of different colors, or specifically, when the thickness of the auxiliary electrode 106R of the red-light-emitting device 130R is larger than the thickness of the auxiliary electrode 106B of the blue-light-emitting device 130B as illustrated in FIG. 1B, the cathode thickness can be different between the light-emitting devices and thus, the emission efficiency of the light-emitting devices can be increased. It is found that in the display apparatus of one embodiment of the present invention, when the auxiliary electrode 106R is provided in the red-light-emitting device 130R and no auxiliary electrode is provided in the blue-light-emitting device 130B as illustrated in FIG. 3B, the cathode thickness can be different between the light-emitting devices and thus, the emission efficiency of the light-emitting devices can be increased.

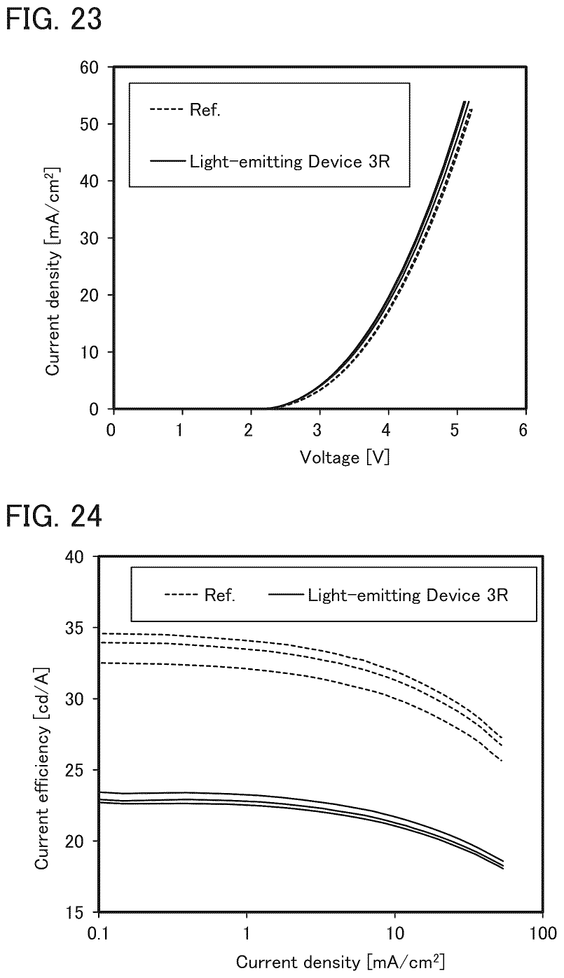

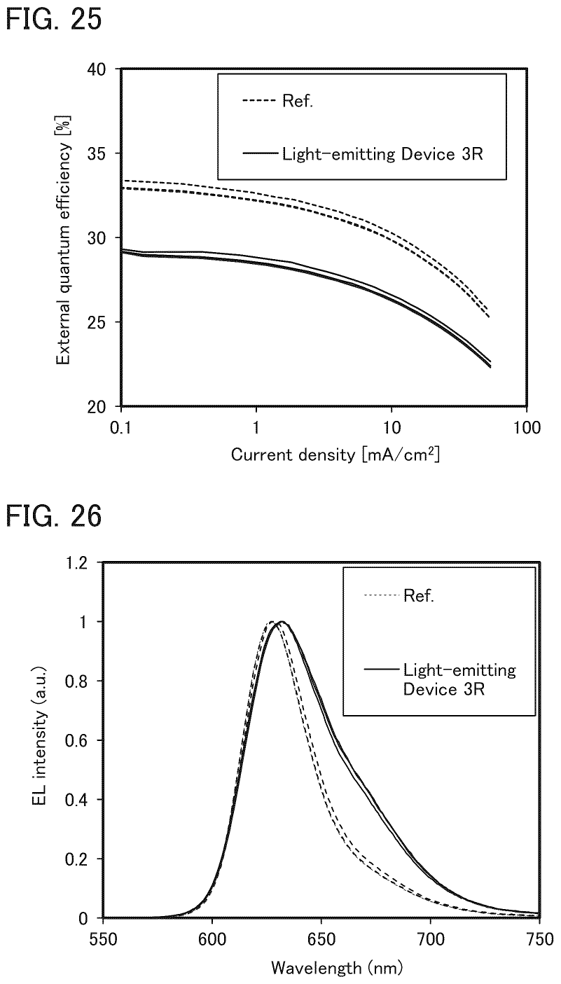

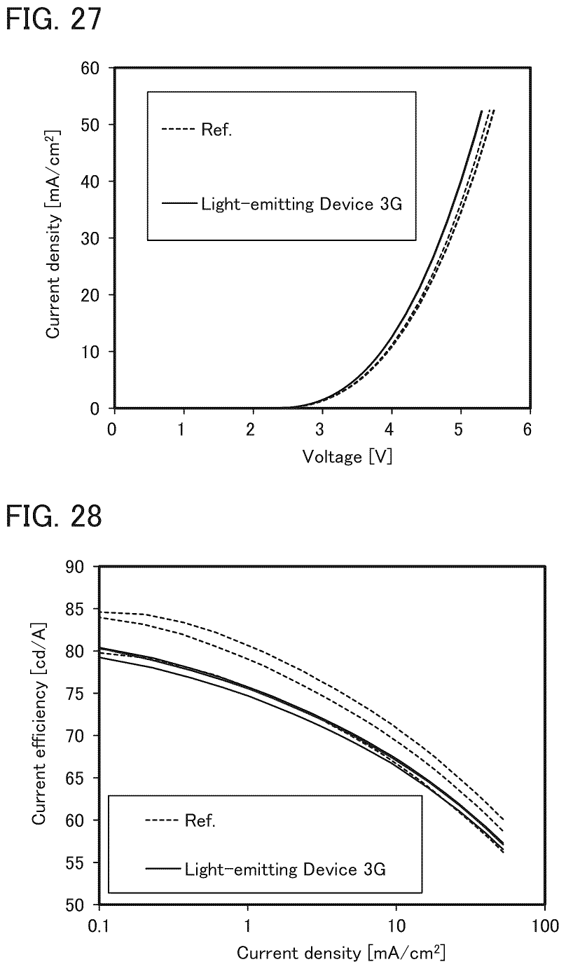

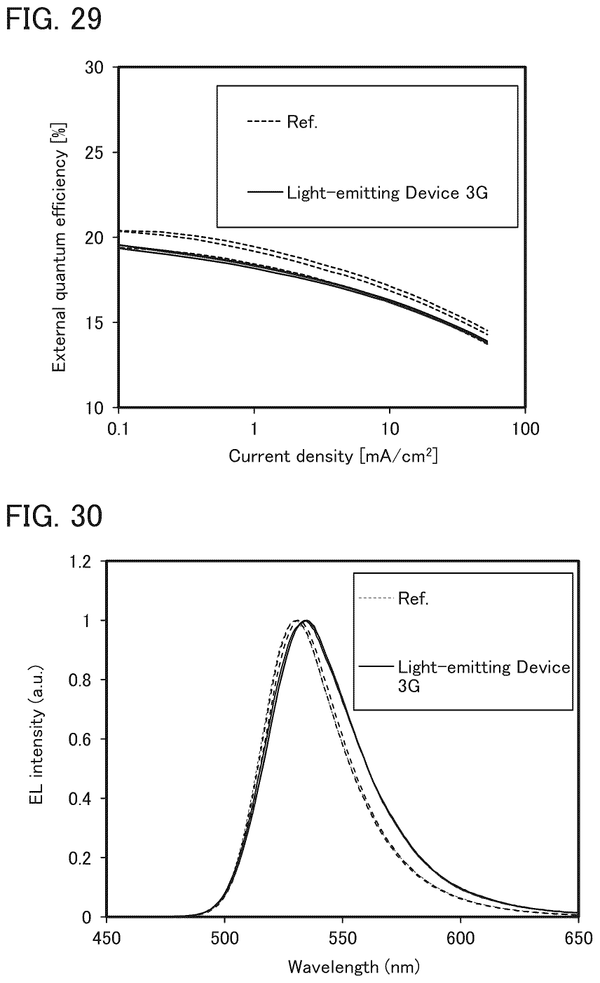

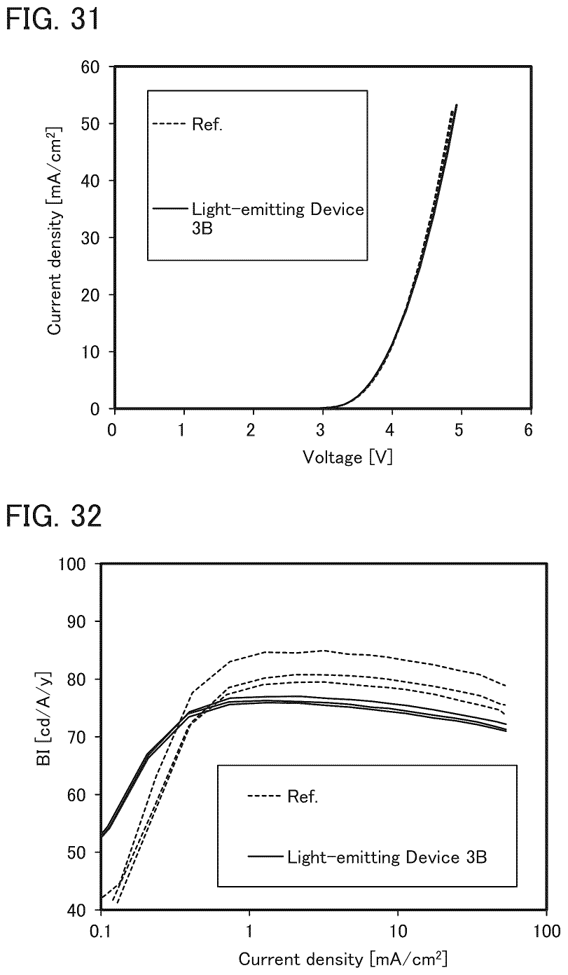

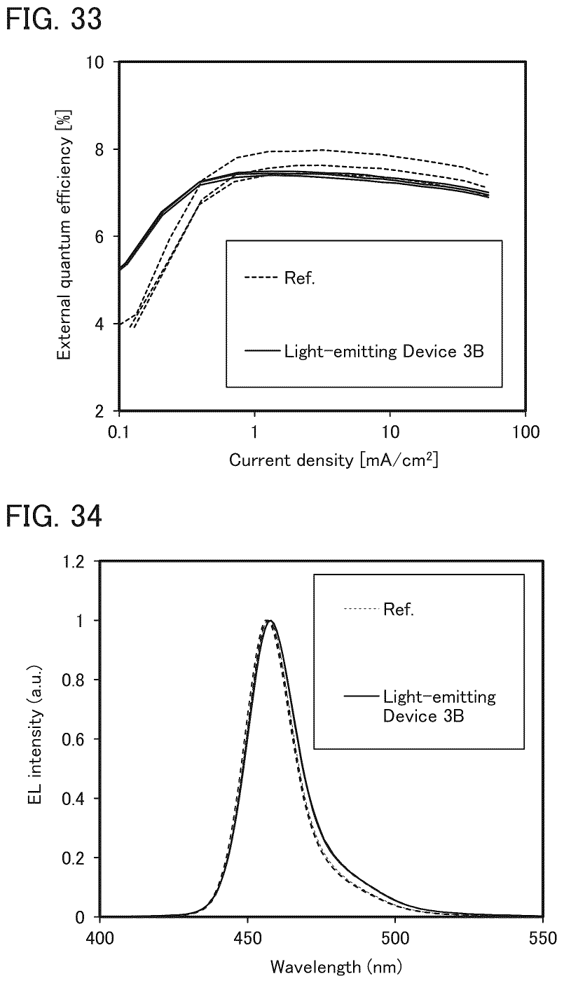

Next, FIG. 23 shows the current density-voltage characteristics of Light-emitting Devices 3R (the number of samples n=3), FIG. 24 shows the current efficiency-current density characteristics thereof, FIG. 25 shows the external quantum efficiency-current density characteristics thereof, and FIG. 26 shows the electroluminescence spectra thereof. FIG. 27 shows the current density-voltage characteristics of Light-emitting Devices 3G (the number of samples n=3), FIG. 28 shows the current efficiency-current density characteristics thereof, FIG. 29 shows the external quantum efficiency-current density characteristics thereof, and FIG. 30 shows the electroluminescence spectra thereof. FIG. 31 shows the current density-voltage characteristics of Light-emitting Devices 3B (the number of samples n=3), FIG. 32 shows the blue index-current density characteristics thereof, FIG. 33 shows the external quantum efficiency-current density characteristics thereof, and FIG. 34 shows the electroluminescence spectra thereof.

Note that FIG. 23 to FIG. 26 also show measurement results of reference light-emitting devices (denoted by Ref. in the graphs) each of which has a structure similar to that of Light-emitting Device 3R and was fabricated without undergoing the process of forming the organic compound layer by a photolithography method. FIG. 27 to FIG. 30 also show measurement results of reference light-emitting devices (denoted by Ref. in the graphs) each of which has a structure similar to that of Light-emitting Device 3G and was fabricated without undergoing the process of forming the organic compound layer by a photolithography method. FIG. 31 to FIG. 34 also show measurement results of reference light-emitting devices (denoted by Ref. in the graphs) each of which has a structure similar to that of Light-emitting Device 3B and was fabricated without undergoing the process of forming the organic compound layer by a photolithography method. To form a cap layer of each of the reference light-emitting devices, PCBBiF was deposited by evaporation to a thickness of 80 nm.

The above results show that the process of forming the organic compound layer by a photolithography method causes only slight degradation of the characteristics, allowing fabrication of light-emitting devices with favorable characteristics.

The light-emitting devices were driven at a constant current with a current density of 50 mA/cm². The LT95 of Light-emitting Device 3B was found to be 239 hours.

As described above, the organic compound layer of Light-emitting Device 3R has the same structure as that of Light-emitting Device 1A except for the thickness of the hole-transport layer, and the cathode thickness of Light-emitting Device 3R is the same as that of Light-emitting Device 1A (15 nm). As shown in FIG. 21, Light-emitting Device 1A with a cathode thickness of 15 nm has lower current efficiency than Light-emitting Device 1B with a cathode thickness of 25 nm; thus, Light-emitting Device 3R should have higher emission efficiency when fabricated to have a cathode thickness of 25 nm by providing an auxiliary electrode between the electron-injection layer and the cathode.

The organic compound layer of Light-emitting Device 3B has the same structure as that of Light-emitting Device 2A except for the thickness of the hole-transport layer, and the cathode thickness of Light-emitting Device 3B is the same as that of Light-emitting Device 2A (15 nm). As shown in FIG. 22, Light-emitting Device 2A with a cathode thickness of 15 nm has a higher blue index than Light-emitting Device 2B with a cathode thickness of 25 nm; it is thus presumable that Light-emitting Device 3B is preferably provided with no auxiliary electrode to maintain high emission efficiency.

### Example 2

In this example, to describe a display apparatus of one embodiment of the present invention, Light-emitting Device 4A and Light-emitting Device 4B that are tandem-type red-light-emitting devices with different cathode thicknesses, Light-emitting Device 5A and Light-emitting Device 5B that are tandem-type green-light-emitting devices with different cathode thicknesses, and Light-emitting Device 6A and Light-emitting Device 6B that are tandem-type blue-light-emitting devices with different cathode thicknesses were fabricated, and results of comparing their emission efficiency are described. Furthermore, Light-emitting Device 7R (red), Light-emitting Device 7G (green), and Light-emitting Device 7B (blue) that are tandem-type light-emitting devices were fabricated in each of which an organic compound layer was formed by a photolithography method to enable a resolution of 3207 ppi, and results of evaluating their characteristics are described.

First, methods for fabricating Light-emitting Devices 4A, 4B, 5A, 5B, 6A, and 6B are described. The structural formulae of organic compounds used in the light-emitting devices are shown below.

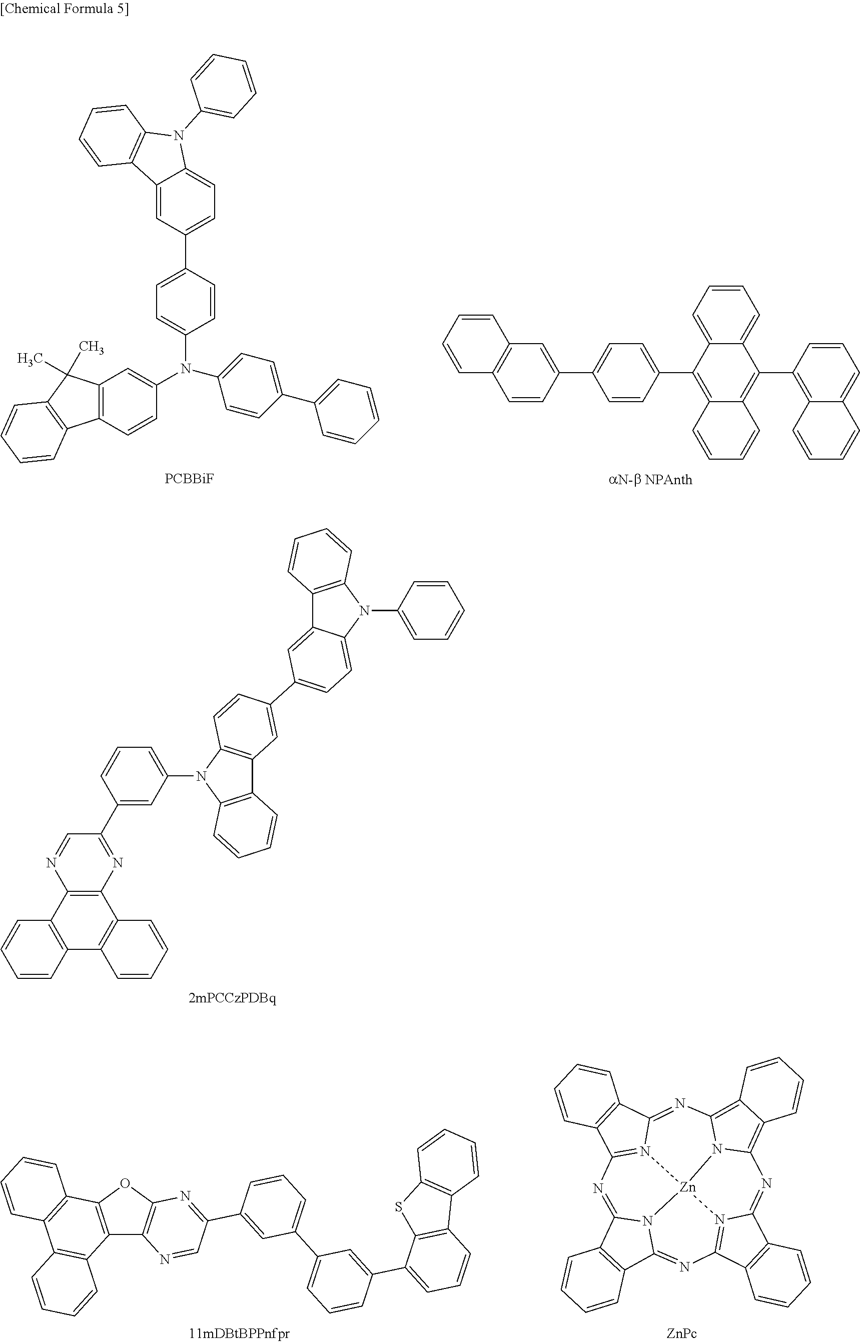

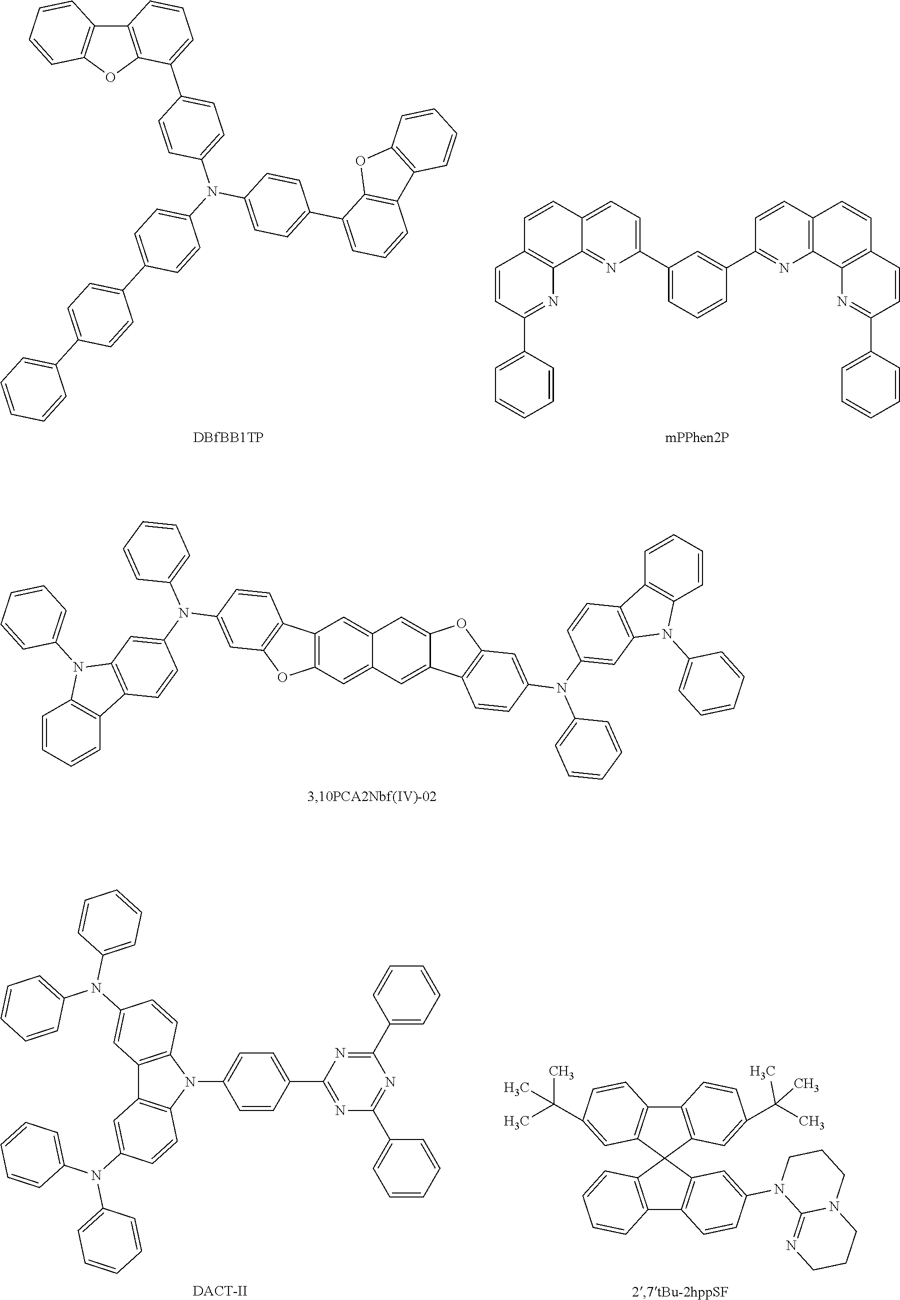

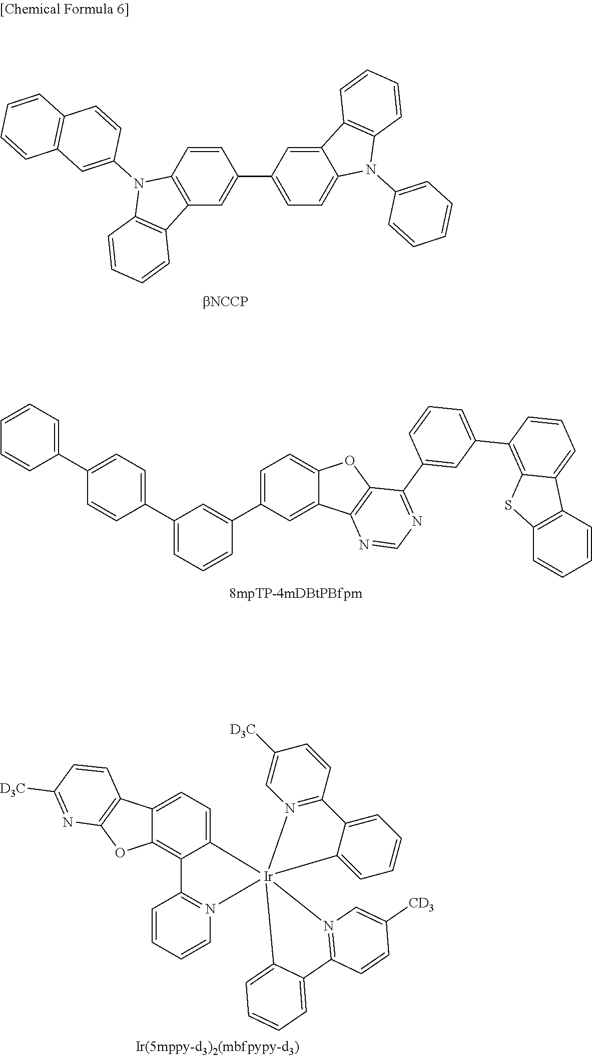

### (Method for Fabricating Light-Emitting Device 4A)

Over a glass substrate, a 50-nm-thick titanium (Ti) layer, a 70-nm-thick aluminum (Al) layer, and a 2-nm-thick Ti layer were stacked in this order from the substrate side and then, baking was performed at 300° C. in the air for 1 hour. Then, as a transparent electrode, a 10-nm-thick layer of indium tin oxide containing silicon oxide (ITSO) was stacked by a sputtering method, so that an anode was formed. The electrode area was set to 4 mm² (2 mm×2 mm).

Next, in pretreatment for forming the light-emitting device over the substrate, the surface of the substrate was washed with water, and baking was performed at 200° C. for 1 hour.

After that, the substrate was transferred into a vacuum evaporation apparatus where the pressure had been reduced to approximately 1×10⁴ Pa, and was subjected to heat treatment at 170° C. for 30 minutes in a heating chamber of the vacuum evaporation apparatus, and then, the substrate was cooled down for approximately 30 minutes.

Then, the substrate was fixed to a substrate holder provided in the vacuum evaporation apparatus such that the surface on which the anode was formed faced downward. Over the anode, PCBBiF and OCHD-003 were deposited by co-evaporation to a thickness of 10 nm such that the weight ratio of PCBBiF to OCHD-003 was 1:0.03, so that a hole-injection layer was formed.

Over the hole-injection layer, PCBBiF was deposited by evaporation to a thickness of 57.5 nm, so that a first hole-transport layer was formed.

Next, over the first hole-transport layer, 11mDBtBPPnfpr, PCBBiF, and a red phosphorescent dopant (OCPG-006) were deposited by co-evaporation to a thickness of 40 nm such that the weight ratio of 11mDBtBPPnfpr to PCBBiF to OCPG-006 was 0.7:0.3:0.05, whereby a first light-emitting layer was formed.

Then, 3,6-bis(diphenylamino)-9-[4-(4,6-diphenyl-1,3,5-triazin-2-yl)phenyl]-9H-carbazole (abbreviation: DACT-II) was deposited by evaporation to a thickness of 10 nm, whereby a first electron-transport layer was formed.

After the formation of the first electron-transport layer, 11mDBtBPPnfpr and 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF) were deposited by co-evaporation to a thickness of 5 nm such that the weight ratio of 11mDBtBPPnfpr to 2′,7′tBu-2hppSF was 1:1, whereby a first layer of an intermediate layer was formed.

Then, a film of zinc phthalocyanine (abbreviation: ZnPc) was formed to have a thickness of 2 nm, so that a third layer of the intermediate layer was formed.

Furthermore, PCBBiF and OCHD-003 were deposited by co-evaporation to a thickness of 10 nm such that the weight ratio of PCBBiF to OCHD-003 was 1:0.15, whereby a second layer of the intermediate layer was formed.

Next, over the intermediate layer, PCBBiF was deposited by evaporation to a thickness of 65 nm, so that a second hole-transport layer was formed.

A second light-emitting layer was formed over the second hole-transport layer in a manner similar to that of the first light-emitting layer.

After that, 2mPCCzPDBq was deposited by evaporation to a thickness of 20 nm and mPPhen2P was further deposited by evaporation to a thickness of 25 nm, so that a second electron-transport layer was formed.

After the formation of the second electron-transport layer, lithium fluoride and ytterbium were deposited by co-evaporation to a thickness of 1.5 nm such that the volume ratio of LiF to Yb was 1:0.5, whereby an electron-injection layer was formed.

Over the electron-injection layer, silver (Ag) and magnesium (Mg) were deposited by co-evaporation to a thickness of 15 nm such that the volume ratio of Ag to Mg was 1:0.1 to form a cathode, whereby Light-emitting Device 4A was fabricated.

The cathode is a semi-transmissive and semi-reflective electrode having a function of reflecting light and a function of transmitting light; thus, the light-emitting device of this example is a top-emission tandem-type device in which light is extracted through the cathode. Over the cathode, ITO was deposited by evaporation to a thickness of 70 nm as a cap layer to improve light extraction efficiency.

### (Method for Fabricating Light-Emitting Device 4B)

Light-emitting Device 4B is a red-light-emitting device whose cathode thickness is different from that of Light-emitting Device 4A. That is, in Light-emitting Device 4B, over the electron-injection layer, silver (Ag) and magnesium (Mg) were deposited by co-evaporation to a thickness of 25 nm such that the volume ratio of Ag to Mg was 1:0.1 to form the cathode. The other components were formed in the same manner as those in Light-emitting Device 4A.

### (Method for Fabricating Light-Emitting Device 5A)

Light-emitting Device 5A is a green-light-emitting device that differs from Light-emitting Device 4A in the thicknesses of the first and second hole-transport layers, the structures of the first and second light-emitting layers, and the thickness of the second electron-transport layer. To form the first hole-transport layer, over the hole-injection layer, PCBBiF was deposited by evaporation to a thickness of 32.5 nm. To form each of the first and second light-emitting layers, 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), βNCCP, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)2(mbfpypy-d₃)) were deposited by co-evaporation to a thickness of 40 nm such that the weight ratio of 8mpTP-4mDBtPBfpm to βNCCP to Ir(5mppy-d3)2(mbfpypy-d3) was 0.6:0.4:0.1. To form the second hole-transport layer, PCBBiF was deposited by evaporation to a thickness of 55 nm over the intermediate layer. To form the second electron-transport layer, 2mPCCzPDBq was deposited by evaporation to a thickness of 10 nm, and then, mPPhen2P was deposited by evaporation to a thickness of 15 nm.

### (Method for Fabricating Light-Emitting Device 5B)

Light-emitting Device 5B is a green-light-emitting device whose cathode thickness is different from that of Light-emitting Device 5A. That is, in Light-emitting Device 5B, over the electron-injection layer, silver (Ag) and magnesium (Mg) were deposited by co-evaporation to a thickness of 25 nm such that the volume ratio of Ag to Mg was 1:0.1 to form the cathode. The other components were formed in the same manner as those in Light-emitting Device 5A.

### (Method for Fabricating Light-Emitting Device 6A)

Light-emitting Device 6A is a blue-light-emitting device that differs from Light-emitting Device 4A in the structures of the first and second hole-transport layers, the structures of the first and second light-emitting layers, and the thickness of the second electron-transport layer. To form the first hole-transport layer, PCBBiF was deposited by evaporation to a thickness of 10 nm over the hole-injection layer and then, DBfBB1TP was deposited by evaporation to a thickness of 10 nm. To form each of the first and second light-emitting layers, αN-βNPAnth and 3,10PCA2Nbf(IV)-02 were deposited by co-evaporation to a thickness of 25 nm such that the weight ratio of αN-βNPAnth to 3,10PCA2Nbf(IV)-02 was 1:0.015. To form the second hole-transport layer, PCBBiF was deposited by evaporation to a thickness of 30 nm over the intermediate layer and then, DBfBB1TP was deposited by evaporation to a thickness of 10 nm. To form the second electron-transport layer, 2mPCCzPDBq was deposited by evaporation to a thickness of 10 nm, and then, mPPhen2P was deposited by evaporation to a thickness of 15 nm.

### (Method for Fabricating Light-Emitting Device 6B)

Light-emitting Device 6B is a blue-light-emitting device whose cathode thickness is different from that of Light-emitting Device 6A. That is, in Light-emitting Device 6B, over the electron-injection layer, silver (Ag) and magnesium (Mg) were deposited by co-evaporation to a thickness of 25 nm such that the volume ratio of Ag to Mg was 1:0.1 to form the cathode. The other components were formed in the same manner as those in Light-emitting Device 6A.

Table 6 lists the structures of Light-emitting Devices 4A and 4B.

TABLE 6
Light-emitting Device 4B

| | | |
|---|---|---|
| | Light-emitting | Light-emitting |
| Thickness | Device 4A | Device 4B |

| Cap layer | 70 nm | ITO (70 nm) | |
|---|---|---|---|
| Cathode | — | Ag:Mg (1:0.1) | |
| | | (15 nm) | (25 nm) |

| Electron-injection | | 1.5 nm | LiF:Yb (1:0.5) |
|---|---|---|---|
| layer | | | |
| Second electron- | 2 | 25 nm | mPPhen2P |
| transport layer | 1 | 20 nm | 2mPCCzPDBq |

| Second light-emitting | 40 nm | 11mDBtBPPnfpr:PCBBiF: |
|---|---|---|
| layer | | OCPG-006 (0.7:0.3:0.05) |
| Second hole- | 65 nm | PCBBiF |
| transport layer | | |

| | | | |
|---|---|---|---|
| Intermediate layer | 2 | 10 nm | PCBBiF:OCHD-003 (1:0.15) |
| | 3 | 2 nm | ZnPc |
| | 1 | 5 nm | 11mDBtBPPnfpr:2′7′tBu- |
| | | | 2hppSF (1:1) |

| First electron- | 10 nm | DACT-II |
|---|---|---|
| transport layer | | |
| First light-emitting | 40 nm | 11mDBtBPPnfpr:PCBBiF: |
| layer | | OCPG-006 (0.7:0.3:0.05) |
| First hole-transport | 57.5 nm | PCBBiF |
| layer | | |

| Hole-injection layer | | 10 nm | PCBBiF:OCHD-003 (1:0.03) |
|---|---|---|---|
| Anode | 4 | 10 nm | ITSO |
| | 3 | 2 nm | Ti |
| | 2 | 70 nm | Al |
| | 1 | 50 nm | Ti |

Table 7 lists the structures of Light-emitting Devices 5A and 5B.

TABLE 7
Light-emitting Device 5B

| | | Light-emitting | Light-emitting |
|---|---|---|---|
| | Thickness | Device 5A | Device 5B |
| Cap layer | 70 nm | ITO (70 nm) | |
| Cathode | — | Ag:Mg (1:0.1) | |
| | | (15 nm) | (25 nm) |

| Electron-injection | | 1.5 nm | LiF:Yb (1:0.5) |
|---|---|---|---|
| layer | | | |
| Second | 2 | 15 nm | mPPhen2P |
| electron- | 1 | 10 nm | 2mPCCzPDBq |
| transport layer | | | |
| Second light- | | 40 nm | 8mpTP-4mDBtPBfpm:βNCCP: |
| emitting layer | | | Ir(5mppy-d₃)₂(mbfpypy-d₃) (0.6:0.4:0.1) |
| Second hole- | | 55 nm | PCBBiF |
| transport layer | | | |
| Intermediate | 2 | 10 nm | PCBBiF:OCHD-003 (1:0.15) |
| layer | 3 | 2 nm | ZnPc |
| | 1 | 5 nm | 11mDBtBPPnfpr:2′7′tBu-2hppSF (1:1) |
| First electron- | | 10 nm | DACT-II |
| transport layer | | | |
| First light-emitting | | 40 nm | 8mpTP-4mDBtPBfpm:βNCCP: |
| layer | | | Ir(5mppy-d₃)₂(mbfpypy-d₃) (0.6:0.4:0.1) |
| First hole-transport | | 32.5 nm | PCBBiF |
| layer | | | |
| Hole-injection | | 10 nm | PCBBiF:OCHD-003 (1:0.03) |
| layer | | | |
| Anode | 4 | 10 nm | ITSO |
| | 3 | 2 nm | Ti |
| | 2 | 70 nm | Al |
| | 1 | 50 nm | Ti |

Table 8 lists the structures of Light-emitting Devices 6A and 6B.

TABLE 8

| | | Light-emitting | Light-emitting |
|---|---|---|---|
| | Thickness | Device 6A | Device 6B |
| Cap layer | 70 nm | ITO (70 nm) | |
| Cathode | — | Ag:Mg (1:0.1) | |
| | | (15 nm) | (25 nm) |

| Electron-injection | | 1.5 nm | LiF:Yb (1:0.5) |
|---|---|---|---|
| layer | | | |
| Second | 2 | 15 nm | mPPhen2P |
| electron- | 1 | 10 nm | 2mPCCzPDBq |
| transport layer | | | |
| Second light-emitting: | | 25 nm | αN-βNP Anth: |
| layer | | | 3,10PCA2Nbf(IV)-02 (1:0.015) |
| Second hole- | 2 | 10 nm | DBfBB1TP |
| transport layer | 1 | 30 nm | PCBBiF |
| Intermediate | 2 | 10 nm | PCBBiF:OCHD-003 (1:0.15) |
| layer | 3 | 2 nm | ZnPc |
| | 1 | 5 nm | 11mDBtBPPnfpr:2′7′tBu-2hppSF (1:1) |
| First electron- | | 10 nm | DACT-II |
| transport layer | | | |
| First light-emitting | | 25 nm | αN-βNP Anth: |
| layer | | | 3,10PCA2Nbf(IV)-02 (1:0.015) |
| First hole- | 2 | 10 nm | DBfBB1TP |
| transport layer | 1 | 10 nm | PCBBiF |
| Hole-injection layer | | 10 nm | PCBBiF:OCHD-003 (1:0.03) |
| Anode | 4 | 10 nm | ITSO |
| | 3 | 2 nm | Ti |
| | 2 | 70 nm | Al |
| | 1 | 50 nm | Ti |

Next, methods for fabricating Light-emitting Devices 7R, 7G, and 7B, in each of which an organic compound layer was formed by a photolithography method to enable a resolution of 3207 ppi, are described. Note that the organic compound layer of Light-emitting Device 7R has the same structure as that of Light-emitting Device 4A except for the structures of the intermediate layer and the first electron-transport layer, and the cathode thickness of Light-emitting Device 7R is the same as that of Light-emitting Device 4A. The organic compound layer of Light-emitting Device 7G has a structure different from that of the organic compound layer of Light-emitting Device 5A; however, Light-emitting Device 7G is a green-light-emitting device like Light-emitting Device 5A, and the cathode thickness of Light-emitting Device 7G is the same as that of Light-emitting Device 5A. The organic compound layer of Light-emitting Device 7B has the same structure as that of Light-emitting Device 6A except for the structure of the intermediate layer, the thickness of the first hole-transport layer, and the structure of the first electron-transport layer, and the cathode thickness of Light-emitting Device 7B is the same as that of Light-emitting Device 6A. The structural formulae of organic compounds used in the light-emitting devices are shown below.

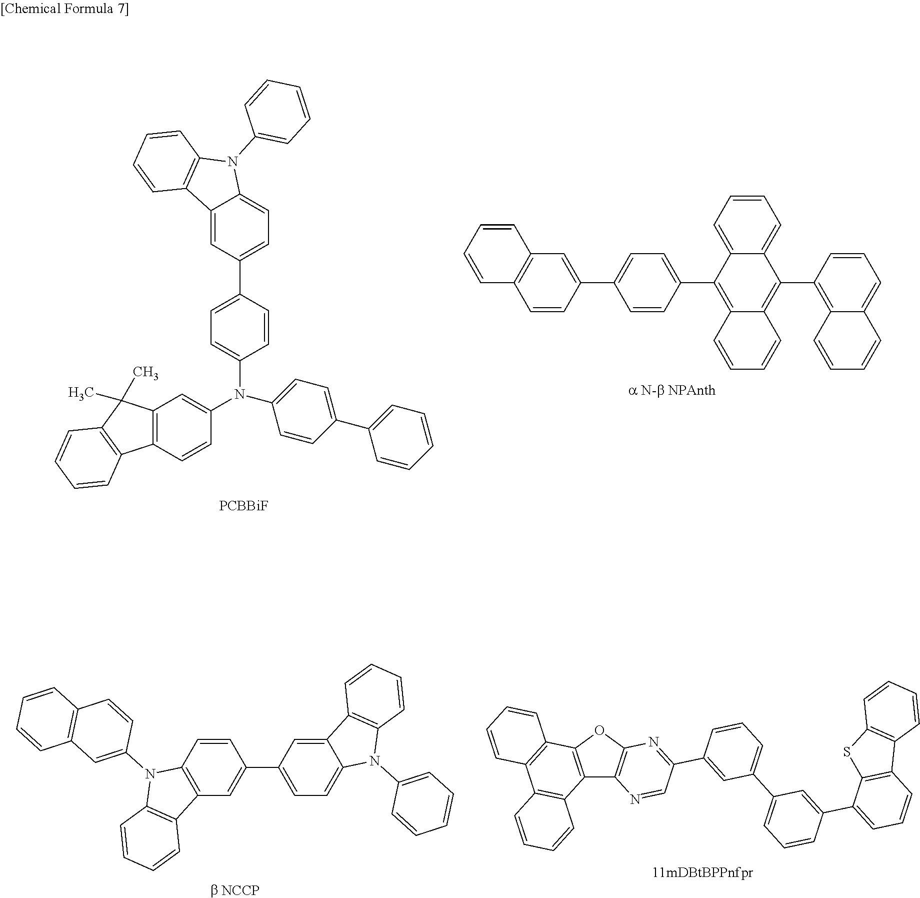

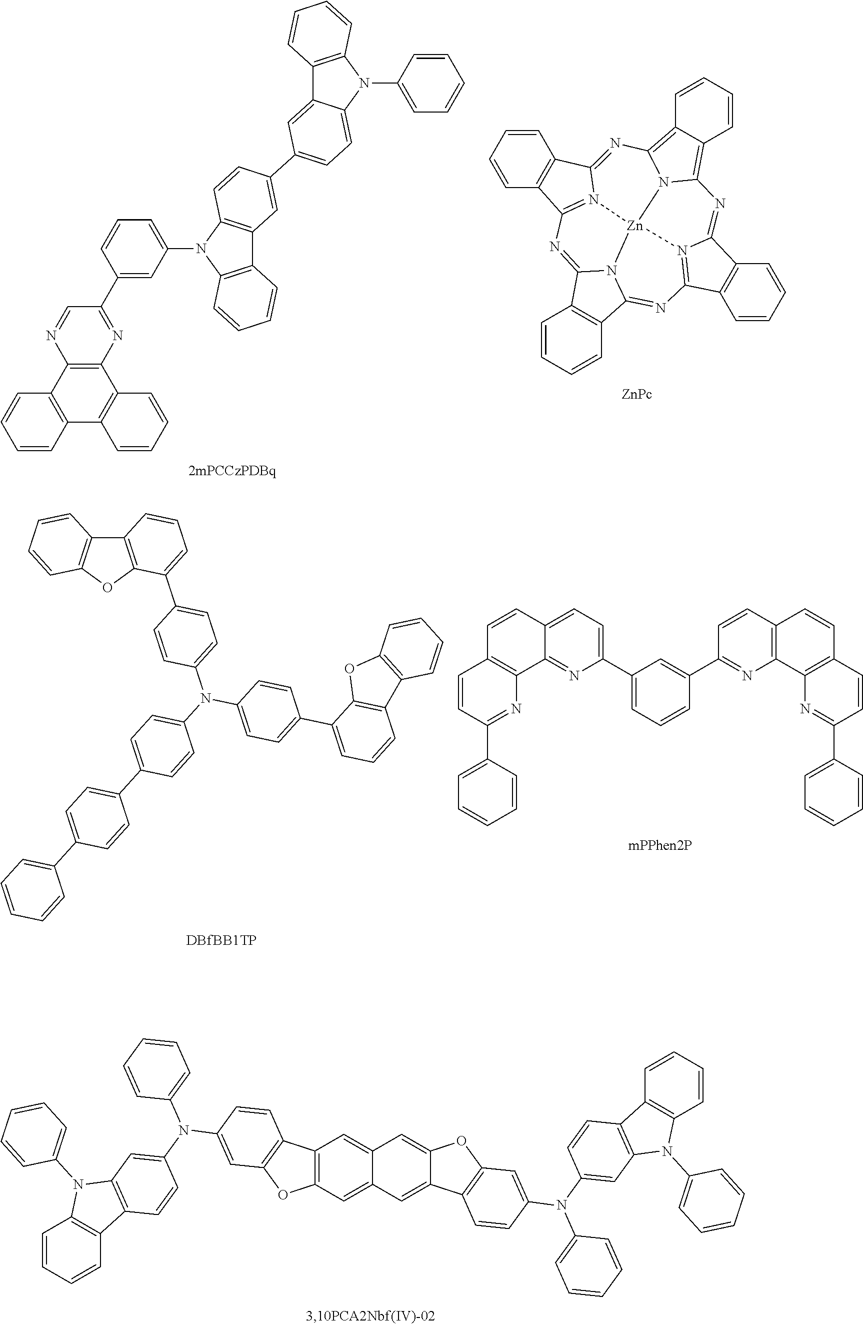

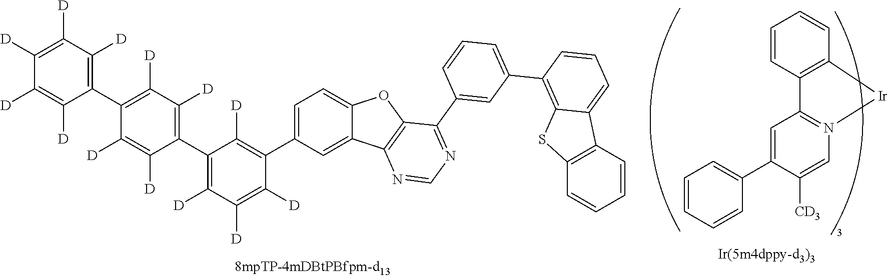

### (Methods for Fabricating Light-Emitting Devices 7R, 7G, and 7B)

First, over a silicon substrate provided with a wiring, a 50-nm-thick titanium (Ti) layer, a 70-nm-thick aluminum (Al) layer, and a 2-nm-thick Ti layer were stacked in this order from the substrate side and then, baking was performed at 300° C. in the air for 1 hour. After that, a 10-nm-thick layer of indium tin oxide containing silicon oxide (ITSO) was stacked by a sputtering method. Then, processing by a photolithography method was performed such that a resolution of 3207 ppi would be achieved, whereby anodes were formed. Then, a film of SiON was formed, and a sidewall was formed using SiON to cover end portions of the anodes. Note that the anodes were formed to achieve matrix arrangement of 251×251=63001 pixels in an area of 2 mm×2 mm. This shape and arrangement correspond to a resolution of 3207 ppi.

Next, in pretreatment for forming the light-emitting devices over the substrate, the substrate was subjected to heat treatment at 120° C. for 120 seconds, 1,1,1,3,3,3-hexamethyldisilazane (abbreviation: HMDS) was then vaporized, and a spray thereof was given to the substrate heated to 60° C., for 120 seconds. This can make it difficult for the stacked-layer film formed over the anodes to be separated from the anodes in the fabrication process.

After that, the substrate was transferred into a vacuum evaporation apparatus where the pressure had been reduced to approximately 1×10⁴ Pa, and was subjected to vacuum baking at 170° C. for 60 minutes in a heating chamber of the vacuum evaporation apparatus, and then, the substrate was cooled down for approximately 60 minutes.

Then, a hole-injection layer was formed as in the method for fabricating Light-emitting Device 4A.

Over the hole-injection layer, PCBBiF was deposited by evaporation to a thickness of 20 nm, and then, DBfBB1TP was deposited by evaporation to a thickness of 10 nm, so that a first hole-transport layer was formed.

Next, a first light-emitting layer was formed as in the method for fabricating Light-emitting Device 6A, which is a blue-light-emitting device; then, 2mPCCzPDBq was deposited by evaporation to a thickness of 10 nm, so that a first electron-transport layer was formed.

After the formation of the first electron-transport layer, mPPhen2P and Li₂O were deposited by co-evaporation to a thickness of 5 nm such that the volume ratio of mPPhen2P to Li₂O was 1:0.01, whereby a first layer of an intermediate layer was formed; then, a third layer and a second layer of the intermediate layer were formed as in the method for fabricating Light-emitting Device 4A.

Next, as in the method for fabricating Light-emitting Device 6A, a second hole-transport layer, a second light-emitting layer, and a second electron-transport layer were formed, and then, the organic compound layer was processed by a photolithography method as described below.

### <<Processing by Photolithography Method>>

The substrate over which the second electron-transport layer and the components thereunder had been formed was taken out from the vacuum evaporation apparatus and exposed to the air, and then, as a first sacrificial layer, a film of aluminum oxide was formed to have a thickness of 30 nm by an ALD method using trimethylaluminum (abbreviation: TMA) as a precursor and water vapor as an oxidizer.

Next, over the first sacrificial layer, a film of tungsten (W) was formed to have a thickness of 54 nm by a sputtering method as a second sacrificial layer.

A photoresist was applied onto the second sacrificial layer, light exposure and development were performed, and processing was performed such that an end portion of the second sacrificial layer was located inward from an end surface of the anode. This makes it possible that the organic compound layer is formed by processing to have a shape such that an end portion of the organic compound layer is located inward from the end surface of the anode.

The second sacrificial layer was processed using an etching gas containing SF₆ with the use of the photoresist as a mask and then, the first sacrificial layer was processed using an etching gas containing fluoroform (CHF₃), helium (He), and methane (CH₄) at a flow rate ratio of CHF₃:He:CH₄=16.5:118.5:15 with the use of the second sacrificial layer as a hard mask. Then, the organic compound layer was processed using an etching gas containing oxygen (O₂).

The above is the description of the processing by a photolithography method. By performing the processing by a photolithography method, the hole-injection layer, the first hole-transport layer, the first light-emitting layer, the first electron-transport layer, the intermediate layer, the second hole-transport layer, the second light-emitting layer, and the second electron-transport layer of Light-emitting Device 7B were formed. Moreover, the anodes in the portions where Light-emitting Devices 7R and 7G were to be formed were exposed.

Next, a hole-injection layer was formed over the second sacrificial layer and the anodes as in the method for fabricating Light-emitting Device 4A.

Over the hole-injection layer, PCBBiF was deposited by evaporation to a thickness of 42.5 nm, so that a first hole-transport layer was formed.

Over the first hole-transport layer, 8mpTP-4mDBtPBfpm-d₁₃, βNCCP, and Ir(5m4dppy-d3)₃ were deposited by co-evaporation to a thickness of 40 nm such that the weight ratio of 8mpTP-4mDBtPBfpm-d₁₃ to βNCCP to Ir(5m4dppy-d₃)₃ was 0.5:0.5:0.1, whereby a first light-emitting layer was formed.

Subsequently, a first electron-transport layer and a first layer, a third layer, and a second layer of an intermediate layer were formed as in the method for fabricating Light-emitting Device 7B.

Over the intermediate layer, PCBBiF was deposited by evaporation to a thickness of 55 nm to form a second hole-transport layer, and then, a second light-emitting layer was formed in a manner similar to that of the first light-emitting layer.

Next, as in the method for fabricating Light-emitting Device 7B, a second electron-transport layer was formed.

After that, processing similar to the above-described processing by a photolithography method was performed, so that the hole-injection layer, the first hole-transport layer, the first light-emitting layer, the first electron-transport layer, the intermediate layer, the second hole-transport layer, the second light-emitting layer, and the second electron-transport layer of Light-emitting Device 7G were formed. Moreover, the anode in the portion where Light-emitting Device 7R was to be formed was exposed.

Subsequently, a hole-injection layer was formed over the second sacrificial layers and the anode as in the method for fabricating Light-emitting Device 4A.

Over the hole-injection layer, PCBBiF was deposited by evaporation to a thickness of 57.5 nm, so that a first hole-transport layer was formed.

Next, a first light-emitting layer was formed as in the method for fabricating Light-emitting Device 4A, which is a red-light-emitting device; then, a first electron-transport layer and a first layer, a third layer, and a second layer of an intermediate layer were formed as in the method for fabricating Light-emitting Device 7B.

Over the intermediate layer, PCBBiF was deposited by evaporation to a thickness of 65 nm to form a second hole-transport layer, and then, a second light-emitting layer was formed in a manner similar to that of the first light-emitting layer.

Next, as in the method for fabricating Light-emitting Device 4A, a second electron-transport layer was formed; then, processing similar to the above-described processing by a photolithography method was performed, so that the hole-injection layer, the first hole-transport layer, the first light-emitting layer, the first electron-transport layer, the intermediate layer, the second hole-transport layer, the second light-emitting layer, and the second electron-transport layer of Light-emitting Device 7R were formed.

After the formation of the hole-injection layer, the first and second hole-transport layers, the first and second light-emitting layers, and the first and second electron-transport layers of Light-emitting Device 7R, the second sacrificial layers were removed using an etching gas containing SF₆, whereas the first sacrificial layers were left. Then, as a protective film, a film of aluminum oxide was formed to have a thickness of 15 nm by an ALD method.

Next, a layer of a photosensitive high molecular material was formed over the protective film by a photolithography method so as not to overlap with the anodes. After heating was performed at 100° C. in an air atmosphere for 1 hour, unnecessary portions of the first sacrificial layers and the protective film were removed using a mixed acid aqueous solution containing hydrofluoric acid (HF), so that the second electron-transport layers were exposed. At this time, the layer of the photosensitive high molecular material functions as a resist.

The substrate, over which the second electron-transport layers were exposed, was transferred into a vacuum evaporation apparatus where the pressure had been reduced to approximately 1×10⁻⁴ Pa, and was subjected to vacuum baking at 100° C. for 90 minutes in a heating chamber of the vacuum evaporation apparatus.

Subsequently, lithium fluoride and ytterbium were deposited by co-evaporation to a thickness of 1.5 nm such that the volume ratio of LiF to Yb was 1:0.5 to form an electron-injection layer, and then, silver (Ag) and magnesium (Mg) were deposited by co-evaporation to a thickness of 15 nm such that the volume ratio of Ag to Mg was 1:0.1 to form a cathode; thus, Light-emitting Devices 7R, 7G, and 7B were fabricated. As a cap layer, a film of PCBBiF was formed over the cathode of the light-emitting devices to have a thickness of 80 nm by a sputtering method.

Table 9 lists the structures of Light-emitting Devices 7R, 7G, and 7B.

TABLE 9

| | | Thickness | Light-emitting | Light-emitting | Light-emitting |
|---|---|---|---|---|---|
| | | (nm) | Device 7R | Device 7G | Device 7B |
| Aperture ratio | | — | 10.6 % | 18.7 % | 25.5 % |
| Cap layer | | 80 | PCBBiF | | |
| Cathode | | 15 | Ag:Mg (1:0.1) | | |
| Electron-injection layer | | 1.5 | LiF:Yb (1:0.5) | | |
| Second | 2 | — | mPPhen2P | mPPhen2P | |
| electron- | | | (25 nm) | (15 nm) | |
| transport layer | 1 | — | 2mPCCzPDBq | 2mPCCzPDBq | |
| | | | (20 nm) | (10 nm) | |
| Second light-emitting layer | | 40 | 11mDBtBPPnfpr: | 8mpTP-4mDBtPBfpm-d₁₃: | αN-βNPAnth: |
| | | | PCBBiF:OCPG-006 | BNCCP:Ir(5m4dppy-d₃)₃ | 3,10PCA2Nbf(IV)-02 |
| | | | (0.7:0.3:0.05) | (0.5:0.5:0.1) | (1:0.015) |
| Second hole- | 2 | — | PCBBiF (65 nm) | PCBBiF (55 nm) | DBfBB1TP (10 nm) |
| transport layer | 1 | — | | | PCBBiF (30 nm) |
| Intermediate | Second layer | 10 | PCBBiF:OCHD-003 (1:0.15) | | |
| layer | Third layer | 2 | ZnPc | | |
| | First layer | 5 | mPPhen2P:Li2O (1:0.01) | | |
| First electron-transport layer | | 10 | 2mPCCzPDBq | | |
| First light-emitting layer | | 40 | 11mDBtBPPnfpr: | 8mpTP-4mDBtPBfpm-d₁₃: | αN-βNPAnth: |
| | | | PCBBiF:OCPG-006 | BNCCP:Ir(5m4dppy-d₃)₃ | 3,10PCA2Nbf(IV)-02 |
| | | | (0.7:0.3:0.05) | (0.5:0.5:0.1) | (1:0.015) |
| First hole- | 2 | — | PCBBiF (57.5 nm) | PCBBiF (42.5 nm) | DBfBB1TP (10 nm) |
| transport layer | 1 | — | | | PCBBiF (20 nm) |

| Hole-injection layer | | 10 | PCBBiF:OCHD-003 (1:0.03) |
|---|---|---|---|
| Anode | 4 | 10 | ITSO |
| | 3 | 2 | Ti |
| | 2 | 70 | A1 |
| | 1 | 50 | Ti |

The light-emitting devices fabricated were sealed using a glass substrate in a glove box containing a nitrogen atmosphere so as not to be exposed to the air. Specifically, a UV curable sealing material was applied to surround the devices, only the sealing material was irradiated with UV while the light-emitting devices were not irradiated with the UV, and heat treatment was performed at 80° C. under an atmospheric pressure for 1 hour. Then, the initial characteristics of the light-emitting devices were measured.

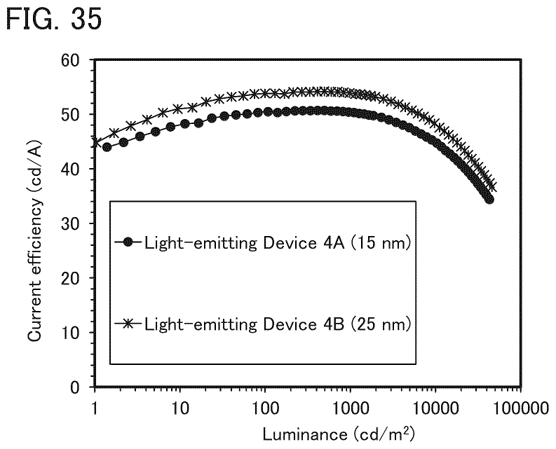

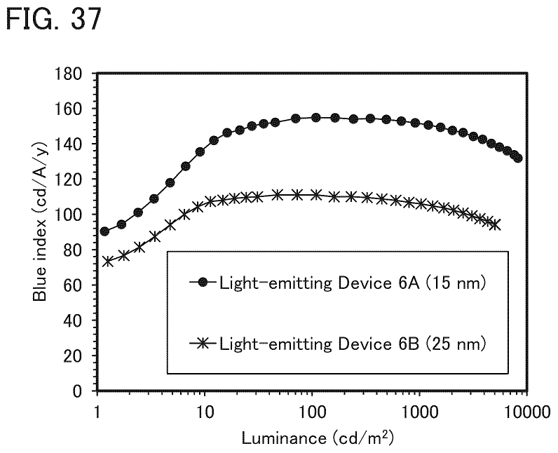

FIG. 35 shows the current efficiency-luminance characteristics of Light-emitting Devices 4A and 4B. FIG. 37 shows the blue index-luminance characteristics of Light-emitting Devices 6A and 6B.

Table 10 shows the main characteristics of Light-emitting Devices 4A and 4B at a luminance of approximately 1000 cd/m². Table 11 shows the main characteristics of Light-emitting Devices 5A and 5B at a luminance of approximately 1000 cd/m². Table 12 shows the main characteristics of Light-emitting Devices 6A and 6B at a luminance of approximately 1000 cd/m². The luminance, CIE chromaticity, and electroluminescence spectra were measured at normal temperature with a spectroradiometer (SR-UL1R from TOPCON TECHNOHOUSE CORPORATION).

TABLE 10

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 7.5 | 0.076 | 1.9 | 0.69 | 0.31 | 955 | 50 | 50 |
| Device 4A | | | | | | | | |
| Light-emitting | 7.5 | 0.073 | 1.82 | 0.69 | 0.31 | 981 | 54 | 48 |
| Device 4B | | | | | | | | |

TABLE 11

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 7.2 | 0.025 | 0.63 | 0.27 | 0.70 | 1064 | 170 | 40 |
| Device 5A | | | | | | | | |
| Light-emitting | 7.2 | 0.026 | 0.64 | 0.25 | 0.72 | 927 | 144 | 34 |
| Device 5B | | | | | | | | |

TABLE 12

| | | | | | | | | External | |
|---|---|---|---|---|---|---|---|---|---|
| | | | Current | | | | Current | quantum | |
| | Voltage | Current | density | Chromaticity | Chromaticity | Luminance | efficiency | efficiency | BI value |
| | (V) | (mA) | (mA/cm²) | x | y | (cd/m²) | (cd/A) | (%) | (cd/A/y) |
| Light-emitting | 9.6 | 0.5 | 12.0 | 0.14 | 0.050 | 912 | 7.6 | 14.4 | 152 |
| Device 6A | | | | | | | | | |
| Light-emitting | 10.0 | 0.9 | 22.7 | 0.15 | 0.043 | 1035 | 4.6 | 9.7 | 106 |
| Device 6B | | | | | | | | | |

FIG. 35 and Table 10 show that the current efficiency of Light-emitting Device 4B is higher than that of Light-emitting Device 4A. This indicates that, like a single-type red-light-emitting device, a tandem-type red-light-emitting device has higher emission efficiency when the thickness of its cathode is 25 nm.

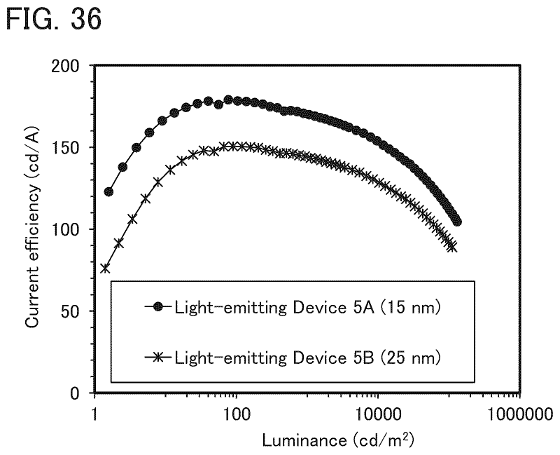

FIG. 36 and Table 11 show that the current efficiency of Light-emitting Device 5A is higher than that of Light-emitting Device 5B. This indicates that a tandem-type green-light-emitting device has higher emission efficiency when the thickness of its cathode is 15 nm.

FIG. 37 and Table 12 show that the blue index of Light-emitting Device 6A is higher than that of Light-emitting Device 6B. This indicates that, like a single-type blue-light-emitting device, a tandem-type blue-light-emitting device has higher emission efficiency when the thickness of its cathode is 15 nm.

The above results show that in a display apparatus of one embodiment of the present invention, when the thickness of the auxiliary electrode 106 differs between the light-emitting devices emitting light of different colors, or specifically, when the thickness of the auxiliary electrode 106R of the red-light-emitting device 130R is larger than the thickness of the auxiliary electrode 106G of the green-light-emitting device 130G and the thickness of the auxiliary electrode 106B of the blue-light-emitting device 130B as illustrated in FIG. 1B, the cathode thickness can be different between the light-emitting devices and thus, the emission efficiency of the light-emitting devices can be increased. It is found that in the display apparatus of one embodiment of the present invention, when the auxiliary electrode 106R is provided in the red-light-emitting device 130R and no auxiliary electrode is provided in the green-light-emitting device 130G or the blue-light-emitting device 130B, the cathode thickness can be different between the light-emitting devices and thus, the emission efficiency of the light-emitting devices can be increased.

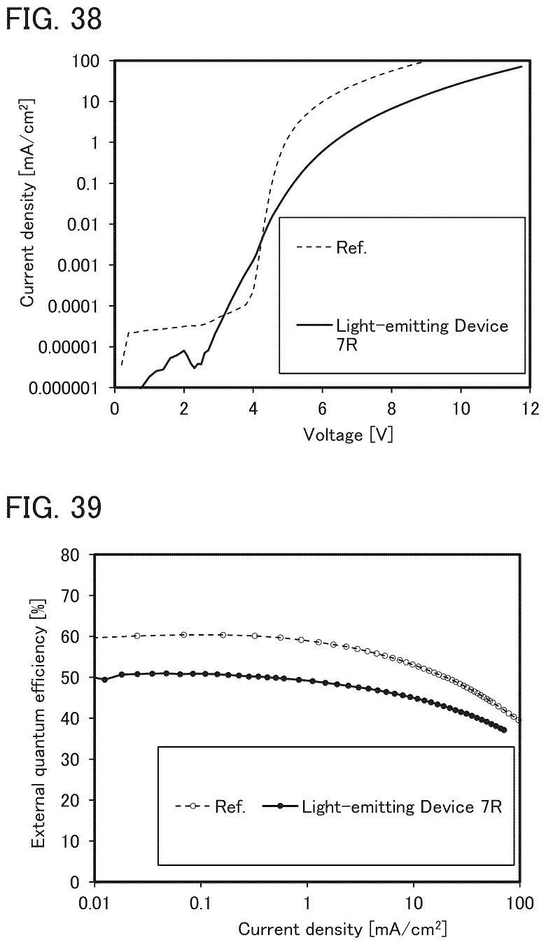

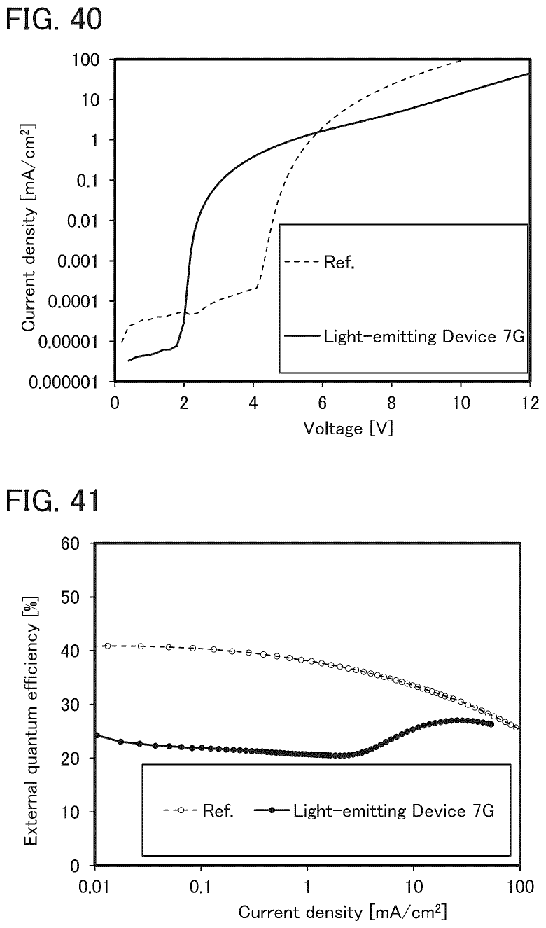

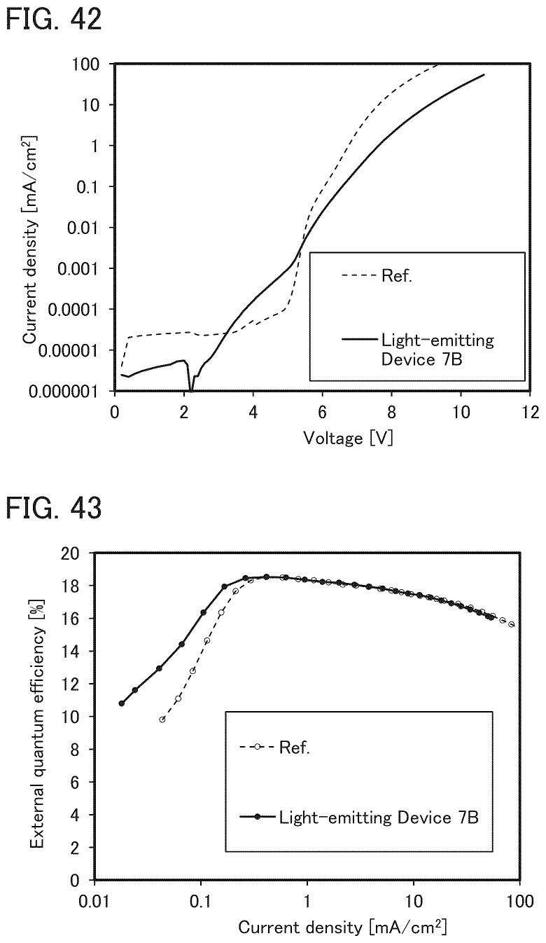

Next, FIG. 38 shows the current density-voltage characteristics of Light-emitting Device 7R, and FIG. 39 shows the external quantum efficiency-current density characteristics thereof. FIG. 40 shows the current density-voltage characteristics of Light-emitting Device 7G, and FIG. 41 shows the external quantum efficiency-current density characteristics thereof. FIG. 42 shows the current density-voltage characteristics of Light-emitting Device 7B, and FIG. 43 shows the external quantum efficiency-current density characteristics thereof.

Note that FIG. 38 and FIG. 39 also show measurement results of a reference light-emitting device (denoted by Ref. in the graphs) that has a structure similar to that of Light-emitting Device 7R and was fabricated without undergoing the process of forming the organic compound layer by a photolithography method. FIG. 40 and FIG. 41 also show measurement results of a reference light-emitting device (denoted by Ref. in the graphs) that has a structure similar to that of Light-emitting Device 7G and was fabricated without undergoing the process of forming the organic compound layer by a photolithography method. FIG. 42 and FIG. 43 also show measurement results of a reference light-emitting device (denoted by Ref. in the graphs) that has a structure similar to that of Light-emitting Device 7B and was fabricated without undergoing the process of forming the organic compound layer by a photolithography method.

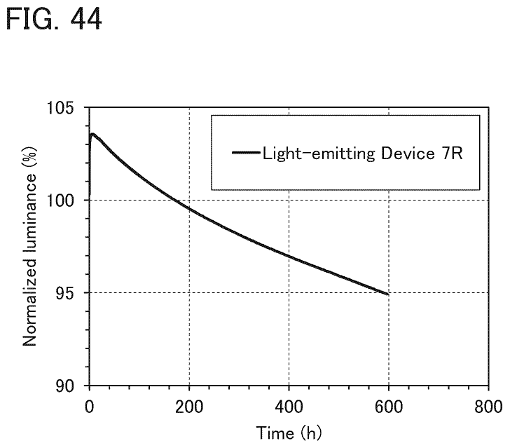

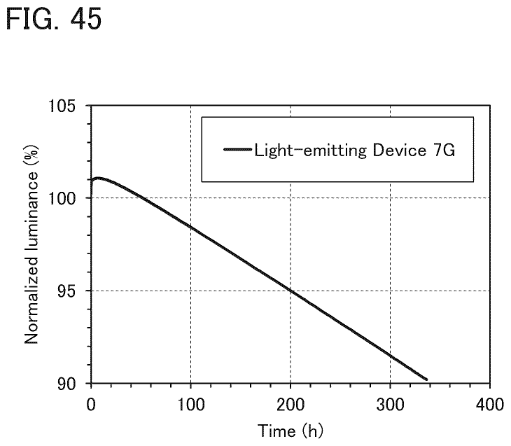

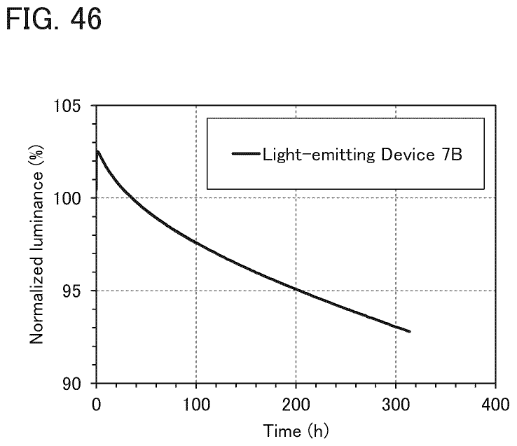

FIG. 44 shows results of constant current driving of Light-emitting Device 7R. FIG. 45 shows results of constant current driving of Light-emitting Device 7G. FIG. 46 shows results of constant current driving of Light-emitting Device 7B.

FIG. 44 shows that the LT95 of Light-emitting Device 7R is 590 hours at a current density of 63 mA/cm². FIG. 45 shows that the LT95 of Light-emitting Device 7G is 200 hours at a current density of 54 mA/cm². FIG. 46 shows that the LT95 of Light-emitting Device 7B is 204 hours at a current density of 50 mA/cm².

As described above, the organic compound layer of Light-emitting Device 7R has the same structure as that of Light-emitting Device 4A except for the structures of the intermediate layer and the first electron-transport layer. As shown in FIG. 35, Light-emitting Device 4A with a cathode thickness of 15 nm has lower current efficiency than Light-emitting Device 4B with a cathode thickness of 25 nm; thus, Light-emitting Device 7R should have higher emission efficiency when fabricated to have a cathode thickness of 25 nm by providing an auxiliary electrode between the electron-injection layer and the cathode.

Light-emitting Device 7G is a green-light-emitting device like Light-emitting Device 5A described above, and the cathode thickness of Light-emitting Device 7G is the same as that of Light-emitting Device 5A (15 nm). As shown in FIG. 36, Light-emitting Device 5A with a cathode thickness of 15 nm has higher current efficiency than Light-emitting Device 5B with a cathode thickness of 25 nm; it is thus presumable that Light-emitting Device 7G is preferably provided with no auxiliary electrode to maintain high emission efficiency.

The organic compound layer of Light-emitting Device 7B has the same structure as that of Light-emitting Device 6A except for the structure of the intermediate layer, the thickness of the first hole-transport layer, and the structure of the first electron-transport layer, and the cathode thickness of Light-emitting Device 7B is the same as that of Light-emitting Device 6A (15 nm). As shown in FIG. 37, Light-emitting Device 6A with a cathode thickness of 15 nm has a higher blue index than Light-emitting Device 6B with a cathode thickness of 25 nm; it is thus presumable that Light-emitting Device 7B is preferably provided with no auxiliary electrode to maintain high emission efficiency.

This application is based on Japanese Patent Application Serial No. 2023-136988 filed with Japan Patent Office on Aug. 25, 2023 and Japanese Patent Application Serial No. 2023-195006 filed with Japan Patent Office on Nov. 16, 2023, the entire contents of which are hereby incorporated by reference.

What is claimed is:

1. A display apparatus comprising:
a first light-emitting device; and
a second light-emitting device,
wherein the first light-emitting device and the second light-emitting device comprise a common electrode with a light-transmitting property,
wherein the first light-emitting device comprises a first electrode, a first EL layer, and a first auxiliary electrode with a light-transmitting property,
wherein the second light-emitting device comprises a second electrode, a second EL layer, and a second auxiliary electrode with a light-transmitting property,
wherein the first EL layer is between the first electrode and the common electrode,
wherein the second EL layer is between the second electrode and the common electrode,
wherein the first auxiliary electrode is between the first EL layer and the common electrode,
wherein the second auxiliary electrode is between the second EL layer and the common electrode, and
wherein a thickness of the first auxiliary electrode is larger than a thickness of the second auxiliary electrode.

2. The display apparatus according to claim 1,
wherein a color of light emitted from the first light-emitting device is different from a color of light emitted from the second light-emitting device.

3. The display apparatus according to claim 1,
wherein a wavelength of light emitted from the first light-emitting device is longer than a wavelength of light emitted from the second light-emitting device.

4. The display apparatus according to claim 1,
wherein the first auxiliary electrode comprises silver and magnesium.

5. The display apparatus according to claim 1,
wherein the thickness of the first auxiliary electrode is greater than or equal to 1 nm and less than or equal to 50 nm.

6. The display apparatus according to claim 1, further comprising an insulating layer,
wherein the insulating layer is between the first EL layer and the second EL layer.

7. A display apparatus comprising:
a first light-emitting device; and
a second light-emitting device,
wherein the first light-emitting device and the second light-emitting device comprise a common electrode with a light-transmitting property,
wherein the first light-emitting device comprises a first electrode, a first EL layer, and a first auxiliary electrode with a light-transmitting property,
wherein the second light-emitting device comprises a second electrode and a second EL layer,
wherein the first EL layer is between the first electrode and the common electrode,
wherein the second EL layer is between the second electrode and the common electrode and is in contact with the common electrode, and
wherein the first auxiliary electrode is between the first EL layer and the common electrode.

8. The display apparatus according to claim 7,
wherein a color of light emitted from the first light-emitting device is different from a color of light emitted from the second light-emitting device.

9. The display apparatus according to claim 7,
wherein a wavelength of light emitted from the first light-emitting device is longer than a wavelength of light emitted from the second light-emitting device.

10. The display apparatus according to claim 7,
wherein the first auxiliary electrode comprises silver and magnesium.

11. The display apparatus according to claim 7,
wherein a thickness of the first auxiliary electrode is greater than or equal to 1 nm and less than or equal to 50 nm.

12. The display apparatus according to claim 7, further comprising an insulating layer,
wherein the insulating layer is between the first EL layer and the second EL layer.

13. A display apparatus comprising:
a first light-emitting device; and
a second light-emitting device,
wherein the first light-emitting device and the second light-emitting device comprise a common electrode with a light-transmitting property and a common layer,
wherein the common electrode is over the common layer,
wherein the first light-emitting device comprises a first electrode, a first EL layer, and a first auxiliary electrode with a light-transmitting property,
wherein the second light-emitting device comprises a second electrode and a second EL layer,
wherein the first EL layer is between the first electrode and the common layer,
wherein the second EL layer is between the second electrode and the common layer and is in contact with the common layer, and
wherein the first auxiliary electrode is between the first EL layer and the common layer.

14. The display apparatus according to claim 13,
wherein the common layer comprises an alkali metal or an alkaline earth metal.

15. The display apparatus according to claim 13,
wherein a color of light emitted from the first light-emitting device is different from a color of light emitted from the second light-emitting device.

16. The display apparatus according to claim 13,
wherein a wavelength of light emitted from the first light-emitting device is longer than a wavelength of light emitted from the second light-emitting device.

17. The display apparatus according to claim 13,
wherein the first auxiliary electrode comprises silver and magnesium.

18. The display apparatus according to claim 13,
wherein a thickness of the first auxiliary electrode is greater than or equal to 1 nm and less than or equal to 50 nm.

19. The display apparatus according to claim 13, further comprising an insulating layer,
wherein the insulating layer is between the first EL layer and the second EL layer.
